(19) United States
(12) Patent Application Publication
(10) Pub. No.: US 2014/0110640 A1
(43) Pub. Date: Apr. 24, 2014

(54) METHOD OF PRODUCING SULFIDE COMPOUND SEMICONDUCTOR BY USE OF SOLVOTHERMAL METHOD AND ROD-LIKE CRYSTAL OF SULFIDE COMPOUND SEMICONDUCTOR

(71) Applicants: Sumio Kamiya, Toyota-shi (JP); Keisuke Kishita, Nagoya-shi (JP); Kazumichi Yanagisawa, Kochi-shi (JP); Haijun Tao, Kochi-shi (JP)

(72) Inventors: Sumio Kamiya, Toyota-shi (JP); Keisuke Kishita, Nagoya-shi (JP); Kazumichi Yanagisawa, Kochi-shi (JP); Haijun Tao, Kochi-shi (JP)

(73) Assignees: KOCHI UNIVERSITY, Kochi-shi, Kochi (JP); TOYOTA JIDOSHA KABUSHIKI KAISHA, Toyota-shi, Aichi-ken (JP)

(21) Appl. No.: 14/124,156

(22) PCT Filed: Jun. 6, 2012
(86) PCT No.: PCT/IB2012/001223

§ 371 Date: Dec. 5, 2013

(30) Foreign Application Priority Data
Jun. 6, 2011 (JP) 2011-126267
May 18, 2012 (JP) 2012-114566

(51) Int. Cl. H01L 31/032

(52) U.S. Cl. CPC H01L 31/0326
USPC 252/519.14; 423/511

(57) ABSTRACT

The present invention provides a method of producing a sulfide compound semiconductor containing Cu, Zn, Sn and S, in which the method includes a solvothermal step of conducting a solvothermal reaction of Cu, Zn, Sn and S in an organic solvent, and a rod-like crystal of sulfide compound semiconductor containing Cu, Zn, Sn and S.

### BACKGROUND OF THE INVENTION

1. Field of the Invention

The present invention relates to a method of producing nano-particles of a sulfide compound semiconductor containing Cu, Zn, Sn and S by use of a solvothermal method, and relates to a rod-like crystal of a sulfide compound semiconductor.

2. Description of the Related Art

As a material of compound semiconductor solar batteries, CuInGaSe₂ (CIGS) is a mainstream material at the present time. However, since the CIGS contains In that is a rare earth element and Se that is a highly toxic element, development of an alternative material is in demand.

As an alternative material for the CIGS, a sulfide compound semiconductor Cu₂ZnSnS₄ (Copper Zinc Tin Sulfur: CZTS) that has a band-gap energy suitable for solar batteries and contains neither In nor Se is gathering attention. The CZTS is typically produced by solid phase reaction of metal powder and sulfur powder under high temperatures in a deaerated glass ample. Further, as another method, Japanese Patent Application Publication No. 2009-135316 (JP 2009-135316 A) describes a method where a CZTS precursor is prepared by sputtering, and a film of the precursor is heated under an atmosphere of hydrogen sulfide, or a method where a solution in which an organic metal is dissolved is coated on a substrate and dried in air to cause hydrolysis and degenerate reaction to form a metal oxide thin film, and the thin film is heated under an atmosphere of hydrogen sulfide.

As described above, some examples of the method of producing CZTS have been known. However, when a solid phase reaction is used to produce, it is difficult to control a temperature of formation of Cu—Zn—Sn system alloys and/or a composition of generation phase. Accordingly; there was a problem that a homogeneous CZTS is difficult to obtain. Further, when a method that uses hydrogen sulfide is used, because of toxicity of hydrogen sulfide, there was a problem that safety management is costly.

### SUMMARY OF THE INVENTION

In view of the above-described problems, the present invention provides a method of producing nano-particles of sulfide compound semiconductor, which enables to obtain microparticulate particles at a low cost, and rod-like crystals of sulfide compound semiconductor.

The present inventors, after variously studying means for solving the problems, have found that when Cu, Zn, Sn and S are solvothermally reacted in an organic solvent, microparticulate CZTS particles can be produced at a cost lower than that of a conventional product that is obtained by solid phase reaction, and thereby the present invention was completed.

That is, according to a first aspect of the present invention, a method of producing a sulfide compound semiconductor containing Cu, Zn, Sn and S is provided, in which the method includes a solvothermal step of conducting a solvothermal reaction of Cu, Zn, Sn and S in an organic solvent.

Further, in the solvothermal step in the method of producing, S may be solvothermally reacted in the form of sulfur powder or thiourea.

Still further, in the solvothermal step in the method of producing, at least one kind of Cu, Zn and Sn may be solvothermally reacted in the form of metal.

Further, in the solvothermal step in the method of producing, Cu, Zn and Sn may be solvothermally reacted in the form of salt.

An organic solvent used in the solvothermal step in the method of producing may be selected from the group consisting of ethylenediamine, isopropyl alcohol, oleylamine, oleic acid, ethanol, acetone, ethylene glycol, water/oleylamine, ethanol/oleylamine and oleic acid/oleylamine.

Still further, in the solvothermal step in the method of producing, the solvothermal reaction is preferably conducted at a temperature in the range of 200 to 450° C. for 1 to 24 hours. Here, in the solvothermal step, the solvothermal reaction is more preferably conducted at a temperature in the range of 200 to 450° C. for 8 to 12 hours.

Further, the S may be also in the form of sulfur powder.

Still further, a concentration of the Cu may be in the range of 0.1 to 1.0 mol/L. Further, a concentration of each of the Zn and the Sn may be also in the range of 0.05 to 0.5 mol/L. Still further, a concentration of the S may be also in the range of 0.2 to 4.0 mol/L.

Further, a molar ratio of the Cu, Zn, Sn and S is preferably in the range of 2:1:1:4 to 2:1:1:12 as a composition ratio of S to Cu, Zn and Sn. Here, a molar ratio of the Cu, Zn, Sn and S is more preferably in the range of 2:1:1:6 to 2:1:1:8 as a composition ratio of S to Cu, Zn and Sn.

According to a second aspect of the present invention, a rod-like crystal of sulfide compound semiconductor containing Cu, Zn, Sn and S is provided.

According to the method of producing of the present invention as described above, a method of producing CZTS nano-particles, which enables to obtain microparticulate particles at a low cost, can be provided. Further, according to the present invention, a rod-like crystal of microparticulate sulfide compound semiconductor containing Cu, Zn, Sn and S can be obtained.

### BRIEF DESCRIPTION OF THE DRAWINGS

The features, advantages, and technical and industrial significance of this invention will be described in the following detailed description of example embodiments of the invention with reference to the accompanying drawings, in which like numerals denote like elements, and wherein:

FIG. 1A is a diagram showing an X-ray powder diffraction (XRD) spectrum of powder of Example 1 of the present invention;

FIG. 1B is a diagram showing a differential thermal analysis (DTA) spectrum of the powder of Example 1;

FIG. 1C is a diagram showing a scanning electron microscope (SEM) image (left diagram, scale bar: 10 μm) of the powder of Example 1 and a transmission electron microscope (TEM) image (right diagram, scale bar: 500 nm) thereof;

FIG. 1D is a diagram showing an SEM image of the powder of Example 1 (upper diagram, scale bar: 30 μm) and element mapping images based on the SEM image thereof;

FIG. 2A is a diagram showing an XRD spectrum of powder of Example 2 of the present invention;

FIG. 2B is a diagram showing a DTA spectrum of the powder of Example 2;

FIG. 2C is a diagram showing an SEM image (left diagram, scale bar: 10 μm) of the powder of Example 2 and a TEM image (right diagram, scale bar: 200 nm) thereof;

FIG. 2D is a diagram showing an SEM image of the powder of Example 2 (upper diagram, scale bar: 30 μm) and element mapping images based on the SEM image thereof;

FIG. 3A is a diagram showing an XRD spectrum of powder of Example 3 of the present invention;

FIG. 3B is a diagram showing a DTA spectrum of the powder of Example 3;

FIG. 3C is a diagram showing an SEM image (left diagram, scale bar: 10 μm) of the powder of Example 3 and a TEM image (right diagram, scale bar: 1000 nm) thereof;

FIG. 3D is a diagram showing an SEM image (upper diagram, scale bar: 30 μm) of the powder of Example 3 and element mapping images based on the SEM image thereof;

FIG. 4A is a diagram showing an XRD spectrum of powder of Example 4 of the present invention;

FIG. 4B is a diagram showing a DTA spectrum of the powder of Example 4;

FIG. 4C is a diagram showing an SEM image (left diagram, scale bar: 10 μm) of the powder of Example 4 and a TEM image (right diagram, scale bar: 1000 nm) thereof;

FIG. 4D is a diagram showing an SEM image (upper diagram, scale bar: 100 μm) of the powder of Example 4 and element mapping images based on the SEM image thereof;

FIG. 5A is a diagram showing an XRD spectrum of powder of Example 5 of the present invention;

FIG. 5B is a diagram showing a DTA spectrum of the powder of Example 5;

FIG. 5C is a diagram showing an SEM image (scale bar: 10 μm) of the powder of Example 5;

FIG. 5D is a diagram showing an SEM image (upper diagram, scale bar: 30 μm) of the powder of Example 5 and element mapping images based on the SEM image thereof;

FIG. 6A is a diagram showing an XRD spectrum of powder of Example 6 of the present invention;

FIG. 6B is a diagram showing a DTA spectrum of the powder of Example 6;

FIG. 6C is a diagram showing an SEM image (scale bar: 10 μm) of the powder of Example 6;

FIG. 6D is a diagram showing an SEM image (upper diagram, scale bar: 30 μm) of the powder of Example 6 and element mapping images based on the SEM image thereof;

FIG. 7A is a diagram showing an XRD spectrum of powder of Example 7 of the present invention;

FIG. 7B is a diagram showing a DTA spectrum of the powder of Example 7;

FIG. 7C is a diagram showing an SEM image (scale bar: 10 μm) of the powder of Example 7;

FIG. 7D is a diagram showing an SEM image (upper diagram, scale bar: 10 μm) of the powder of Example 7 and element mapping images based on the SEM image thereof;

FIG. 8A is a diagram showing an XRD spectrum of powder of Example 8 of the present invention;

FIG. 8B is a diagram showing a DTA spectrum of the powder of Example 8;

FIG. 8C is a diagram showing an SEM image (scale bar: 10 μm) of the powder of Example 8;

FIG. 8D is a diagram showing an SEM image (upper diagram, scale bar: 30 μm) of the powder of Example 8 and element mapping images based on the SEM image thereof;

FIG. 9A is a diagram showing an XRD spectrum of powder of Example 9 of the present invention;

FIG. 9B is a diagram showing a DTA spectrum of the powder of Example 9;

FIG. 9C is a diagram showing an SEM image (left diagram, scale bar: 1 μm) of the powder of Example 9 and a TEM image (right diagram, scale bar: 100 μm) thereof;

FIG. 9D is a diagram showing an SEM image (upper diagram, scale bar: 10 μm) of the powder of Example 9 and element mapping images based on the SEM image thereof;

FIG. 10A is a diagram showing an XRD spectrum of powder of Example 10 of the present invention;

FIG. 10B is a diagram showing a DTA spectrum of the powder of Example 10;

FIG. 10C is a diagram showing an SEM image (left diagram, scale bar: 10 μm) of the powder of Example 10 and a TEM image (right diagram, scale bar: 500 nm) thereof;

FIG. 10D is a diagram showing an SEM image (upper diagram, scale bar: 10 μm) of the powder of Example 10 and element mapping images based on the SEM image thereof;

FIG. 11A is a diagram showing an XRD spectrum of powder of Example 11 of the present invention;

FIG. 11B is a diagram showing a DTA spectrum of the powder of Example 11;

FIG. 11C is a diagram showing an SEM image (left diagram, scale bar: 10 μm) of the powder of Example 11 and a TEM image (right diagram, scale bar: 200 nm) thereof;

FIG. 11D is a diagram showing an SEM image (upper diagram, scale bar: 5 μm) of the powder of Example 11 and element mapping images based on the SEM image thereof;

FIG. 12A is a diagram showing an XRD spectrum of powder of Example 12 of the present invention;

FIG. 12B is a diagram showing a DTA spectrum of the powder of Example 12;

FIG. 12C is a diagram showing an SEM image (left diagram, scale bar: 1 μm) of the powder of Example 12 and a TEM image (right diagram, scale bar: 200 nm) thereof;

FIG. 12D is a diagram showing an SEM image (upper diagram, scale bar: 10 μm) of the powder of Example 12 and element mapping images based on the SEM image thereof;

FIG. 13A is a diagram showing an XRD spectrum of powder of Example 13 of the present invention;

FIG. 13B is a diagram showing a DTA spectrum of the powder of Example 13;

FIG. 13C is a diagram showing an SEM image (left diagram, scale bar: 10 μm) of the powder of Example 13 and a TEM image (right diagram, scale bar: 200 nm) thereof;

FIG. 13D is a diagram showing an SEM image (upper diagram, scale bar: 20 μm) of the powder of Example 13 and element mapping images based on the SEM image thereof;

FIG. 14A is a diagram showing an XRD spectrum of powder of Example 14 of the present invention;

FIG. 14B is a diagram showing a DTA spectrum of the powder of Example 14;

FIG. 14C is a diagram showing an SEM image (left diagram, scale bar: 1 μm) of the powder of Example 14 and a TEM image (right diagram, scale bar: 200 nm) thereof;

FIG. 14D is a diagram showing an SEM image (upper diagram, scale bar: 10 μm) of the powder of Example 14 and element mapping images based on the SEM image thereof;

FIG. 15A is a diagram showing an XRD spectrum of powder of Example 15 of the present invention;

FIG. 15B is a diagram showing a DTA spectrum of the powder of Example 15;

FIG. 15C is a diagram showing an SEM image (left diagram, scale bar: 1 μm) of the powder of Example 15 and a TEM image (right diagram, scale bar: 200 nm) thereof;

FIG. 15D is a diagram showing an SEM image (upper diagram, scale bar: 20 μm) of the powder of Example 15 and element mapping images based on the SEM image thereof;

FIG. 16A is a diagram showing an XRD spectrum of powder of Example 16 of the present invention;

FIG. 16B is a diagram showing a DTA spectrum of the powder of Example 16;

FIG. 16C is a diagram showing an SEM image (left diagram, scale bar: 10 μm) of the powder of Example 16 and a TEM image (right diagram, scale bar: 500 nm) thereof;

FIG. 16D is a diagram showing an SEM image (upper diagram, scale bar: 10 μm) of the powder of Example 16 and element mapping images based on the SEM image thereof;

FIG. 17A is a diagram showing an XRD spectrum of powder of Example 17 of the present invention;

FIG. 17B is a diagram showing a DTA spectrum of the powder of Example 17;

FIG. 17C is a diagram showing an SEM image (left diagram, scale bar: 10 μm) of the powder of Example 17 and a TEM image (right diagram, scale bar: 200 nm) thereof;

FIG. 17D is a diagram showing an SEM image (upper diagram, scale bar: 20 μm) of the powder of Example 17 and element mapping images based on the SEM image thereof;

FIG. 18A is a diagram showing an XRD spectrum of powder of Example 18 of the present invention;

FIG. 18B is a diagram showing a DTA spectrum of the powder of Example 18;

FIG. 18C is a diagram showing an SEM image (left diagram, scale bar: 10 μm) of the powder of Example 18 and a TEM image (right diagram, scale bar: 200 nm) thereof;

FIG. 18D is a diagram showing an SEM image (upper diagram, scale bar: 20 μm) of the powder of Example 18 and element mapping images based on the SEM image thereof;

FIG. 19A is a diagram showing an XRD spectrum of powder of Example 19 of the present invention;

FIG. 19B is a diagram showing a DTA spectrum of the powder of Example 19;

FIG. 19C is a diagram showing an SEM image (left diagram, scale bar: 10 μm) of the powder of Example 19 and a TEM image (right diagram, scale bar: 200 nm) thereof;

FIG. 19D is a diagram showing an SEM image (upper diagram, scale bar: 20 μm) of the powder of Example 19 and element mapping images based on the SEM image thereof;

FIG. 20A is a diagram showing an XRD spectrum of powder of Example 20 of the present invention;

FIG. 20B is a diagram showing a DTA spectrum of the powder of Example 20;

FIG. 20C is a diagram showing an SEM image (left diagram, scale bar: 1 μm) of the powder of Example 20 and a TEM image (right diagram, scale bar: 500 nm) thereof;

FIG. 20D is a diagram showing an SEM image (upper diagram, scale bar: 10 μm) of the powder of Example 20 and element mapping images based on the SEM image thereof;

FIG. 21A is a diagram showing an XRD spectrum of powder of Example 21 of the present invention;

FIG. 21B is a diagram showing a DTA spectrum of the powder of Example 21;

FIG. 21C is a diagram showing an SEM image (left diagram, scale bar: 10 μm) of the powder of Example 21 and a TEM image (right diagram, scale bar: 200 nm) thereof;

FIG. 21D is a diagram showing an SEM image (upper diagram, scale bar: 20 μm) of the powder of Example 21 and element mapping images based on the SEM image thereof;

FIG. 22A is a diagram showing an electron diffraction image of the powder of Example 11 of the present invention and TEM images thereof;

FIG. 22B is a diagram showing an electron diffraction image of the powder of Example 11 and TEM images thereof;

FIG. 22C is a diagram showing an electron diffraction image of the powder of Example 11 and TEM images thereof;

FIG. 23A is a diagram showing an electron diffraction image of the powder of Example 13 of the present invention and TEM images thereof;

FIG. 23B is a diagram showing an electron diffraction image of the powder of Example 13 and TEM images thereof;

FIG. 23C is a diagram showing an electron diffraction image of the powder of Example 13 and TEM images thereof;

FIG. 24A is a diagram showing an electron diffraction image of the powder of Example 14 of the present invention and TEM images thereof;

FIG. 24B is a diagram showing an electron diffraction image of the powder of Example 14 and TEM images thereof;

FIG. 24C is a diagram showing an electron diffraction image of the powder of Example 14 and TEM images thereof;

FIG. 25A is a diagram showing an electron diffraction image of the powder of Example 16 of the present invention and TEM images thereof;

FIG. 25B is a diagram showing an electron diffraction image of the powder of Example 16 and TEM images thereof;

FIG. 25C is a diagram showing an electron diffraction image of the powder of Example 16 and TEM images thereof;

FIG. 26A is a diagram showing an electron diffraction image of the powder of Example 19 of the present invention and TEM images thereof;

FIG. 26B is a diagram showing an electron diffraction image of the powder of Example 19 and TEM images thereof;

FIG. 27A is a diagram showing an electron diffraction image of the powder of Example 20 of the present invention and TEM images thereof;

FIG. 27B is a diagram showing an electron diffraction image of the powder of Example 20 and TEM images thereof;

FIG. 27C is a diagram showing an electron diffraction image of the powder of Example 20 and TEM images thereof;

FIG. 28A is a diagram showing an electron diffraction image of the powder of Example 21 of the present invention and TEM images thereof;

FIG. 28B is a diagram showing an electron diffraction image of the powder of Example 21 and TEM images thereof;

FIG. 29 is a diagram showing an SEM image of the powder of Example 31 of the present invention;

FIG. 30 is a diagram showing XRD spectra of powders of Examples 31 to 35 of the present invention. A: Example 31; B: Example 32; C: Example 33: D: Example 34; and E: Example 35;

FIG. 31 is a diagram showing Raman spectra of powders of Examples 31 to 35 of the present invention. A: Example 31; B: Example 32; C: Example 33; D: Example 34; and E: Example 35;

FIG. 32 is a diagram showing a TEM image of the powder of Example 31 of the present invention and an electron diffraction image thereof. A: TEM image (scale bar: 500 nm); B: electron diffraction image;

FIG. 33 is a diagram showing a TEM image of the powder of Example 32 of the present invention and an electron diffraction image thereof. A: TEM image (scale bar: 500 nm); B: electron diffraction image;

FIG. 34 is a diagram showing a TEM image of the powder of Example 33 of the present invention and an electron diffraction image thereof. A: TEM image (scale bar: 200 nm); B: electron diffraction image;

FIG. 35 is a diagram showing a TEM image of the powder of Example 34 of the present invention and an electron diffraction image thereof. A: TEM image (scale bar: 500 nm); B: electron diffraction image of site 1 of the TEM image; C: electron diffraction image of site 2 of the TEM image;

FIG. 36 is a diagram showing a TEM image of the powder of Example 35 of the present invention and an electron diffraction image thereof. A: TEM image (scale bar: 200 nm); B: electron diffraction image;

FIG. 37 is a diagram showing TG-DTA measurements of the powder of Example 34 of the present invention;

FIG. 38 is a diagram showing XPS spectra (Cu2p) of powders of Examples 31 to 35 of the present invention. A: Example 31; B: Example 32; C: Example 33; D: Example 34; E: Example 35;

FIG. 39 is a diagram showing XPS spectra (Zn2p3) of powders of Examples 31 to 35 of the present invention. A: Example 31; B: Example 32; C: Example 33; D: Example 34; E: Example 35;

FIG. 40 is a diagram showing XPS spectra (Sn3d5) of powders of Examples 31 to 35 of the present invention. A: Example 31; B: Example 32; C: Example 33; D: Example 34; E: Example 35; and

FIG. 41 is a diagram showing XPS spectra (S2p) of powders of Examples 31 to 35 of the present invention. A: Example 31; B: Example 32; C: Example 33; D: Example 34; E: Example 35.

### DETAILED DESCRIPTION OF EMBODIMENTS

The present invention relates to a method of producing a sulfide compound semiconductor containing Cu, Zn, Sn and S (Copper Zinc Tin Sulfur: CZTS). In the present specification, “a sulfide compound semiconductor (CZTS)” means a semiconductive compound containing Cu, Zn, Sn and S and has a kesterite structure represented by a formula Cu₂ZnSnS₄. Preferable embodiments of the present invention will be detailed below.

The method of the present invention includes a solvothermal step of conducting a solvothermal reaction of Cu, Zn, Sn and S in an organic solvent. The present inventors have found that when Cu, Zn, Sn and S are solvothermally reacted in an organic solvent, microparticulate CZTS nano-particles having high crystallinity are generated. Accordingly, when the step is conducted, microparticulate CZTS having high crystallinity can be produced.

In the present specification, “a solvothermal reaction” means a process where a plurality of raw materials is reacted in an organic solvent under high pressure to obtain a crystal of a reaction product. In the present step, an organic solvent used in the solvothermal reaction is preferably an organic solvent selected from the group consisting of aliphatic monoamine or polyamine, aliphatic monoalcohol or polyalcohol, aliphatic acid and aliphatic ketone or a combination of two kinds or more thereof, or a combination of water and at least one kind of the organic solvents, more preferably an organic solvent selected from the group consisting of aliphatic monoamine or diamine, aliphatic monoalcohol or dialcohol, aliphatic acid and aliphatic ketone or a combination of two kinds or more thereof, or a combination of water and at least one kind of the organic solvents, and still more preferably an organic solvent selected from the group consisting of straight, branched or cyclic saturated or unsaturated aliphatic monoamine or diamine, straight, branched or cyclic saturated or unsaturated aliphatic monoalcohol or dialcohol, straight, branched or cyclic saturated or unsaturated aliphatic acid, and straight, branched or cyclic saturated or unsaturated aliphatic ketone or a combination of two or more kinds thereof, or a combination of water and at least one kind of the organic solvents. In the case described above, the number of carbon atoms of the aliphatic group is preferably in the range of C₁ to C₂₀, more preferably in the range of C₂ to C₂₀, and still more preferably in the range of C₁ to C₁₈. For example, the organic solvent is preferably an organic solvent selected from the group consisting of ethylenediamine, isopropyl alcohol, oleylamine, oleic acid, ethanol, acetone and ethylene glycol, or a combination of two or more kinds thereof, or a combination of water and at least one kind of the organic solvents. Among the combinations of the organic solvents of two or more kinds or combinations of water and at least one kind of the organic solvents, water/oleylamine, ethanol/oleylamine or oleic acid/oleylamine is preferred. In these cases, a mixing ratio of water or organic solvents may be 1:1.

The present step is preferably conducted under the presence of, in addition to raw material substances and an organic solvent, one or more kinds of additives in certain cases. An additive used in the step is preferably polyvinylpyrrolidone. When the present step is conducted under the presence of the additive, a concentration of the additive is, with respect to a total mass of the raw material, 10% by mass to 50% by mass and preferably in the range of 30% by mass to 40% by mass. By conducting the present step under the presence of the additive, the dispersibility of the raw material can be improved.

In the present step, a solvothermal reaction temperature is preferably in the range of 200 to 450° C., more preferably in the range of 200 to 350° C., and still more preferably in the range of 250 to 350° C. Further, a solvothermal reaction time is preferably in the range of 1 to 24 hours, more preferably in the range of 8 to 24 hours and still more preferably in the range of 8 to 12 hours.

When the solvothermal reaction is conducted under the above-mentioned Conditions, CZTS can be obtained at a temperature lower than and for a time shorter than these of the conventional method like a solid phase reaction.

When the present step is conducted, means for conducting a solvothermal reaction is not specifically limited. An apparatus used in the solvothermal reaction in the art such as an autoclave can be used. Specifically, when the solvothermal reaction is conducted at a temperature in the range of 200 to 250° C., an apparatus that uses a relatively cheap resin such as a fluororesin (for example, TEFLON™, PTFE manufactured by DuPont) may be used, and when the solvothermal reaction is conducted at a temperature more than 250° C. and 400° C. or lower, an apparatus that uses a heat-resistant and corrosion-resistant alloy such as a nickel alloy (for example, HASTELLOY™, manufactured by Haynes International, Inc.) may be used. When the present step is conducted by use of an autoclave, the filling rate of a reaction mixture containing Cu, Zn, Sn and S is preferably in the range of 30 to 70% by volume relative to an internal volume of the autoclave, and more preferably 40 to 60% by volume or less. When the above method is used, without preparing a special apparatus, the present step can be readily conducted.

In the present step, S may be used in the form of sulfur powder or thiourea. The present inventors have found that when the solvothermal reaction is conducted, with sulfur powder or thiourea as a raw material, the CZTS can be produced. Usually, when the CZTS is produced, in order to use sulfur powder, a solid phase reaction under high temperature and high pressure is necessary. On the other hand, when sulfide such as hydrogen sulfide is used, in order to prevent health damage due to toxic hydrogen sulfide, safety management is costly. Accordingly, when the solvothermal reaction is conducted with sulfur powder or thiourea as an S source, the CZTS can be obtained at a lower cost, at a lower temperature and for a shorter time than a conventional method like a solid phase reaction or a reaction that uses sulfide.

In the present step, Cu, Zn and Sn used may be in the form of either metal or salt. It is preferable that at least one kind of Cu, Zn and Sn is in the form of metal and the others are in the form of salt, and more preferable that all of Cu, Zn and Sn are in the form of salt. In the case of in the form of salt, examples of pair ions include a conjugate base of inorganic acid or organic acid, for example, a conjugate base of hydrogen halide or C₁ to C₄ aliphatic acid, preferably, Cl⁻¹, CH₃COO⁻(Ac⁻) and CH₃CH₂COO⁻. Among these, Cl⁻ or CH₃COO⁻(Ac⁻) is preferable. Further, in the case of salt form, the salt form may be an anhydride form or a hydride form. Salts of Cu, Zn and Sn are preferably salts selected respectively from the group consisting of CuAc₂, CuAc₂×H₂O, CuCl₂, CuCl₂×2H₂O, ZnAc₂, ZnCl₂, SnCl₂, SnCl₄×5H₂O and SnAc₂. Salts of Cu, Zn and Sn (for example, CuAc₂×H₂O, CuCl₂, CuCl₂×2H₂O, ZnAc₂, ZnCl₂, SnCl₂, SnCl₄×5H₂O and SnAc₂) are cheap materials industrially utilized in the art. Accordingly, when the above-mentioned salts are used as Cu, Zn and Sn sources, the target CZTS can be produced at a low cost.

In the present step, a concentration of Cu is preferably in the range of 0.01 to 1.0 mol/L and more preferably in the range of 0.1 to 1.0 mol/L. Concentrations of Zn and Sn are preferably in the range of 0.01 to 0.5 mol/L, and more preferably in the range of 0.05 to 0.5 mol/L. Further, a concentration of S is preferably in the range of 0.1 to 4.0 mol/L and more preferably in the range of 0.2 to 4.0 mol/L. Specifically, a molar ratio of Cu, Zn, Sn and S is, as a composition ratio of S to Cu, Zn and Sn, preferably in the range of 2:1:1:4 to 2:1:1:12, more preferably in the range of 2:1:1:4 to 2:1:1:8 and still more preferably in the range of 2:1:1:6 to 2:1:1:8. When Cu, Zn, Sn and S of the above concentrations are used, the CZTS can be produced with high purity and at high yield.

The CZTS obtained from the solvothermal reaction can be separated from a reaction mixture after the solvothermal reaction by conventional means such as filtration and can be washed with water as desired.

When the present step is conducted under the above conditions, the CZTS can be produced with high purity and at high yield.

The present inventors have found that when metal salts are used as raw materials, the CZTS obtained according to the method of the present invention becomes a crystal form having a fine particle size. Specifically, the CZTS obtained according to the method of the present invention usually has a particle size of 5 to 200 nm and typically of 30 to 200 nm. In the CZTS obtained according to the method of the invention, primary particles having the above mentioned particle size flocculate to form secondary particles having particle size of 5 nm to 500 μm. The CZTS obtained from the solid phase reaction usually has a particle size of 1 μm or more. Accordingly, by use of the method of the present invention, CZTS nano-particles having a particle size finer than that of the conventional method can be obtained.

The particle size of the CZTS is not specifically limited, but can be determined by use of for example, a UV-laser meter or a transmission electron microscope (TEM).

Further, the present inventors have found that the CZTS obtained according to the method of the present invention is usually spherical crystals having the above mentioned particle size but a rod-like crystal depending on the case. The rod-like crystal CZTS is a novel crystalline form which could not be obtained according to the conventional method. Accordingly, the present invention relates to a rod-like crystal of CZTS.

The rod-like crystal of CZTS of the present invention is preferably produced according to the present method described above and more preferably produced according to a method of the present invention that uses acetone as an organic solvent in the solvothermal step. In this case, a length in a major axis direction of the rod-like crystal is usually in the range of 30 to 70 nm. A length in a minor axis direction of the rod-like crystal is usually in the range of 5 to 10 nm. Further, a ratio of the length in a major axis direction to the length in a minor axis direction is usually in the range of 4 to 10.

The rod-like crystals tend to orient, due to the shape thereof, so that axes along the major axis direction of crystals are contained each other in the same plane. Accordingly, when the rod-like crystals of CZTS of the present invention are used, a compound semiconductor having high crystal orientation can be produced.

As described above, according to the method of the present invention, CZTS nano-particles having a fine particle size can be produced. By use of the CZTS produced according to the method of the present invention, a compound semiconductor solar battery can be produced at a lower cost. Further, the rod-like crystal of CZTS obtained according to the method of the present invention has high crystal orientation. Accordingly, when the rod-like crystal of CZTS obtained according to the method of the present invention is used, a compound semiconductor solar battery having higher conversion efficiency can be produced.

The present invention will be described below in more detail with reference to examples and comparative examples. Firstly, 2 mmol of Cu source, 1 mmol of Zn source, and 1 mmol of Sn source were dispersed together with various mole numbers of sulfur (S) powder in 10 ml of an organic solvent, filled in an autoclave and stirred for 30 minutes. The dispersion was solvothermally reacted in the autoclave (solvothermal step). The resulting product was filtered and dried in air under conditions of 50° C. and 22 hours (drying step). Thereby, CZTS was obtained. Preparation conditions of the respective examples are shown in Table 1.

TABLE 1

| | | | | S | | | | Element |
|---|---|---|---|---|---|---|---|---|
| Example | | Zn | Sn | powder | | Temperature | Time | composition |
| No. | Cu source | source | source | (mmol) | Organic solvent | (° C.) | (hour) | (Cu:Zn:SnS) |
| 1 | Cu | Zn | Sn | 4 | EDA | 450 | 24 | 30:13:12:45 |
| 2 | Cu | Zn | Sn | 4 | IPA | 450 | 24 | 21:27:7:46 |
| 3 | Cu | Zn | Sn | 8 | EDA | 450 | 24 | 27::15:13:45 |
| 4 | Cu | Zn | Sn | 8 | IPA | 450 | 24 | 26:12:13:49 |
| 5 | Cu | Zn | Sn | 4 | EDA | 200 | 24 | 30:16:11:42 |
| 6 | Cu | Zn | Sn | 8 | EDA | 200 | 24 | 32:13:13:42 |
| 7 | Cu | ZnAc₂ | Sn | 8 | EDA | 200 | 24 | 29:15:13:44 |
| 8 | Cu | ZnAc₂ | SnCl₂ | 8 | EDA | 200 | 24 | 27:9:14:50 |
| 9 | CuAc₂•H₂O | ZnAc₂ | SnCl₂ | 8 | Oleylamine | 200 | 1 | 27:13:9:51 |
| 10 | CuAc₂•H₂O | ZnAc₂ | SnCl₂ | 8 | Oleylamine | 200 | 10 | 26:11:13:50 |
| 11 | CuAc₂•H₂O | ZnAc₂ | SnAc₂ | 8 | Oleylamine | 300 | 1 | 28:15:13:44 |
| 12 | CuAc₂•H₂O | ZnAc₂ | SnAc₂ | 8 | Oleic acid | 300 | 1 | 31:13:14:43 |
| 13 | CuAc₂•H₂O | ZnAc₂ | SnAc₂ | 8 | Oleylamine | 300 | 10 | 30:15:13:42 |
| 14 | CuAc₂•H₂O | ZnAc₂ | SnAc₂ | 8 | Oleic acid | 300 | 10 | 30:16:13:42 |
| 15 | CuAc₂•H₂O | ZnAc₂ | SnAc₂ | 8 | Ethanol | 300 | 10 | 31:15:13:42 |
| 16 | CuAc₂•H₂O | ZnAc₂ | SnAc₂ | 8 | Acetone | 300 | 10 | 25:14:13:49 |
| 17 | CuAc₂•H₂O | ZnAc₂ | SnAc₂ | 8 | IPA | 300 | 10 | 29:16:14:41 |
| 18 | CuAc₂•H₂O | ZnAc₂ | SnAc₂ | 8 | EDA | 300 | 10 | 27:16:12:45 |
| 19 | CuAc₂•H₂O | ZnAc₂ | SnAc₂ | 8 | Water/oleylamine | 300 | 10 | 33:16:12:39 |
| | | | | | (1/1) | | | |
| 20 | CuAc₂•H₂O | ZnAc₂ | SnAc₂ | 8 | Ethanol/oleylamine | 300 | 10 | 30:11:14:44 |
| | | | | | (1/1) | | | |
| 21 | CuAc₂•H₂O | ZnAc₂ | SnAc₂ | 8 | Oleic | 300 | 10 | 27:13:15:45 |
| | | | | | acid/oleylamine | | | |
| | | | | | (1/1) | | | |

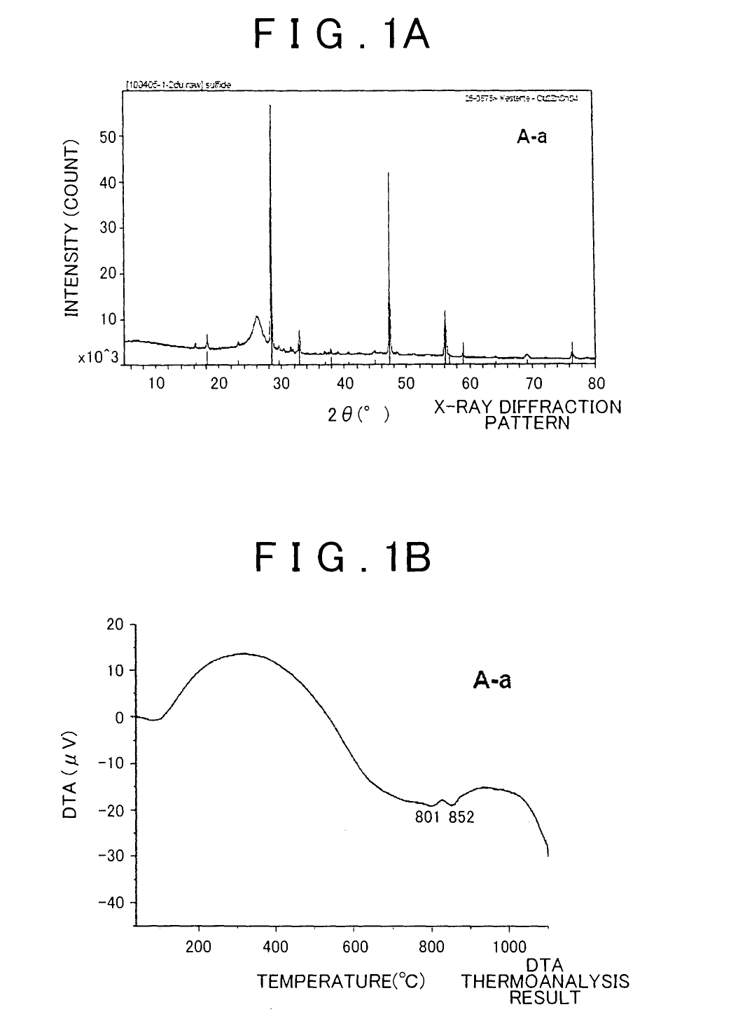

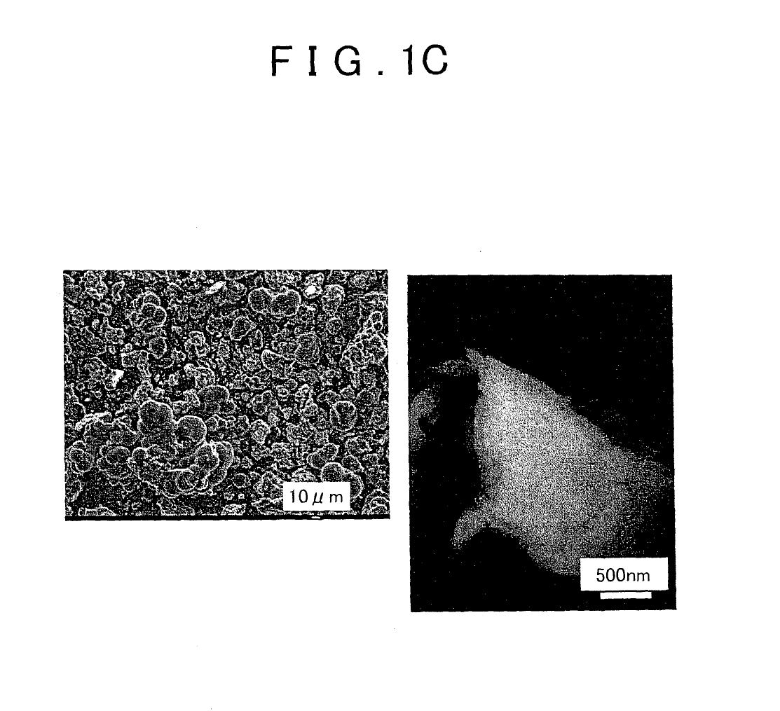

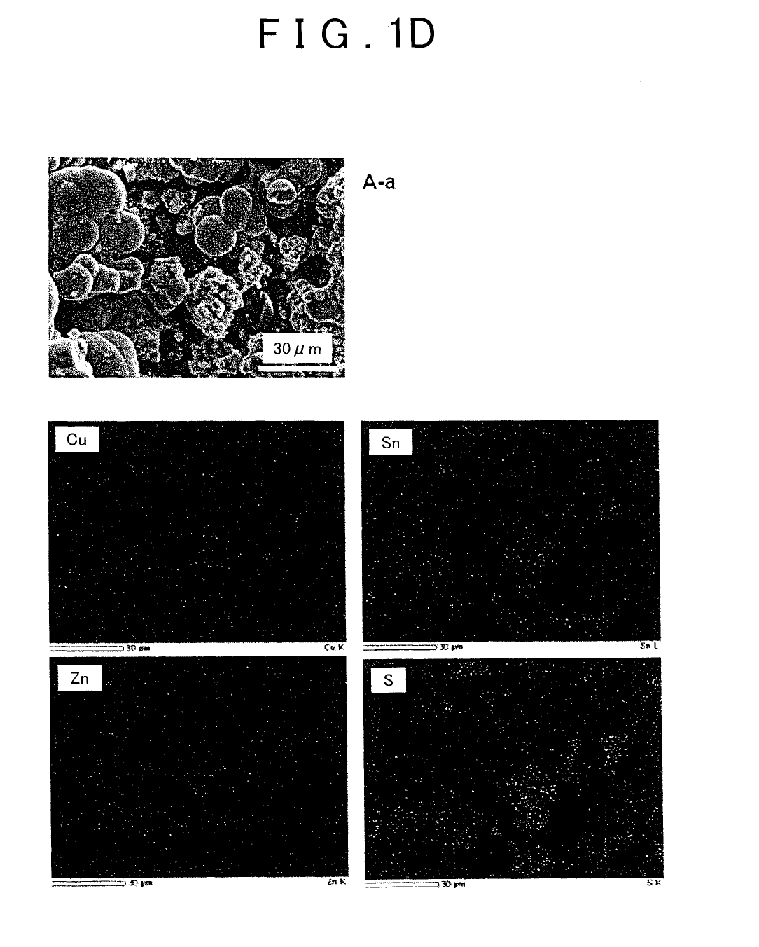

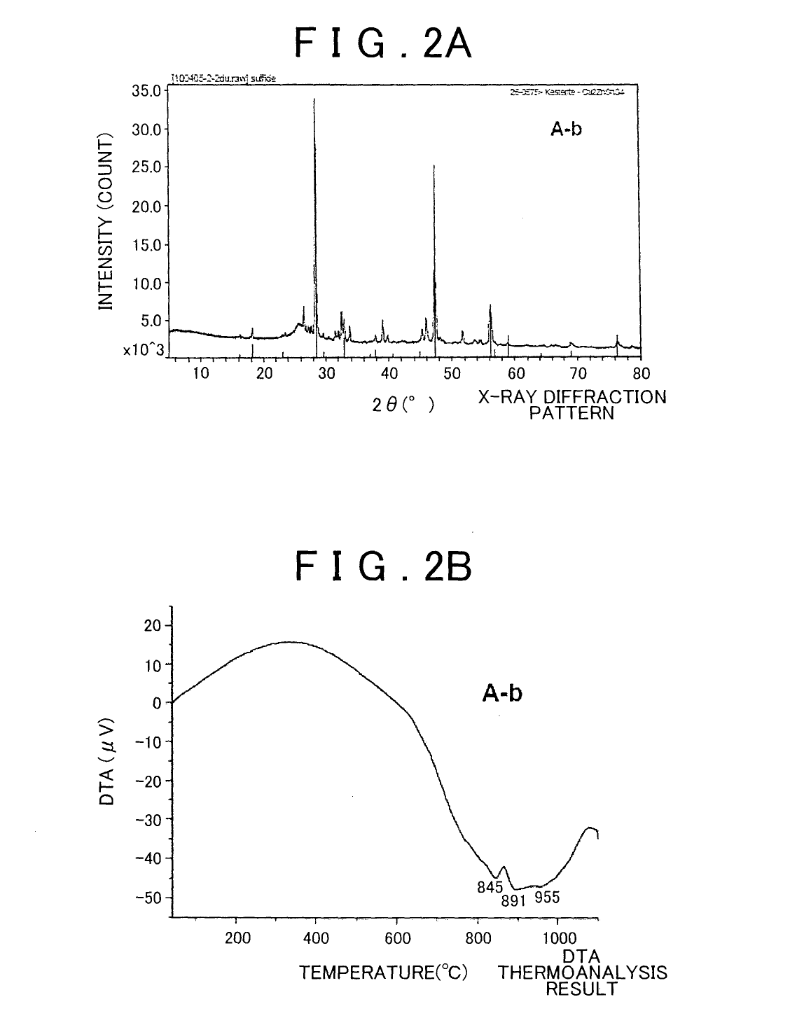

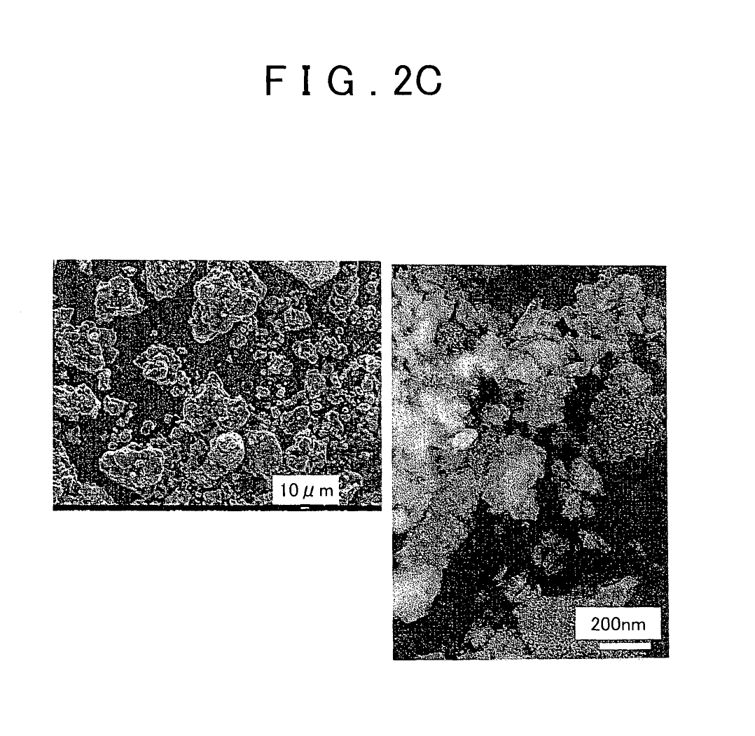

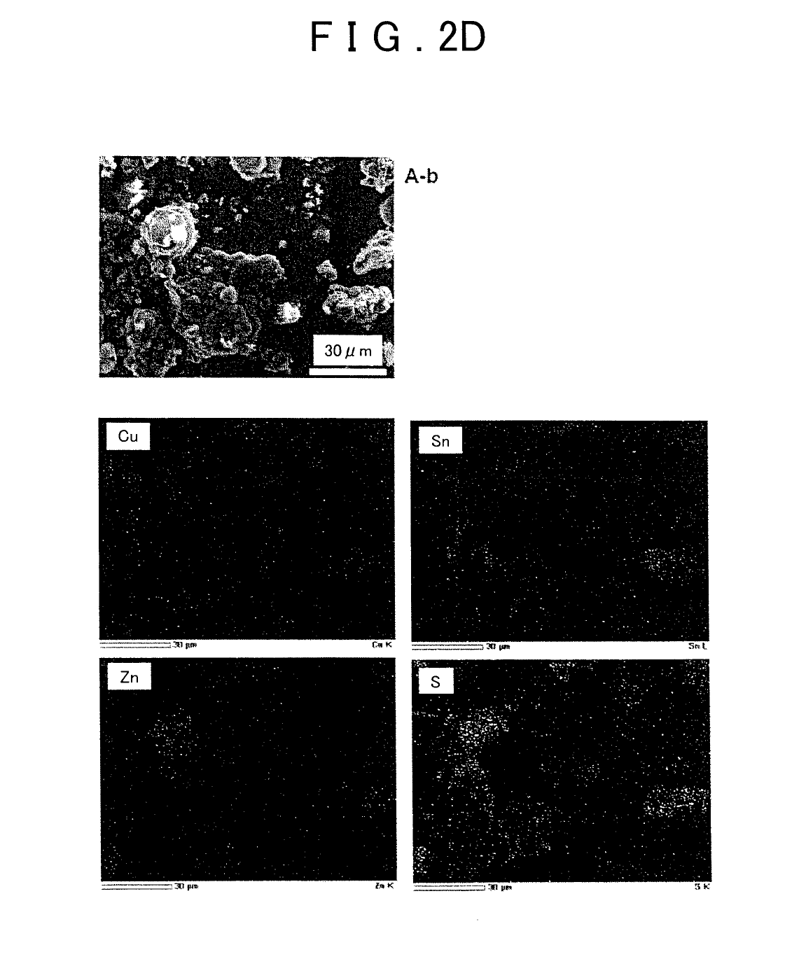

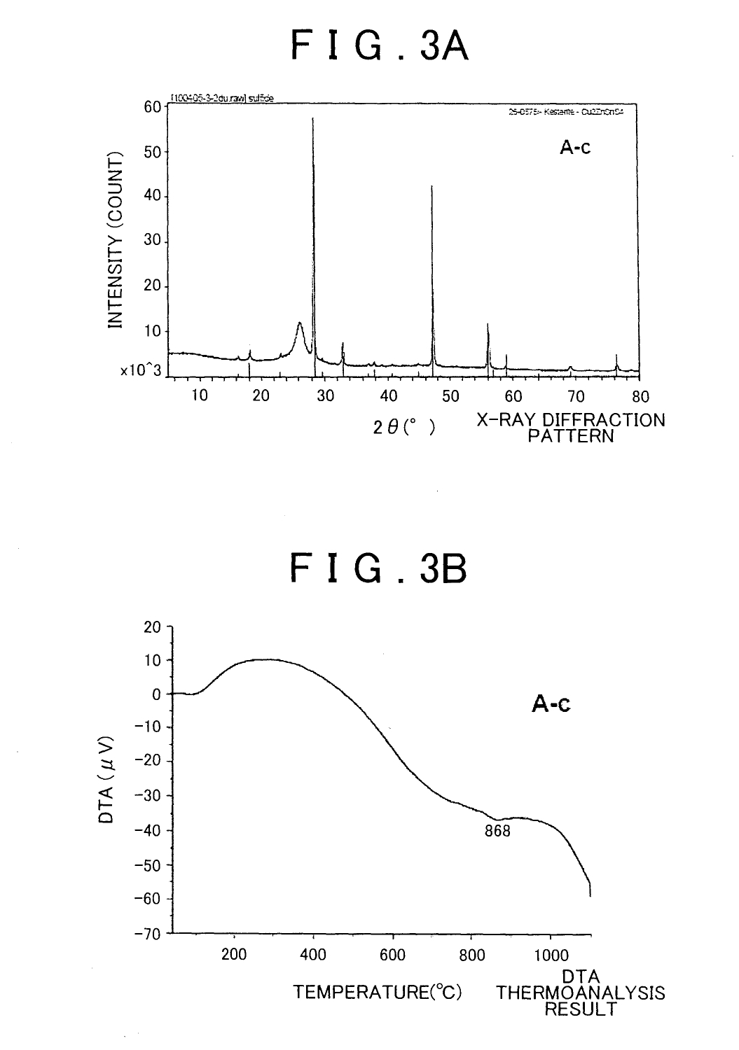

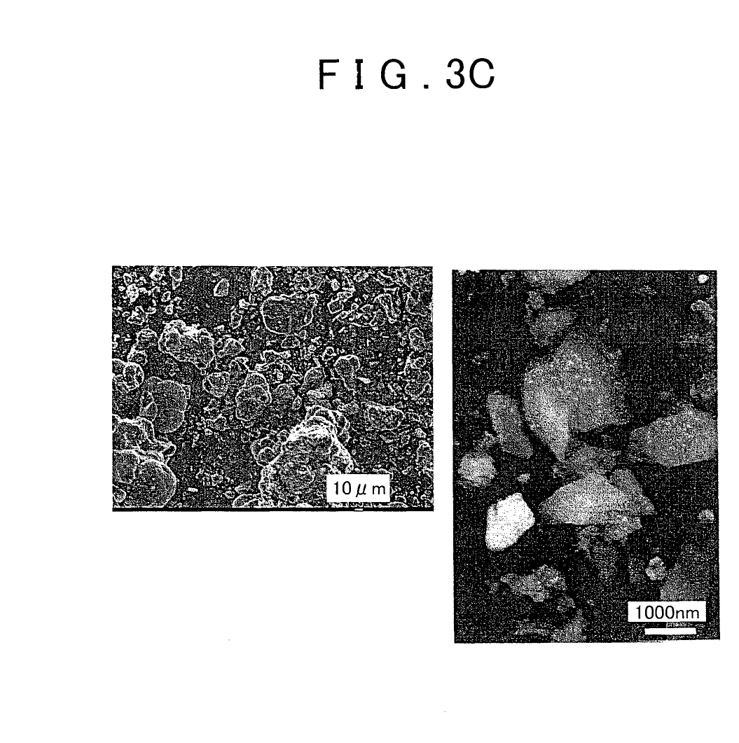

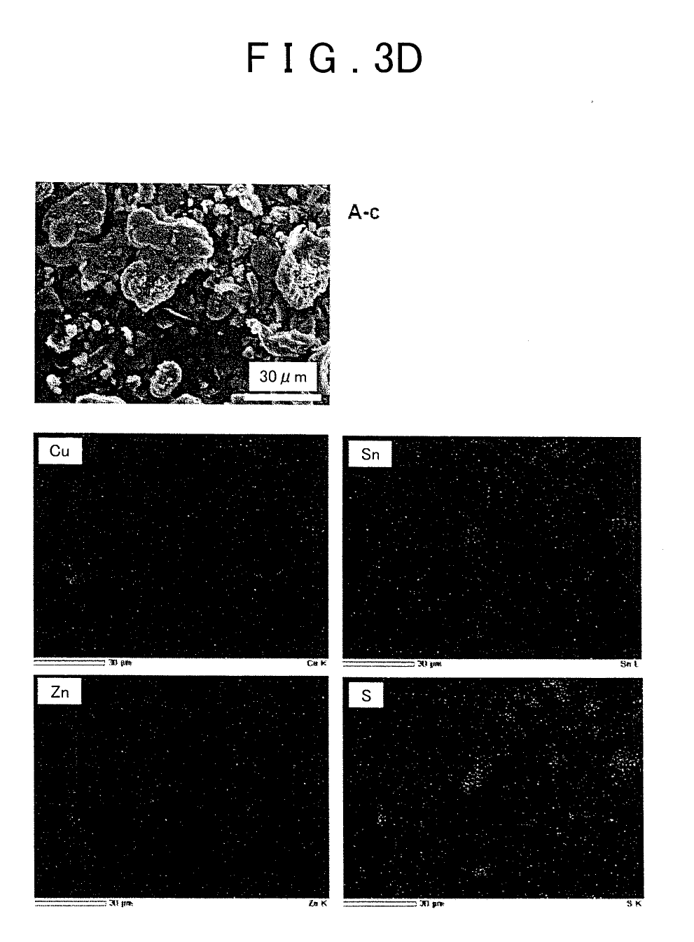

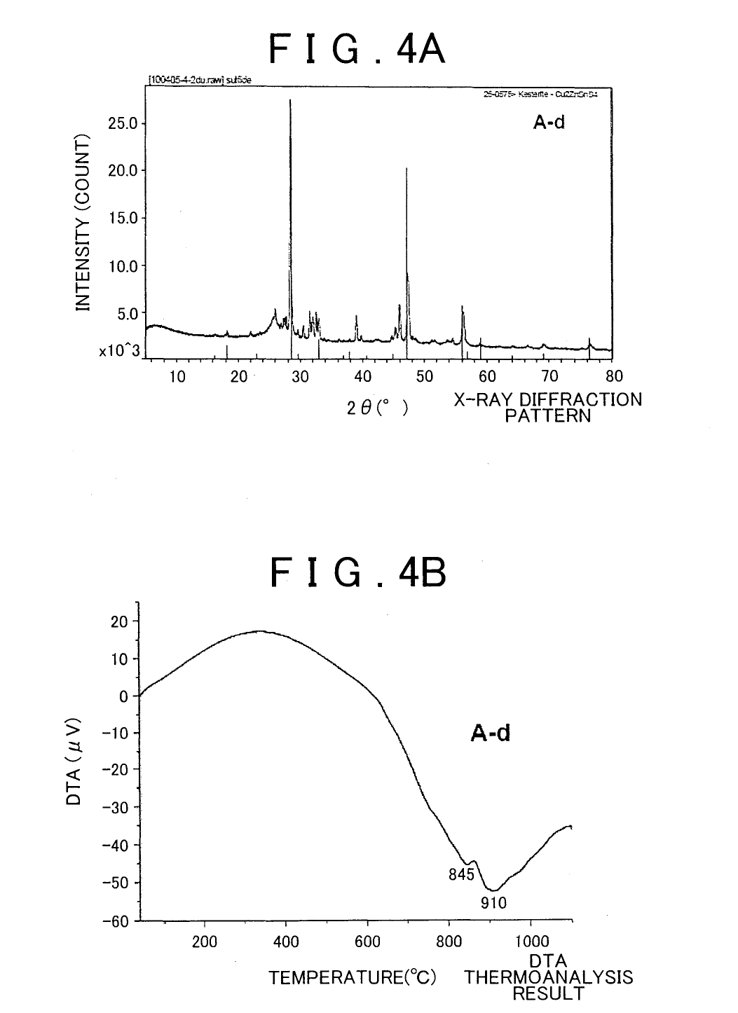

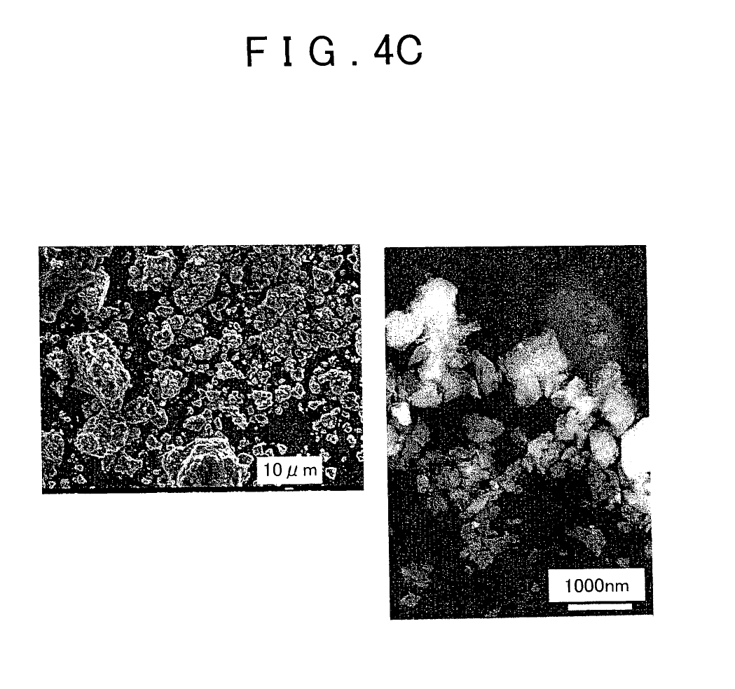

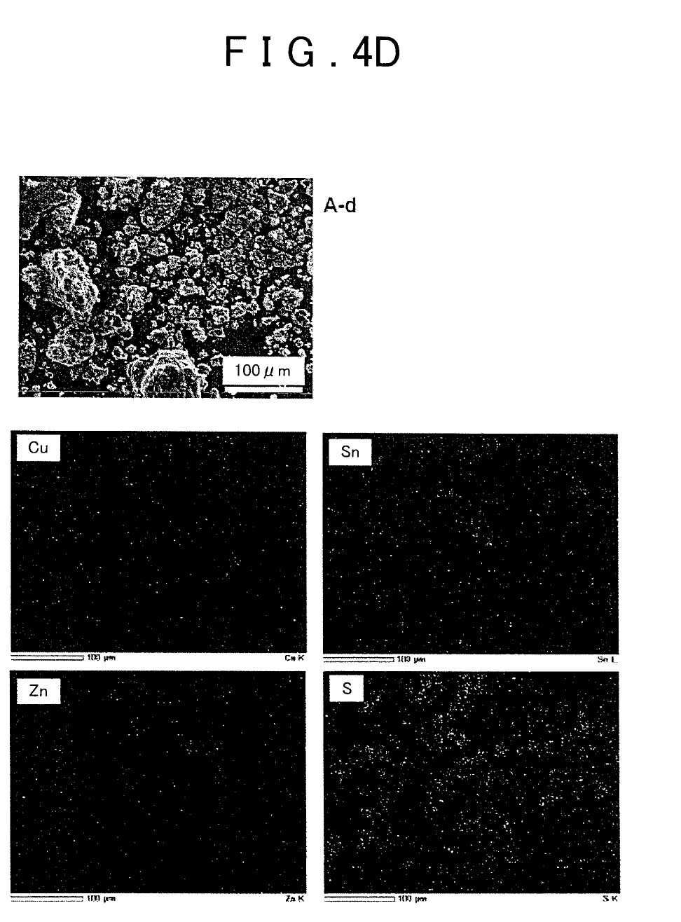

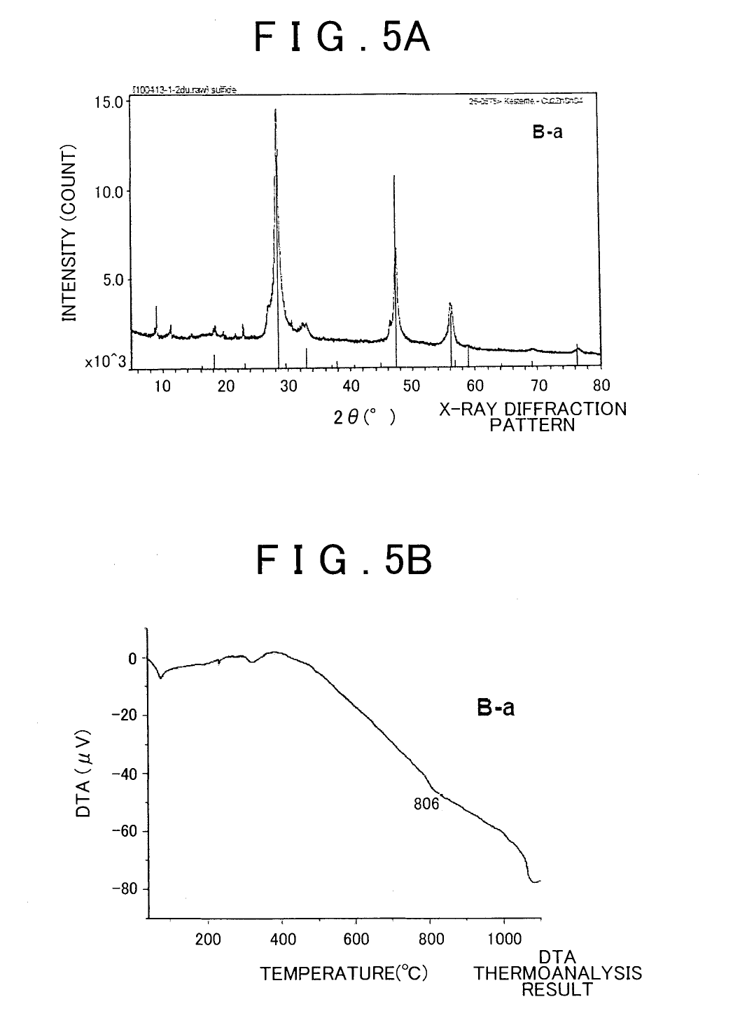

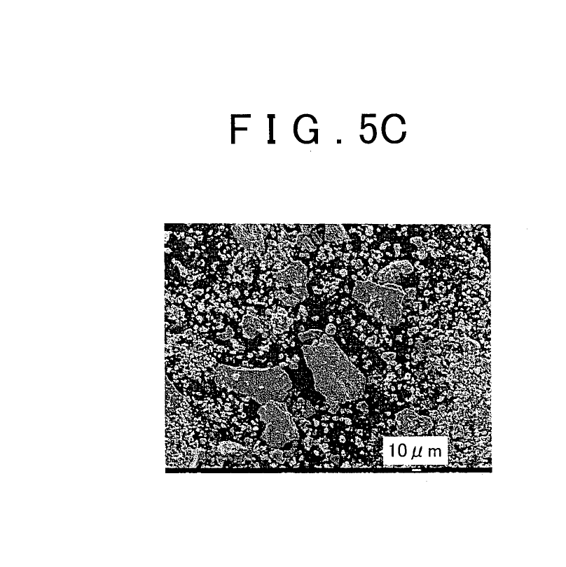

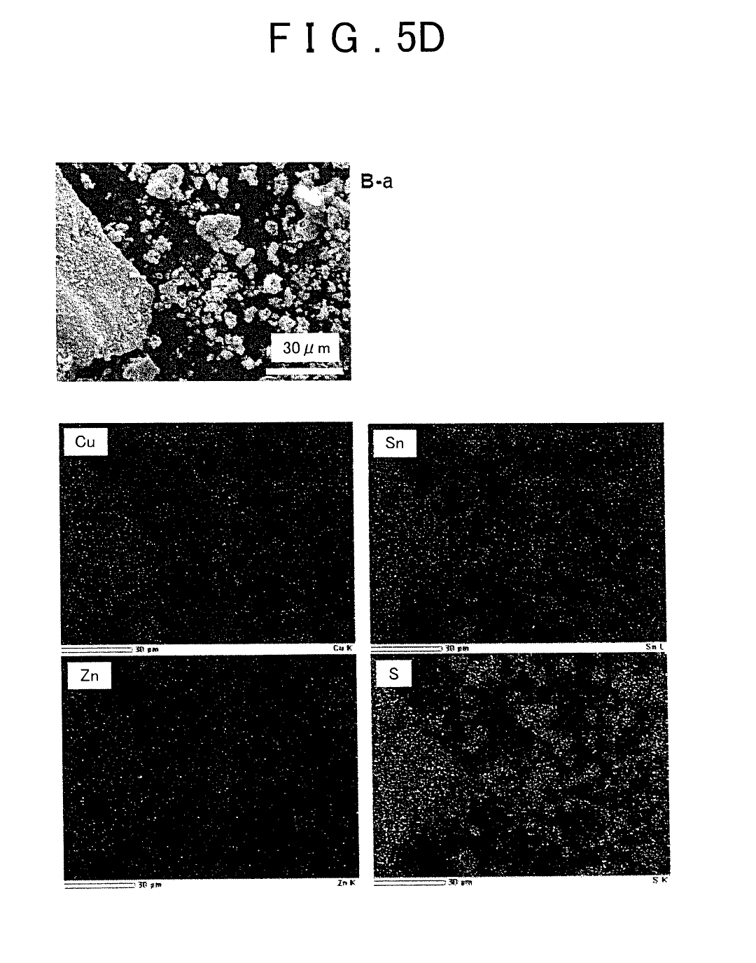

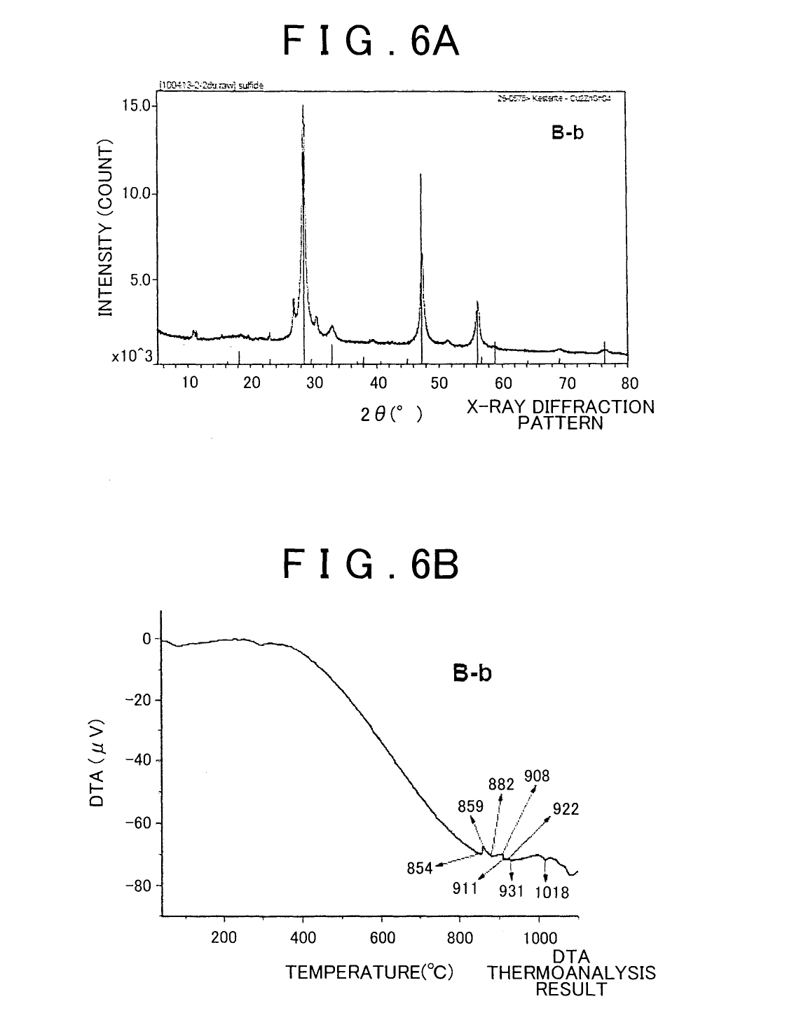

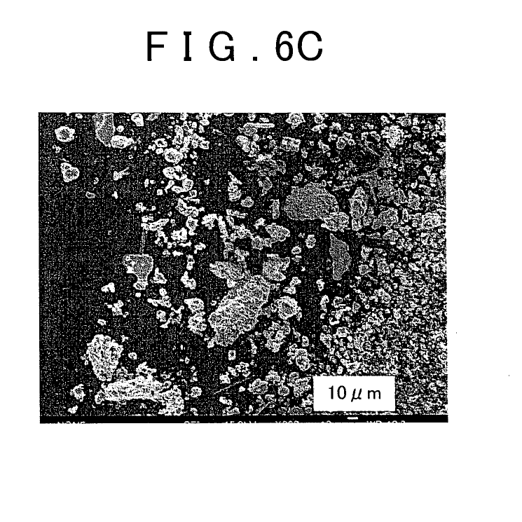

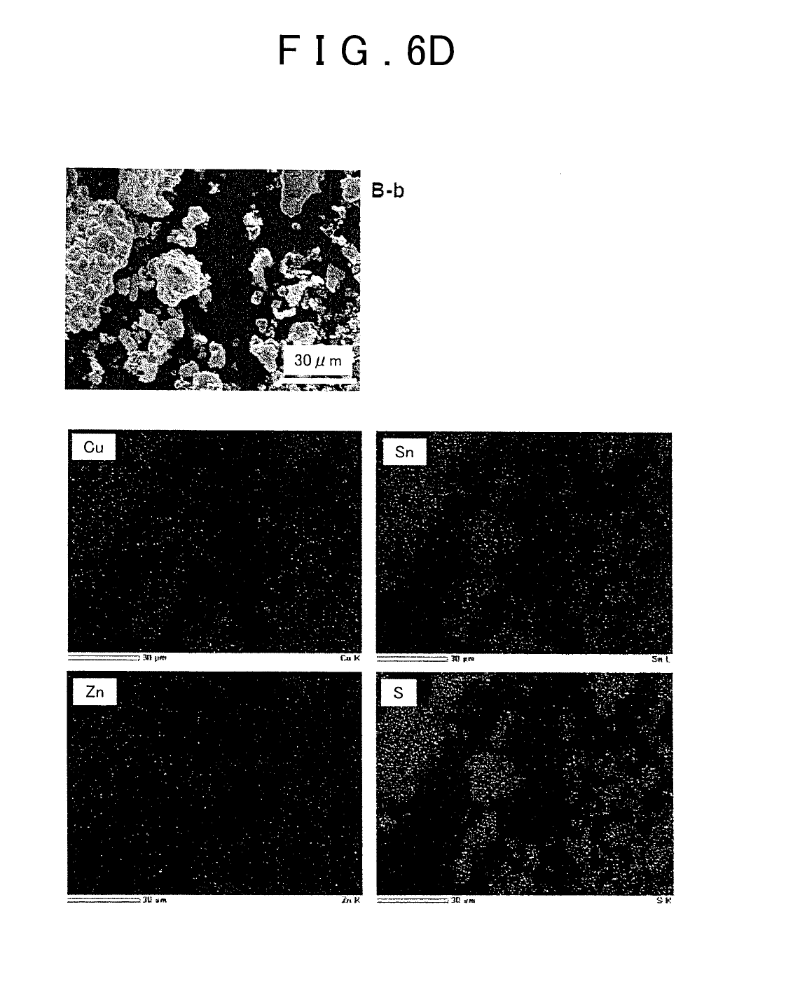

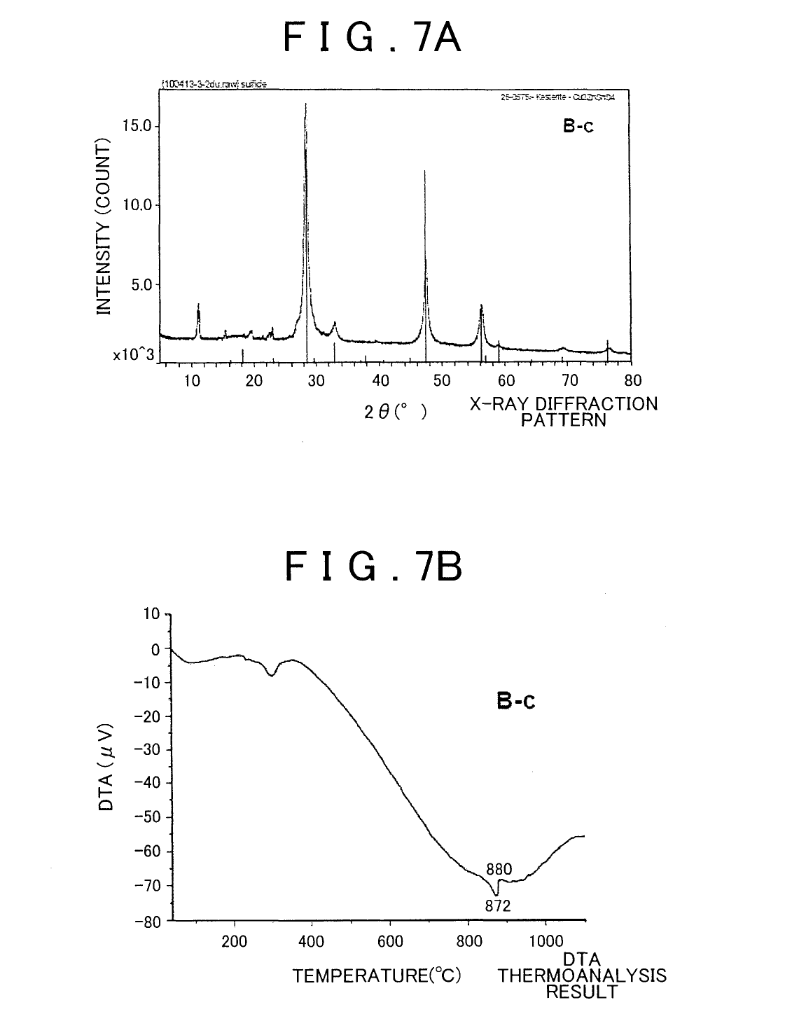

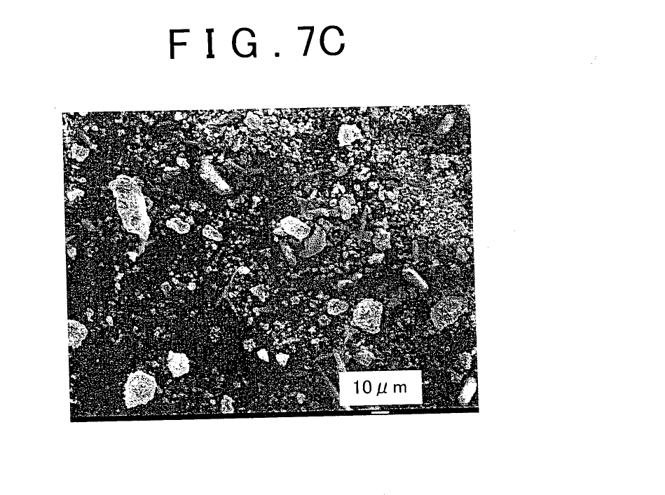

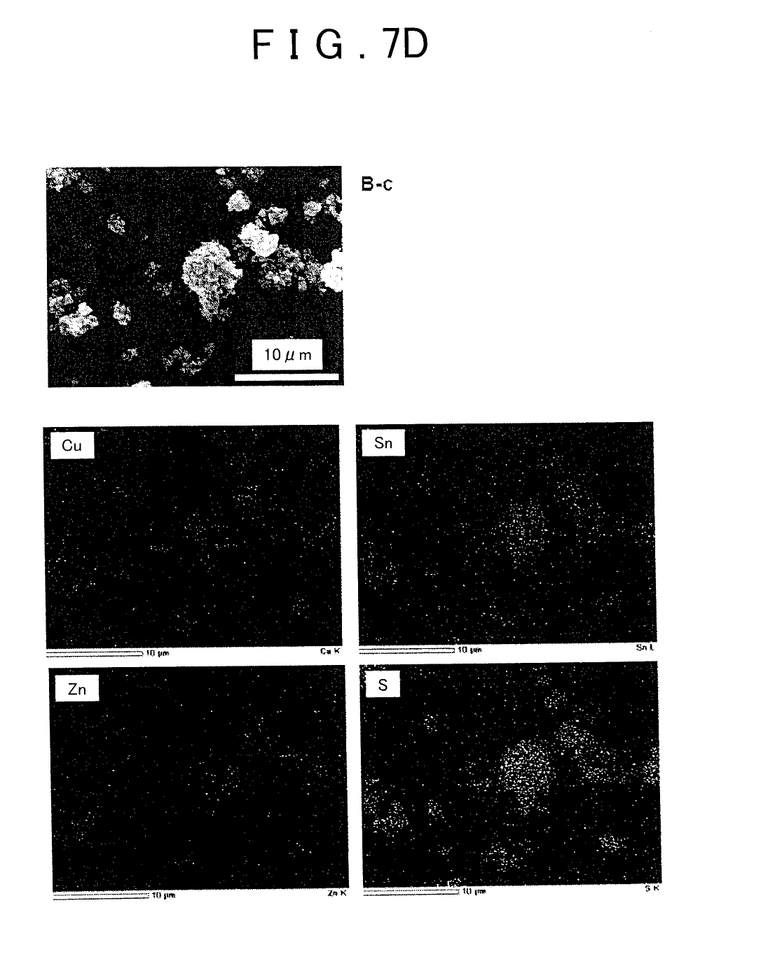

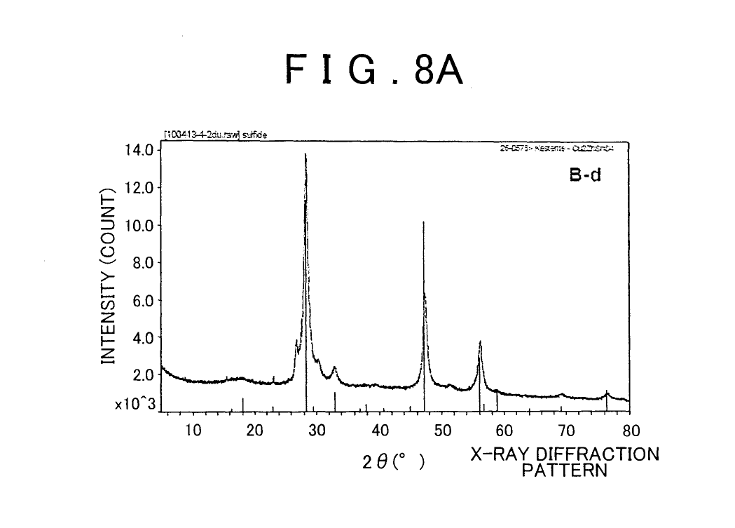

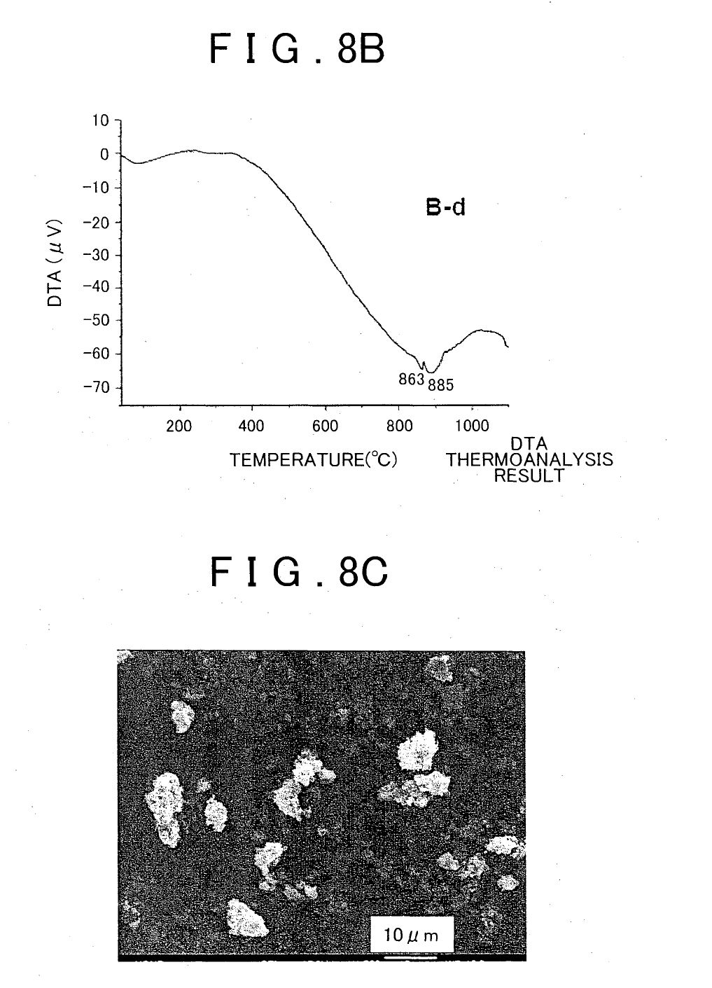

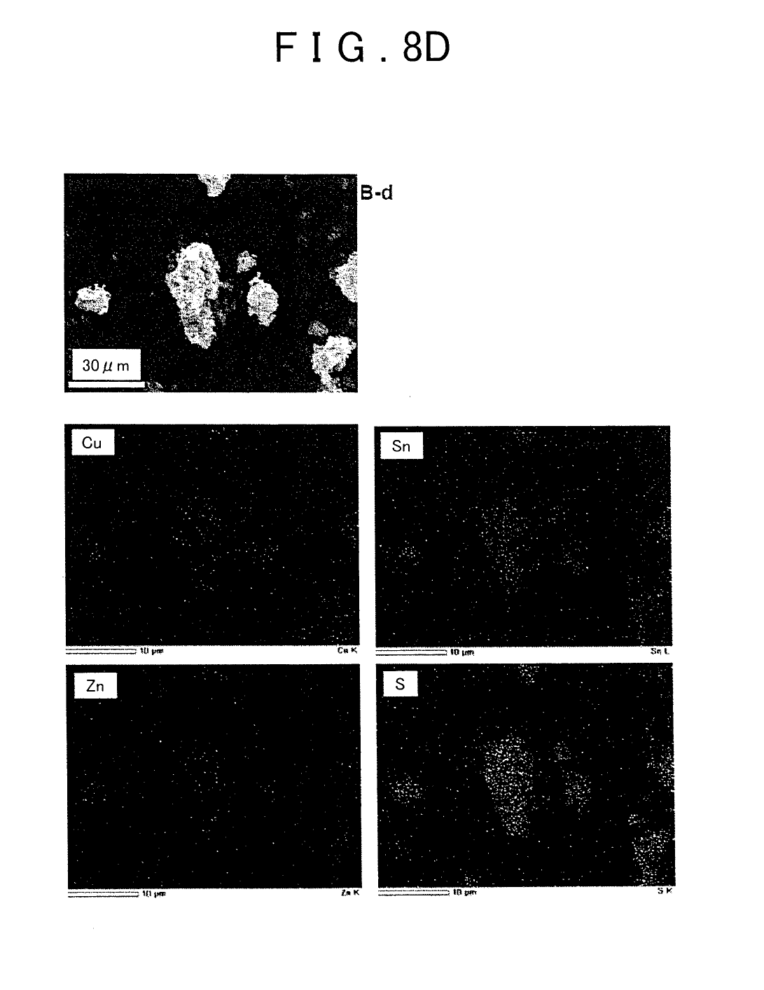

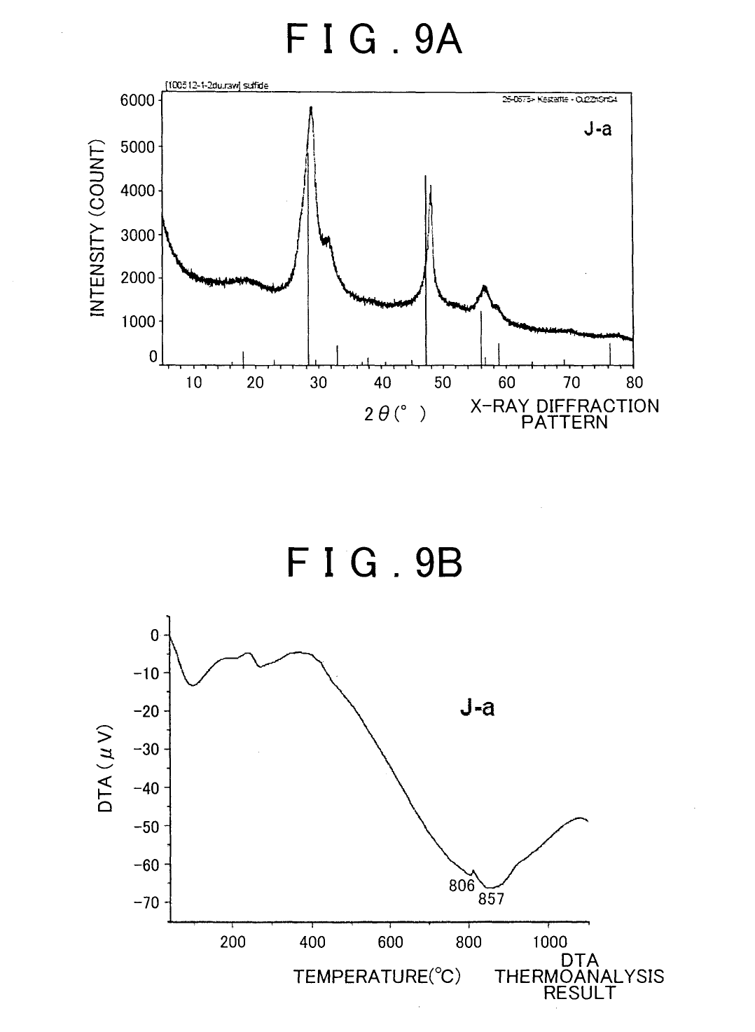

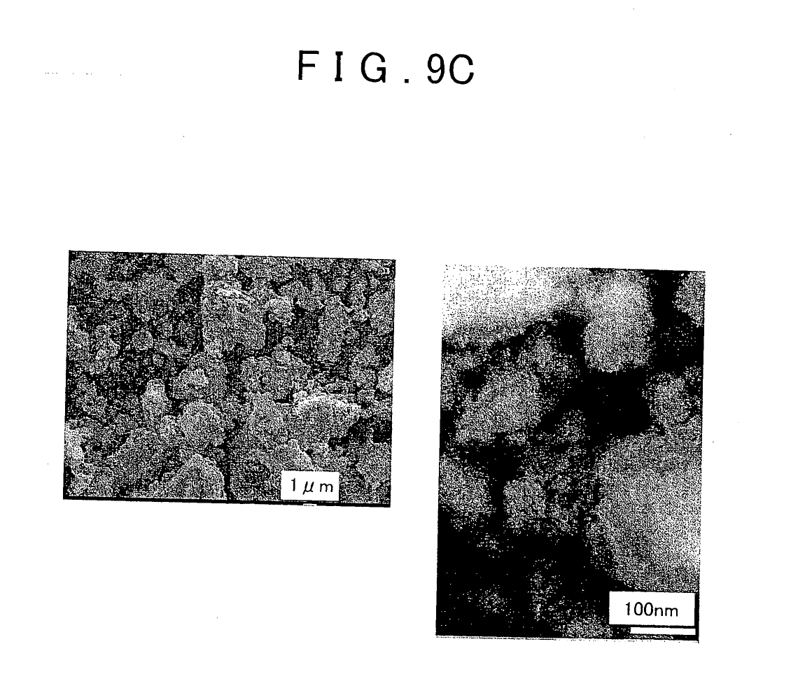

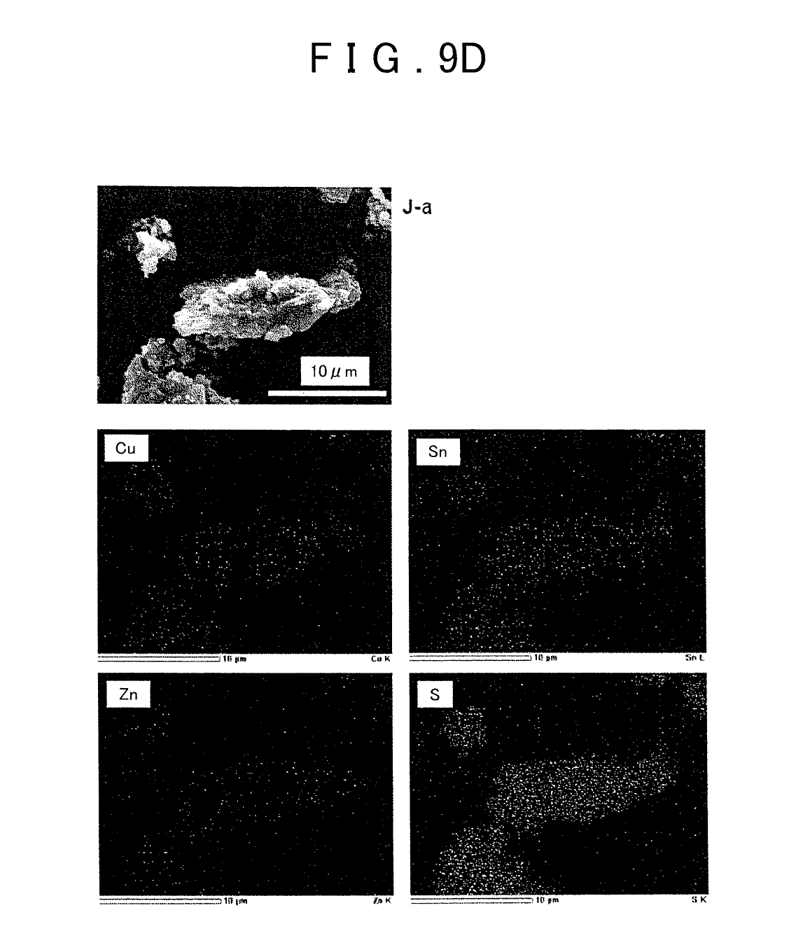

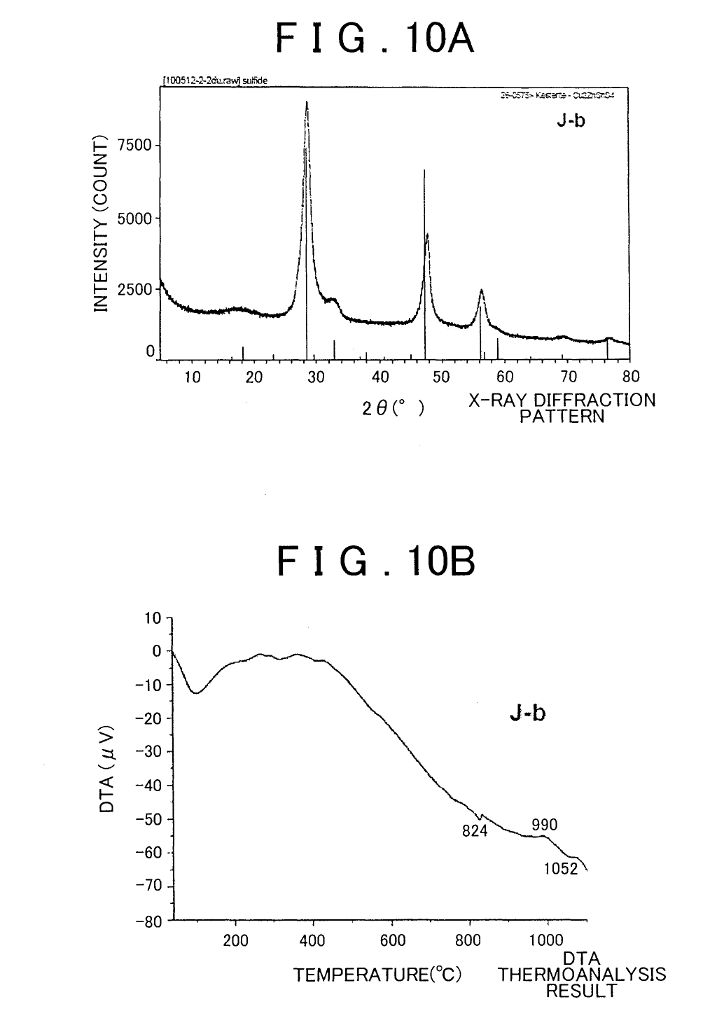

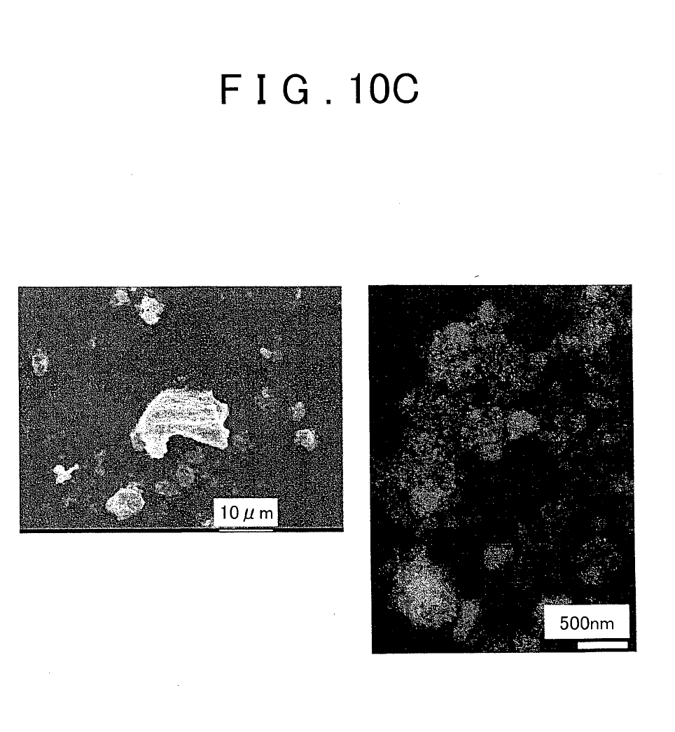

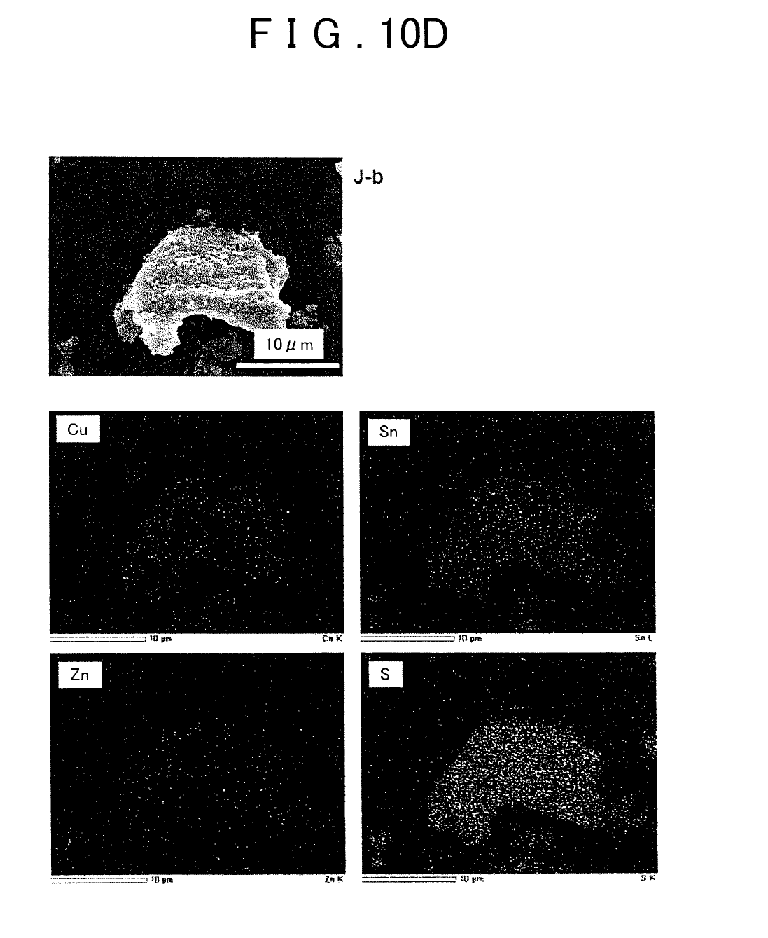

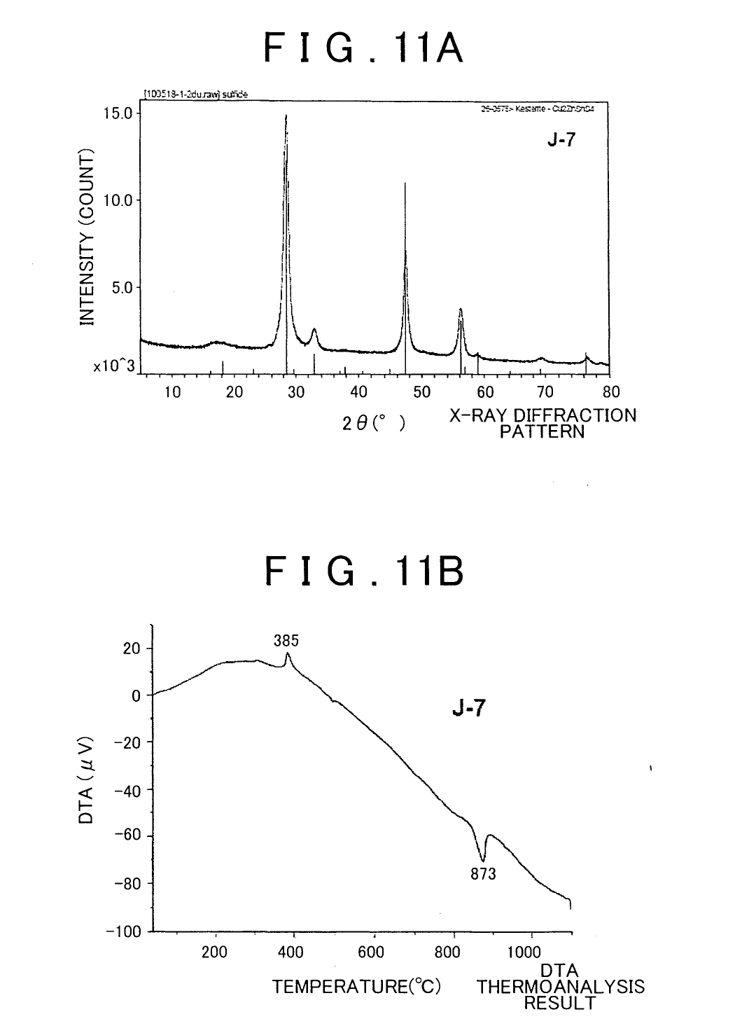

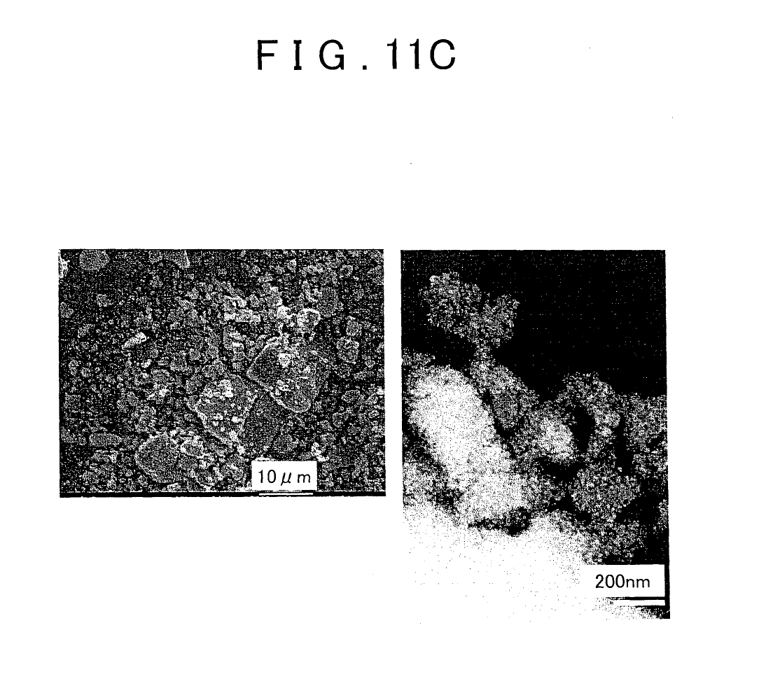

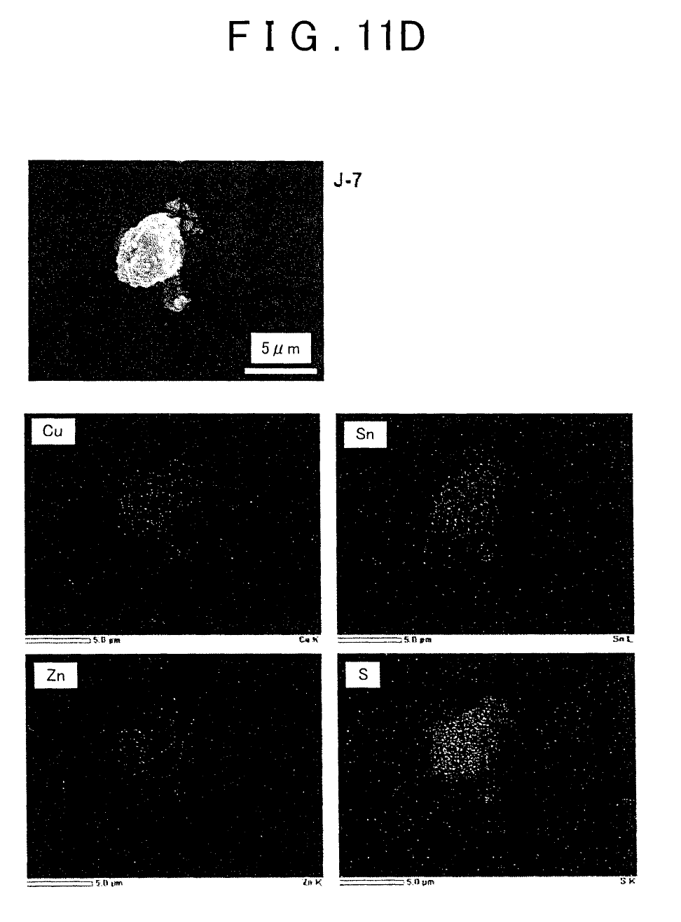

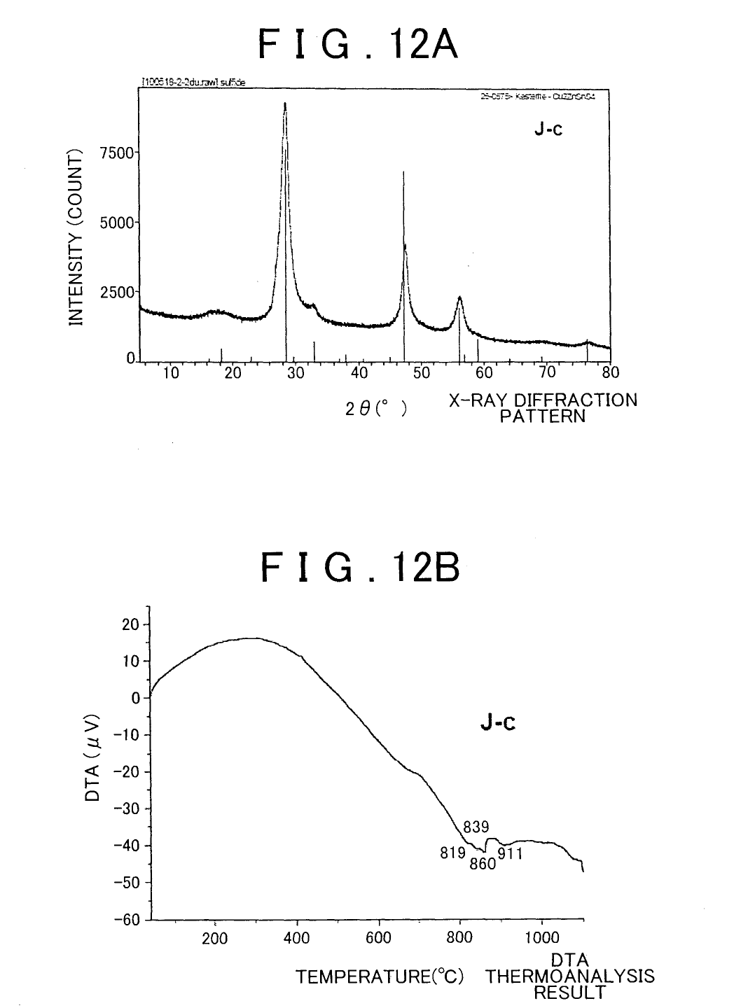

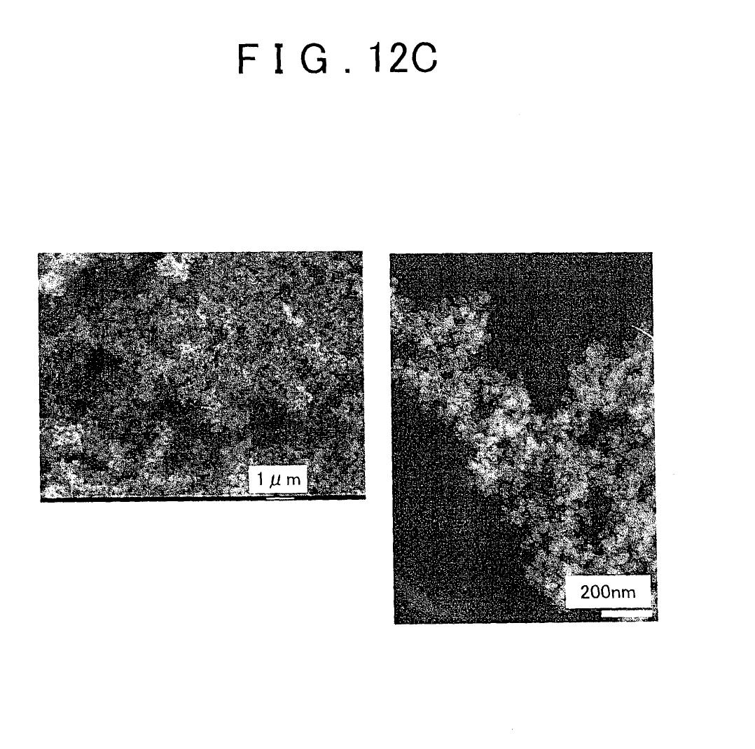

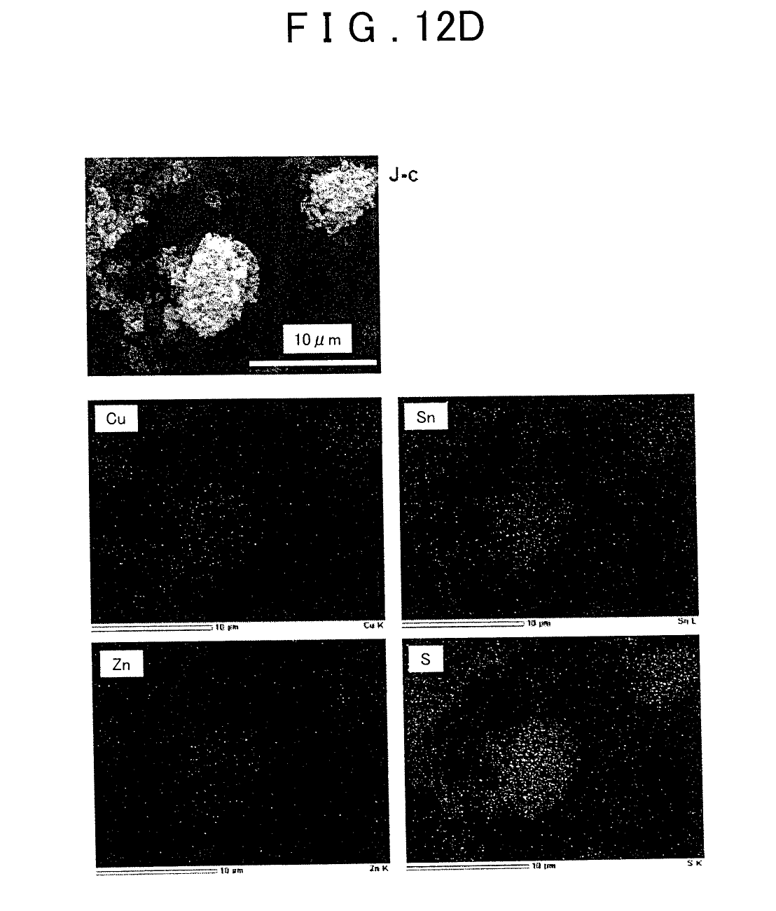

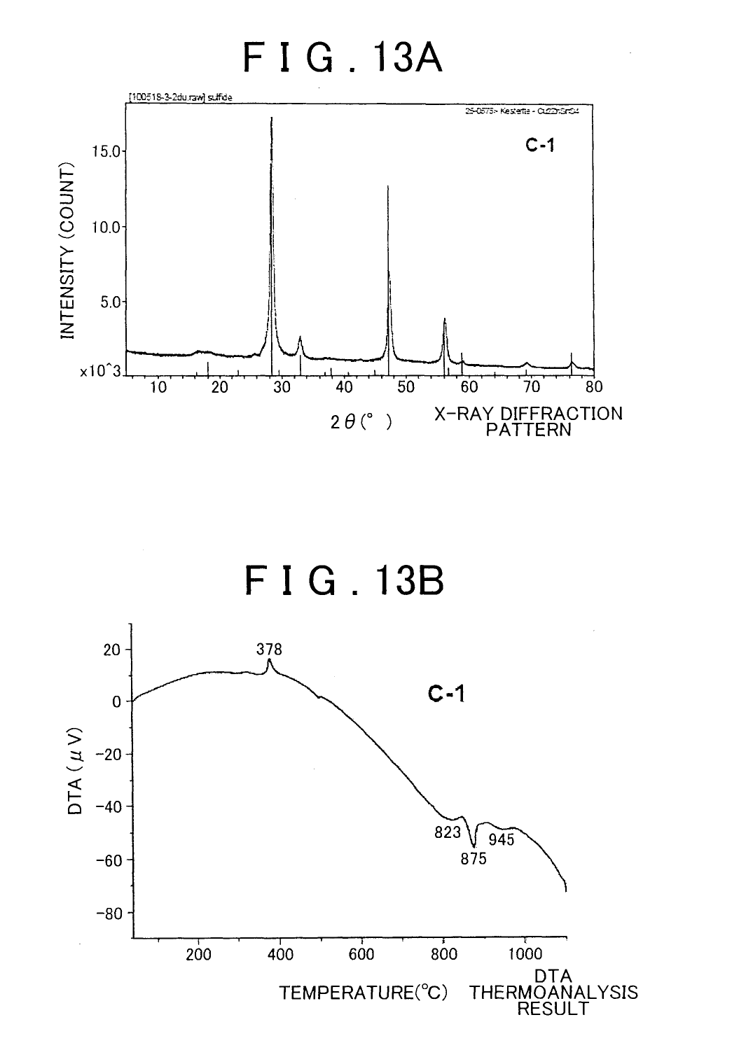

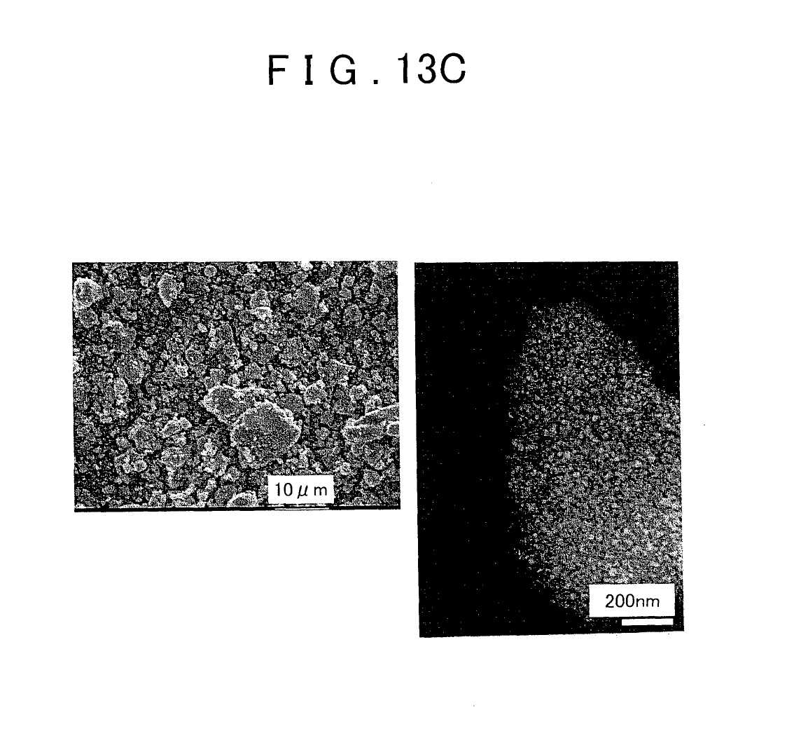

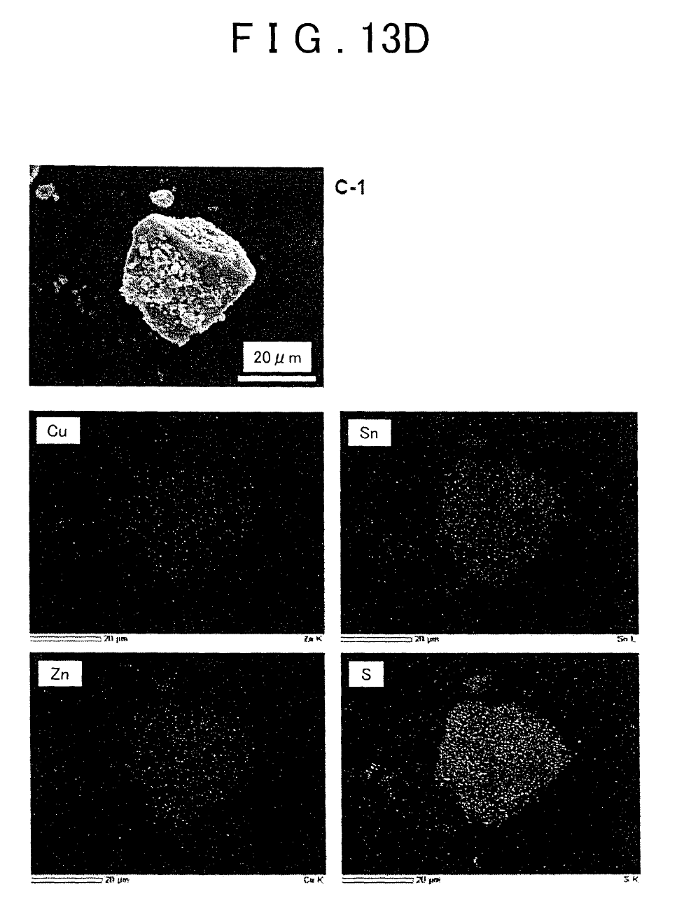

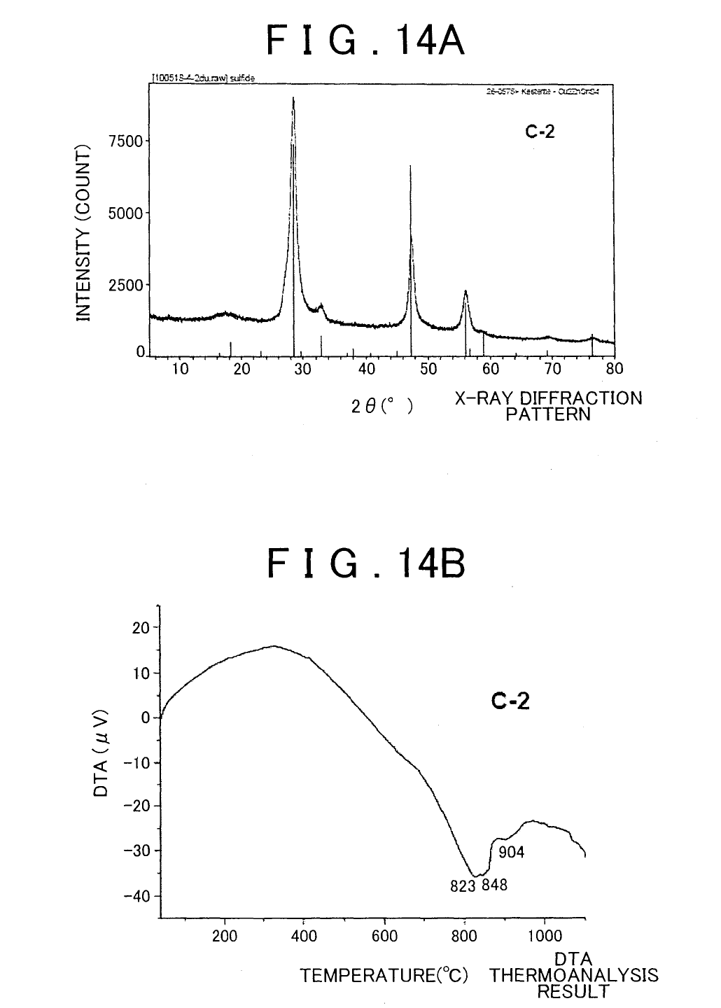

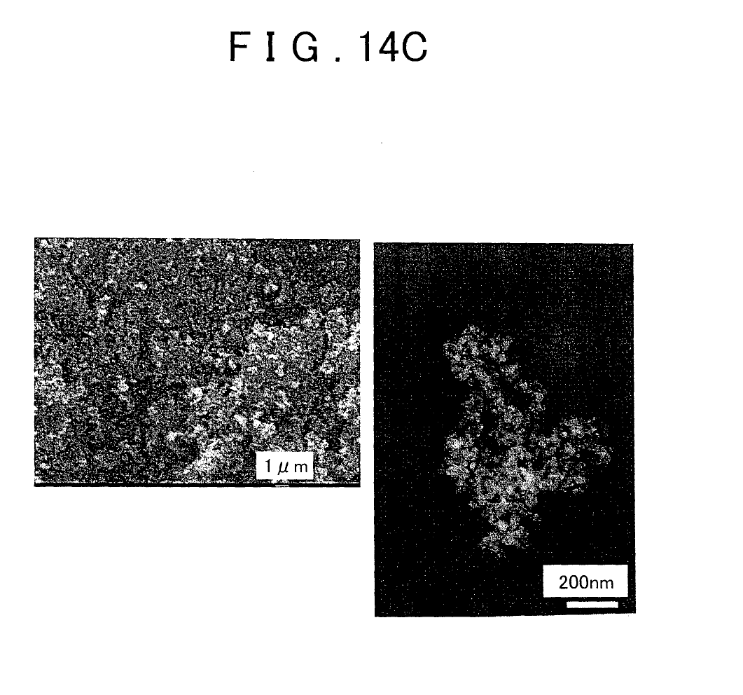

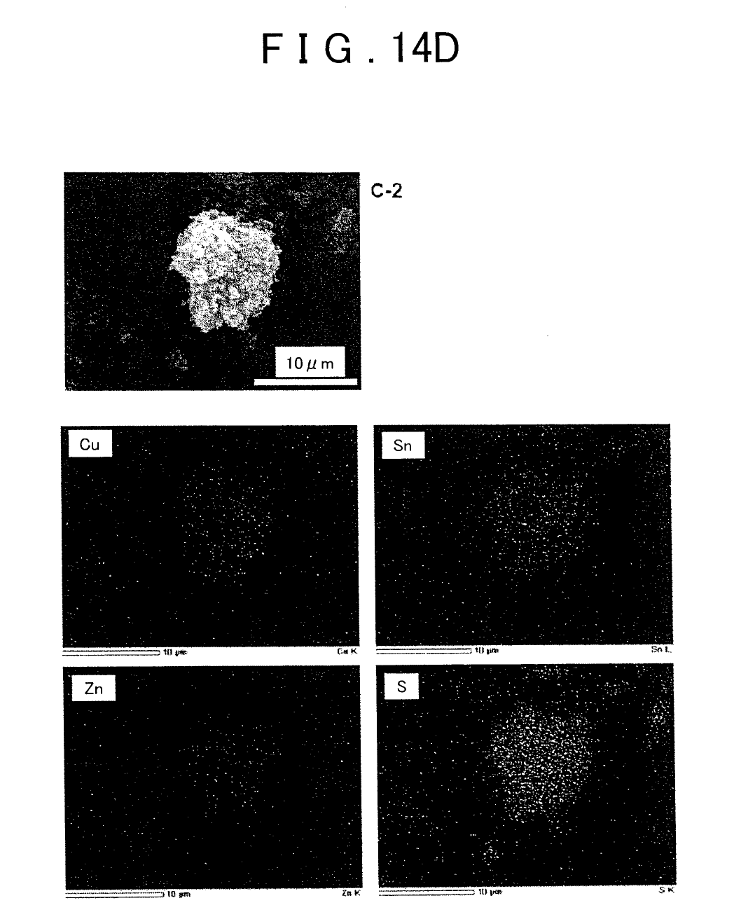

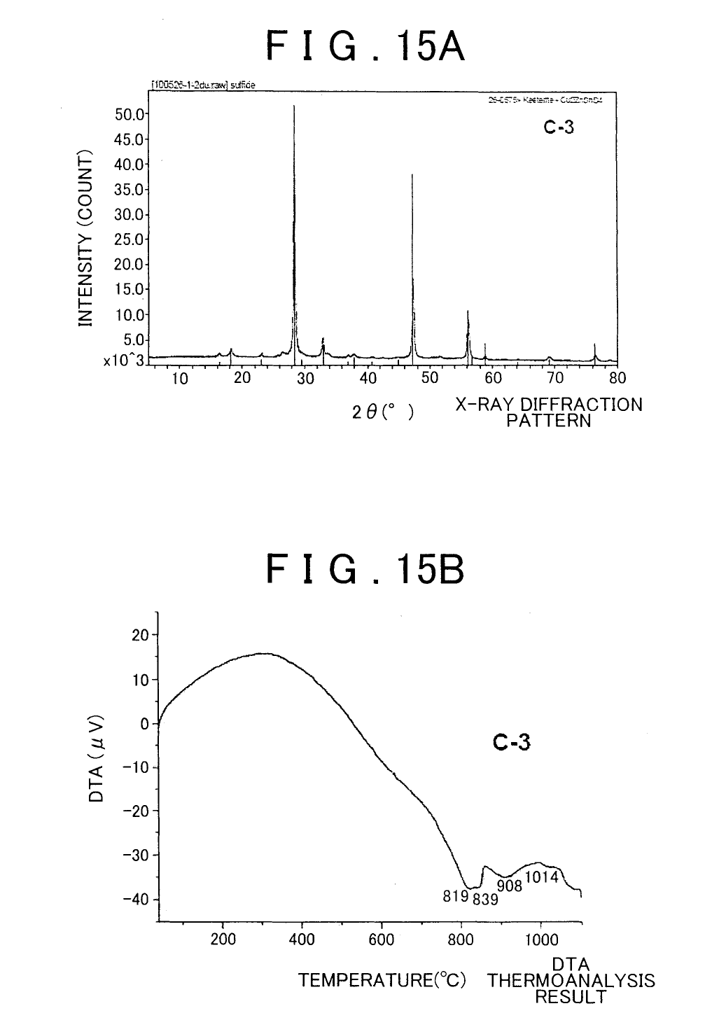

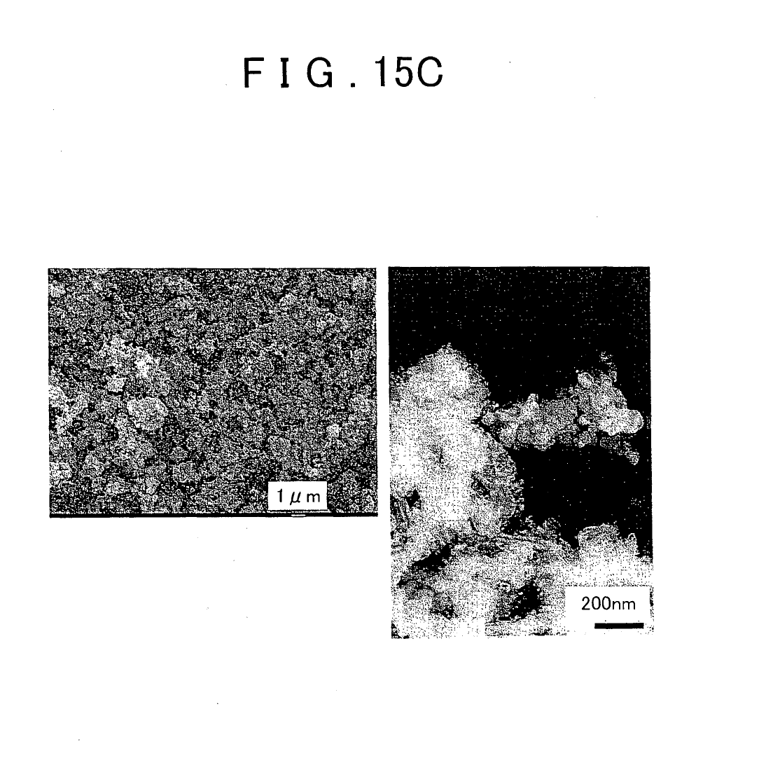

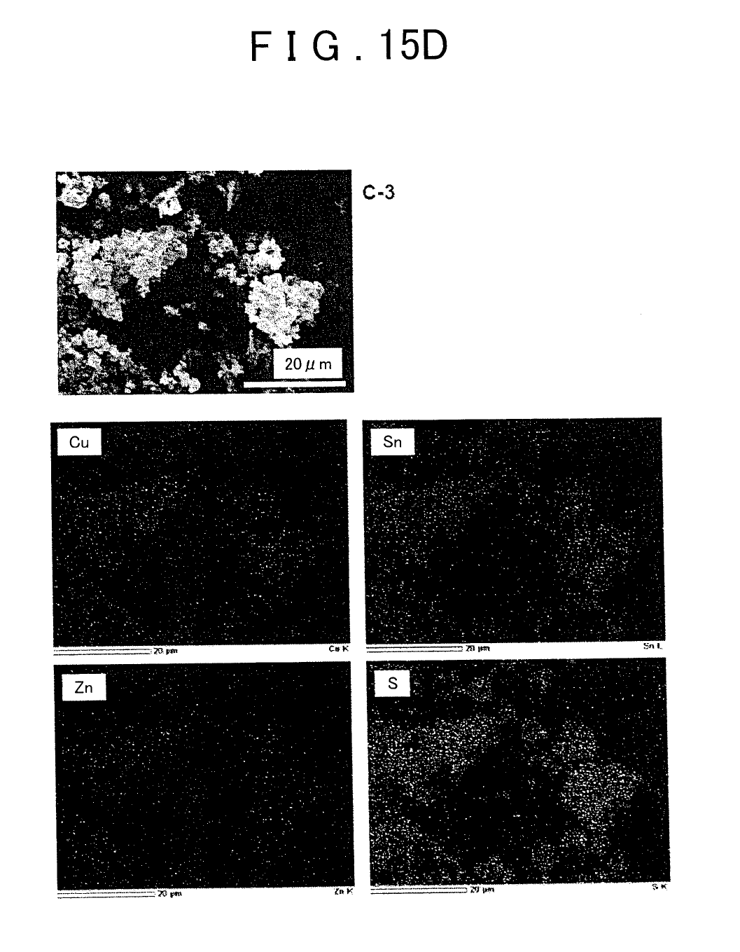

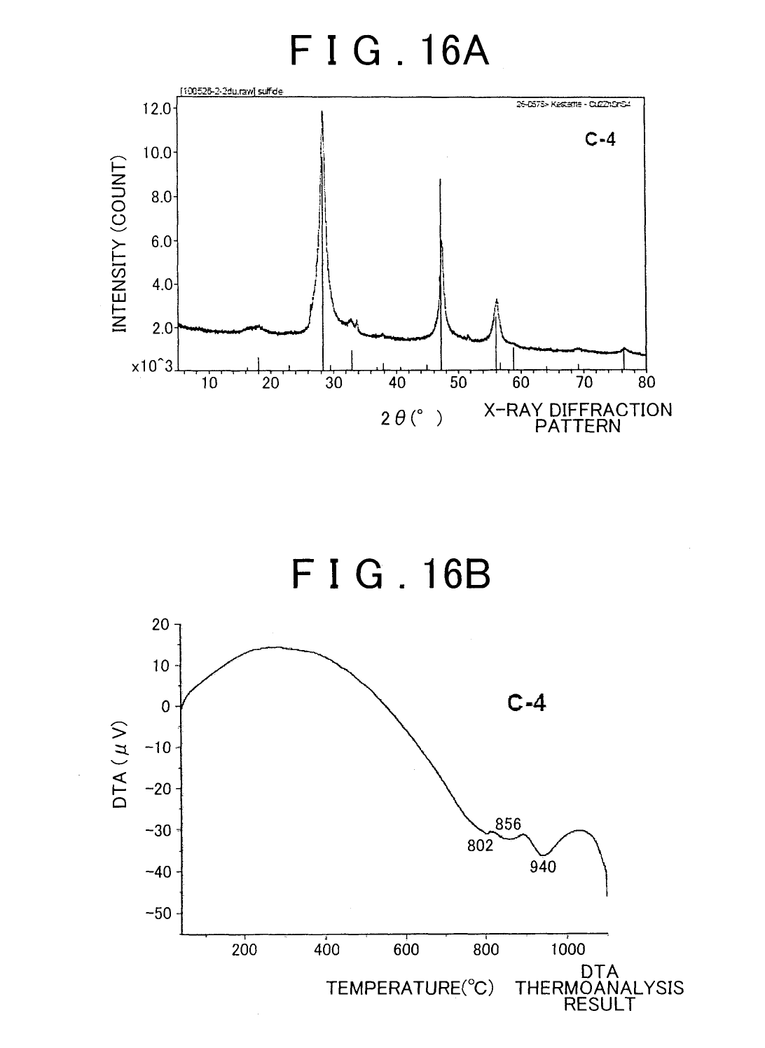

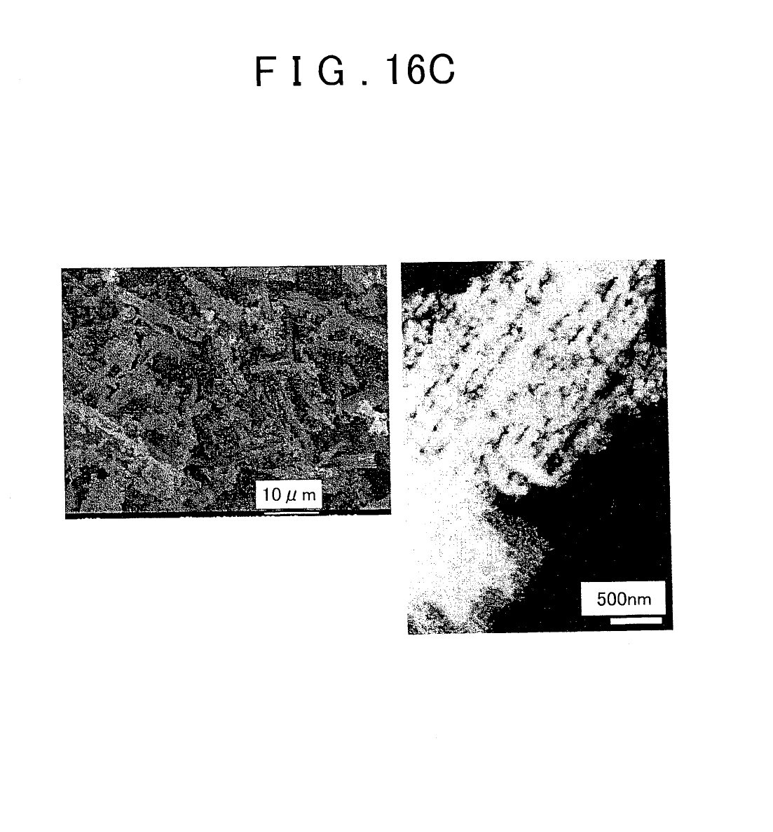

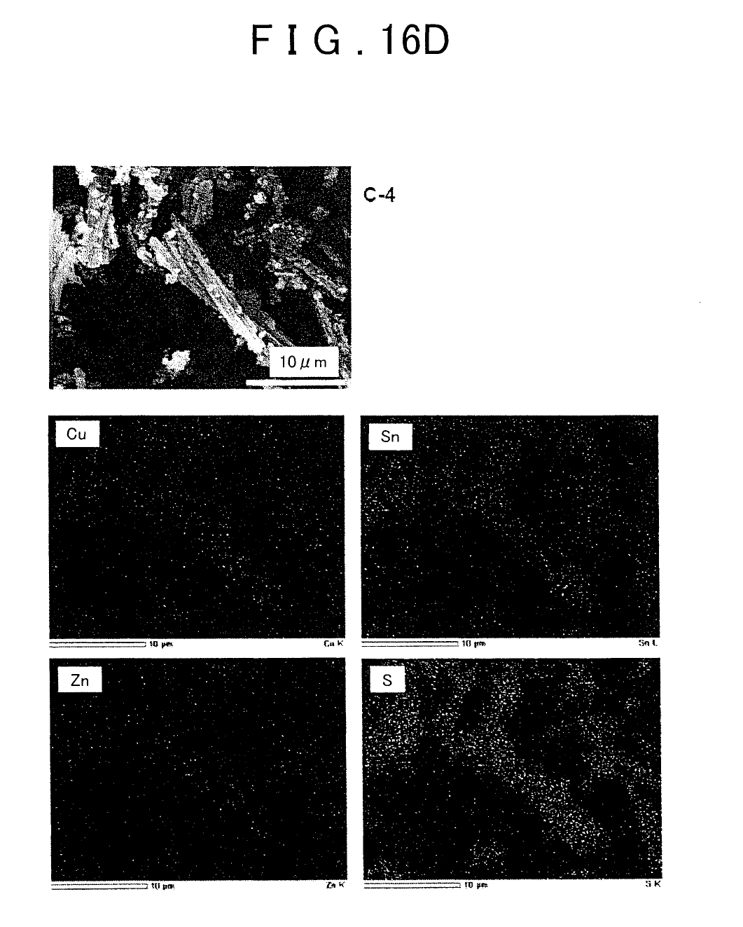

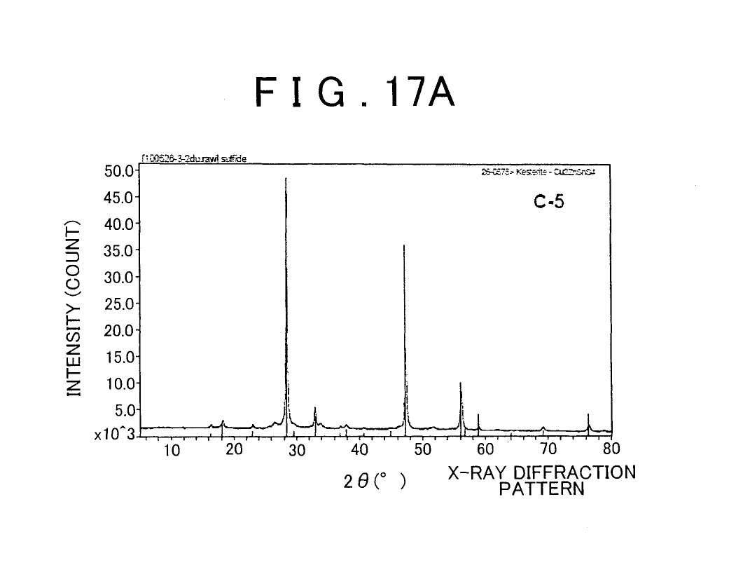

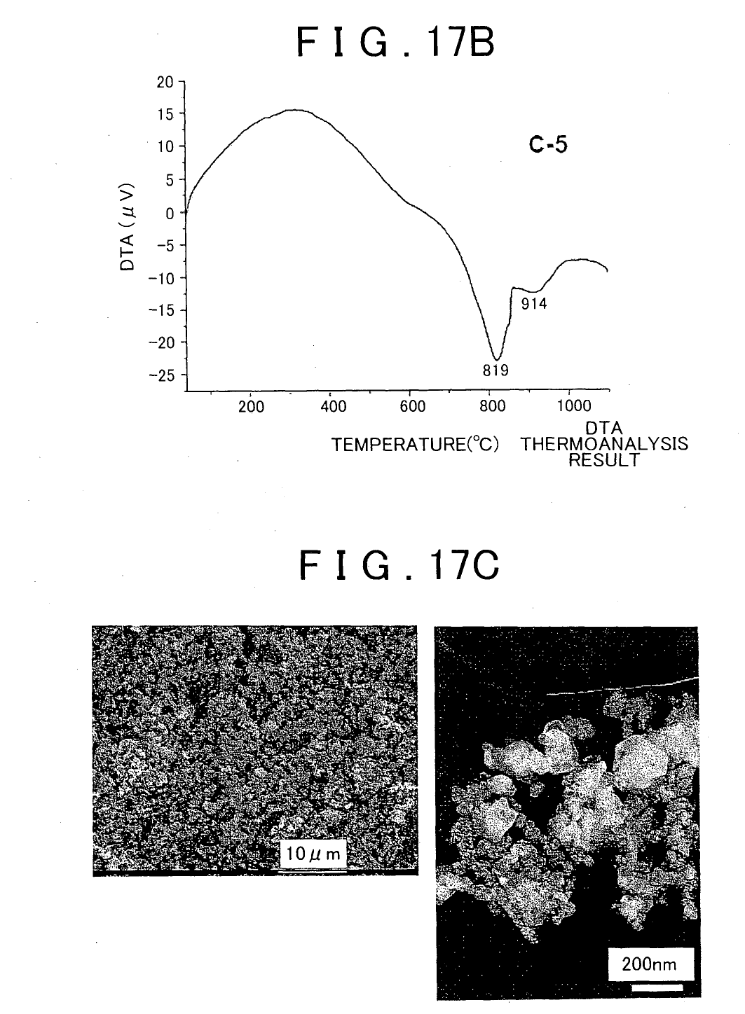

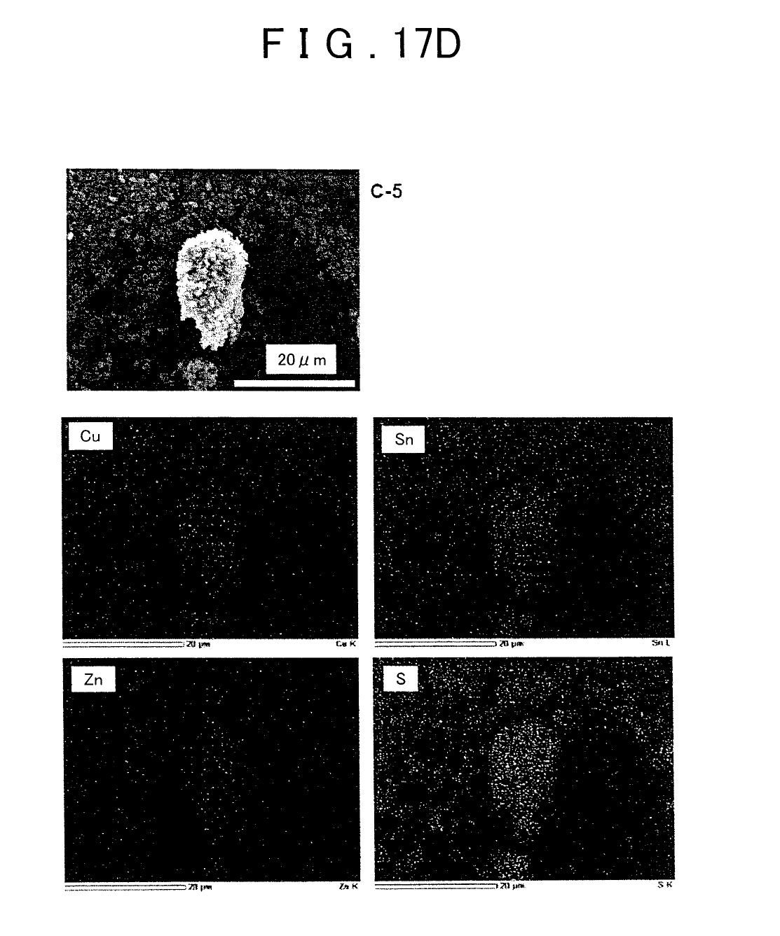

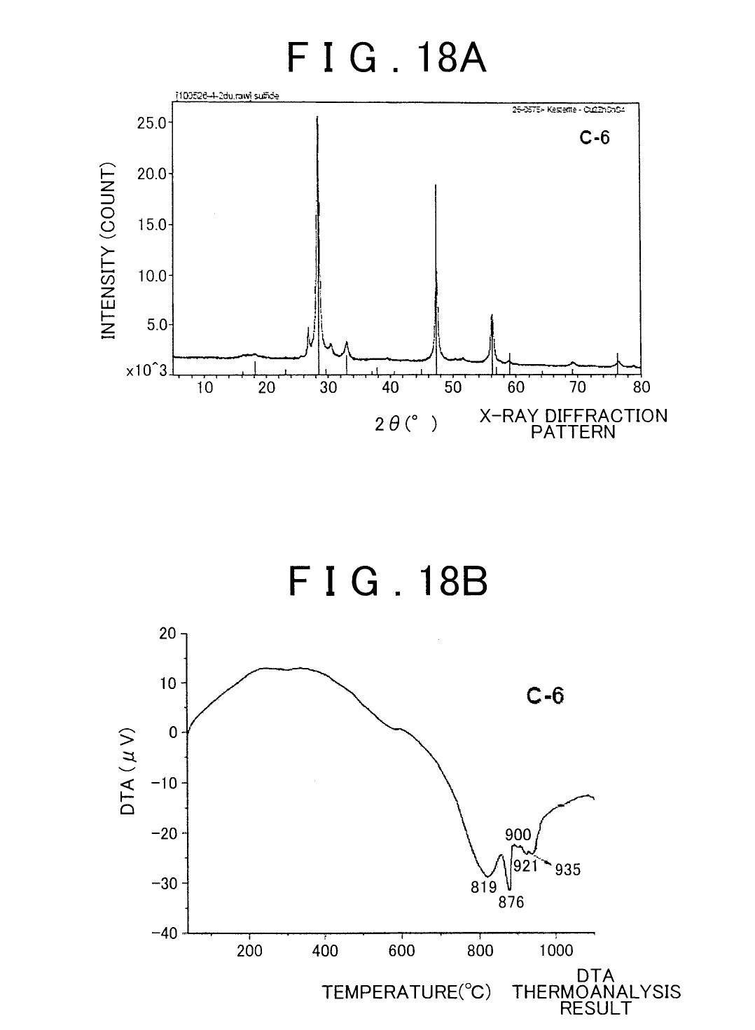

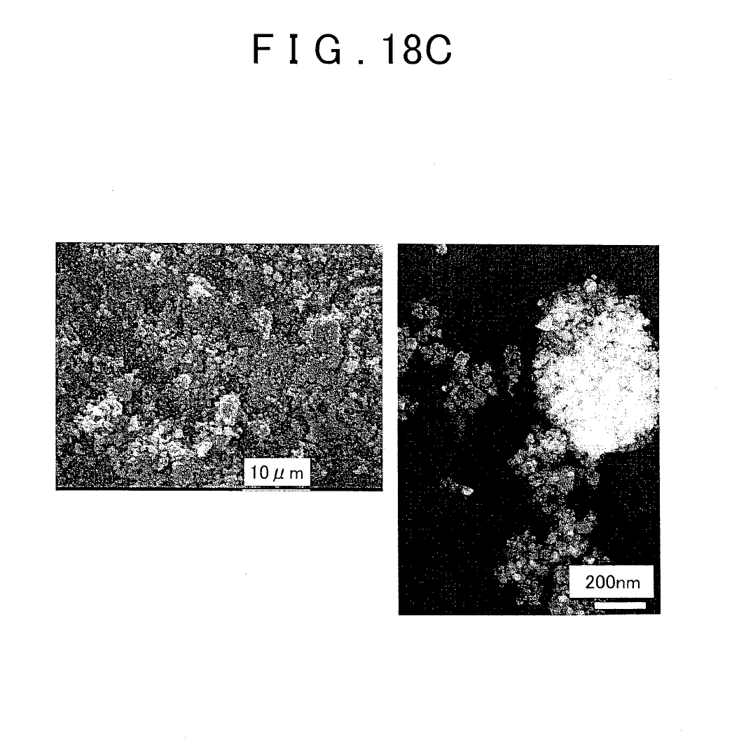

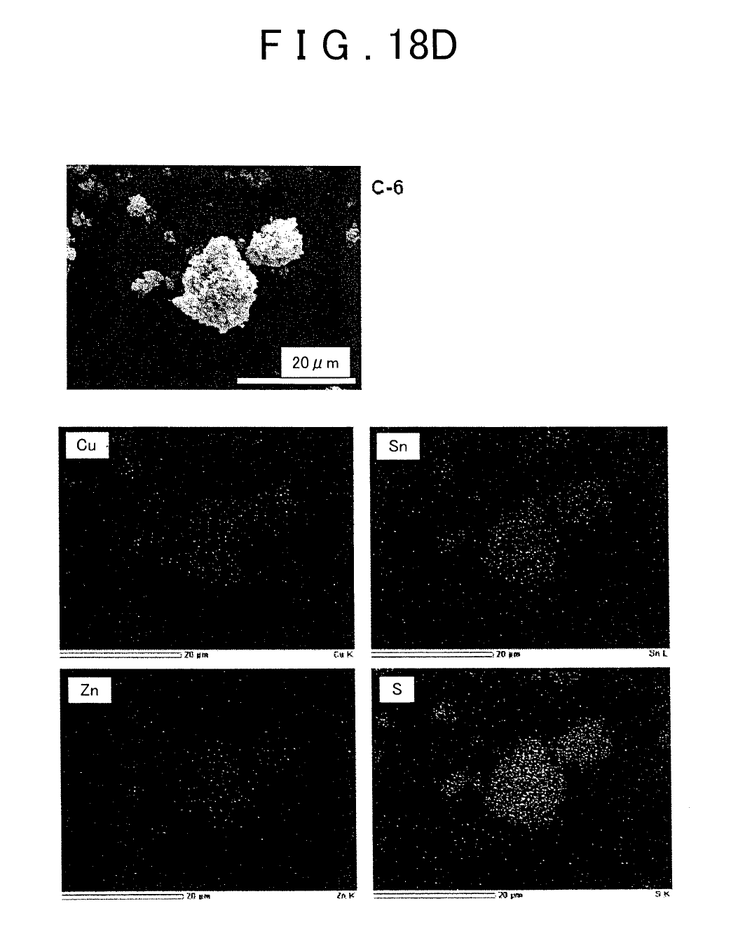

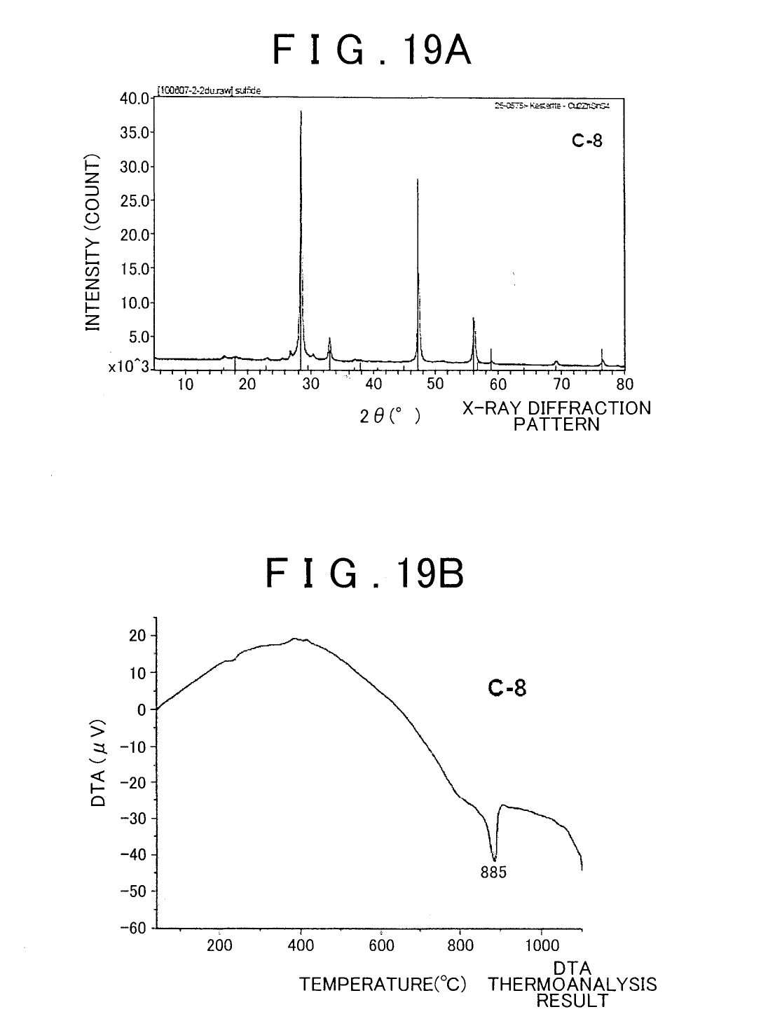

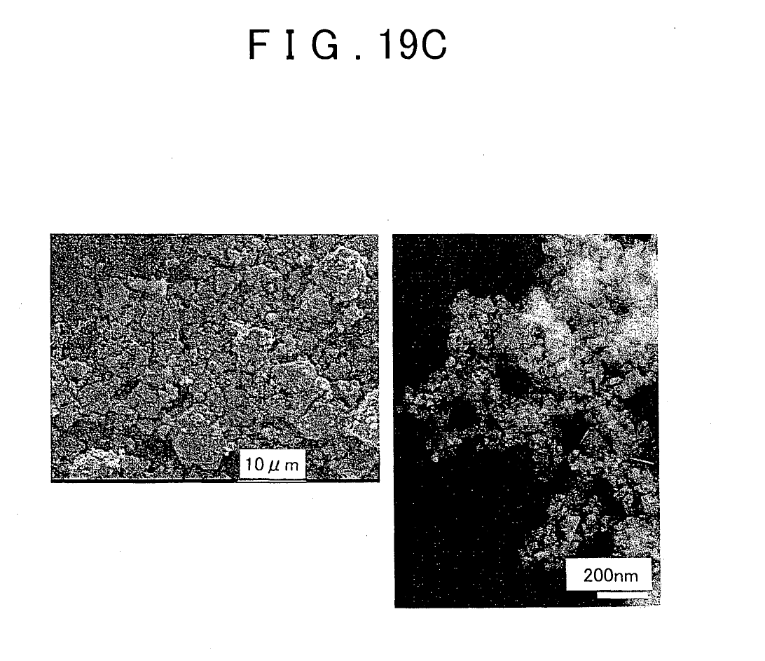

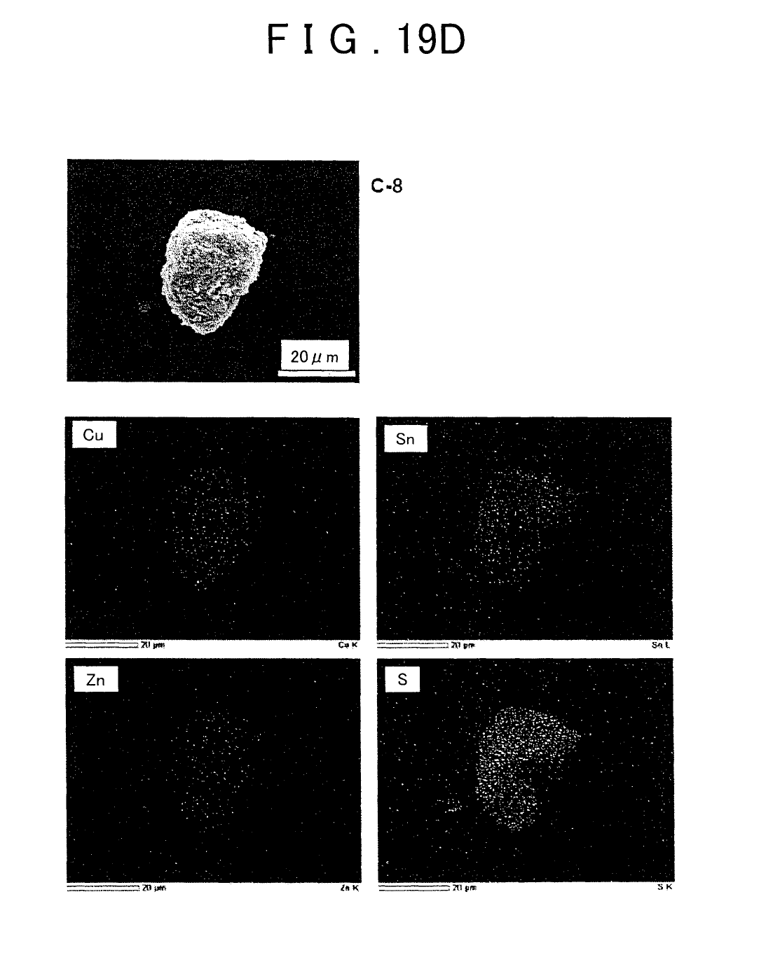

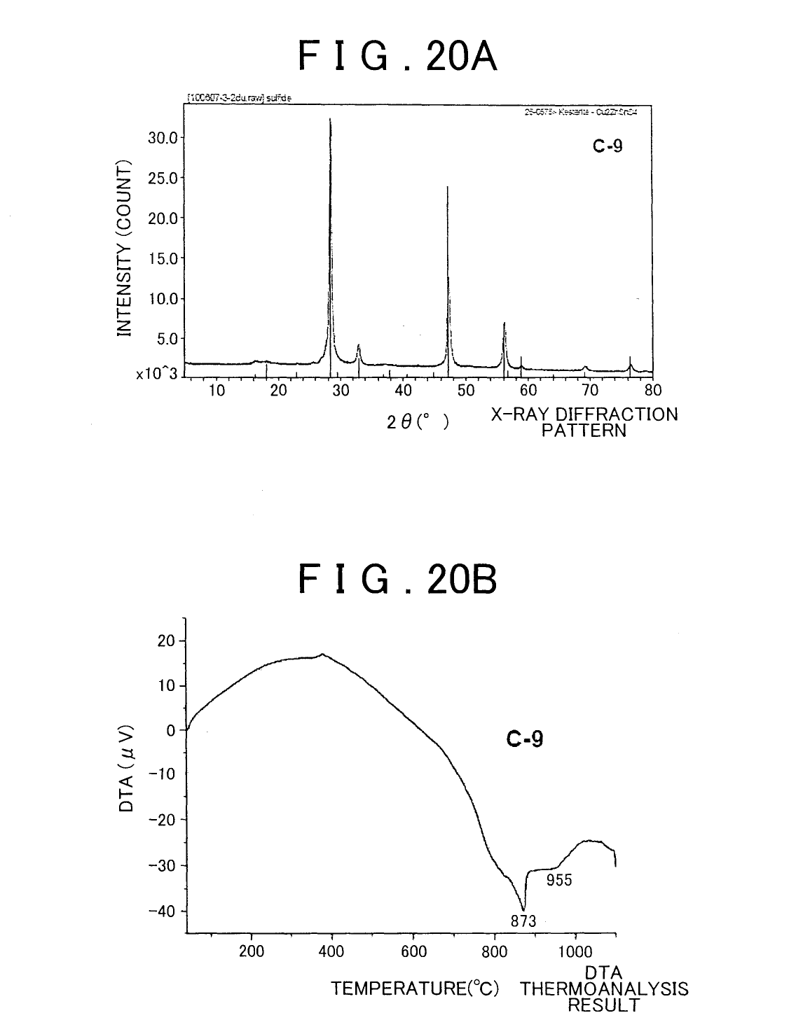

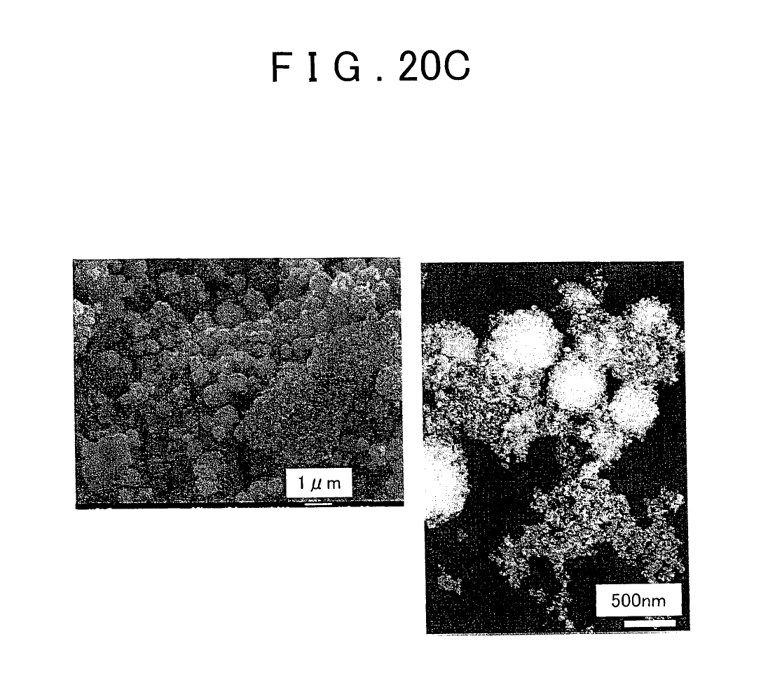

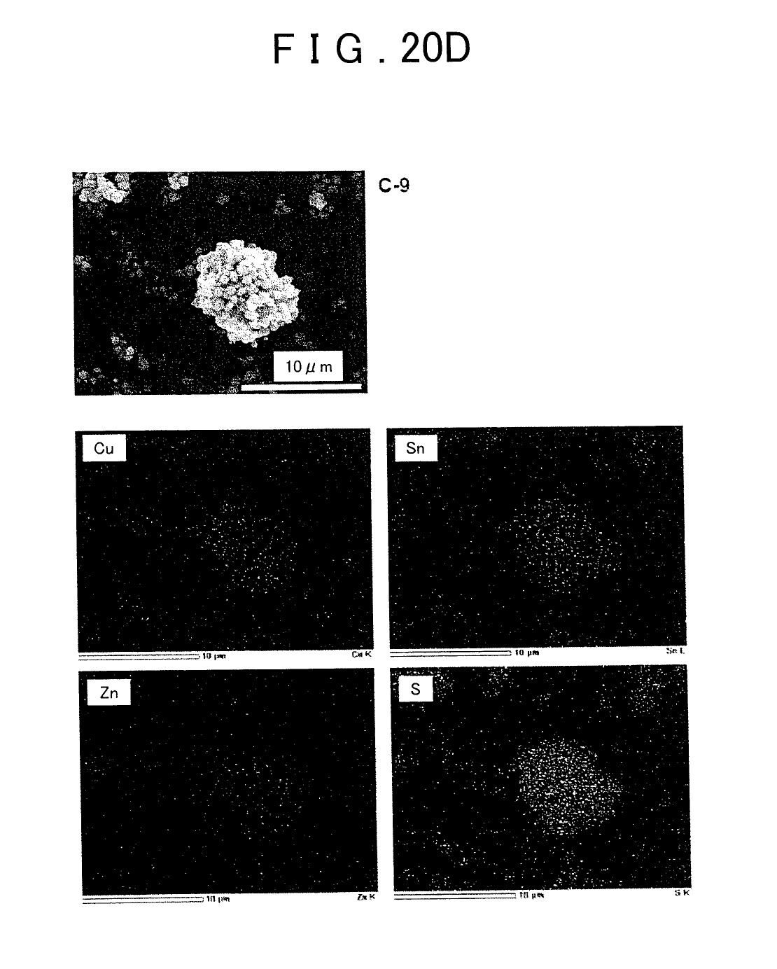

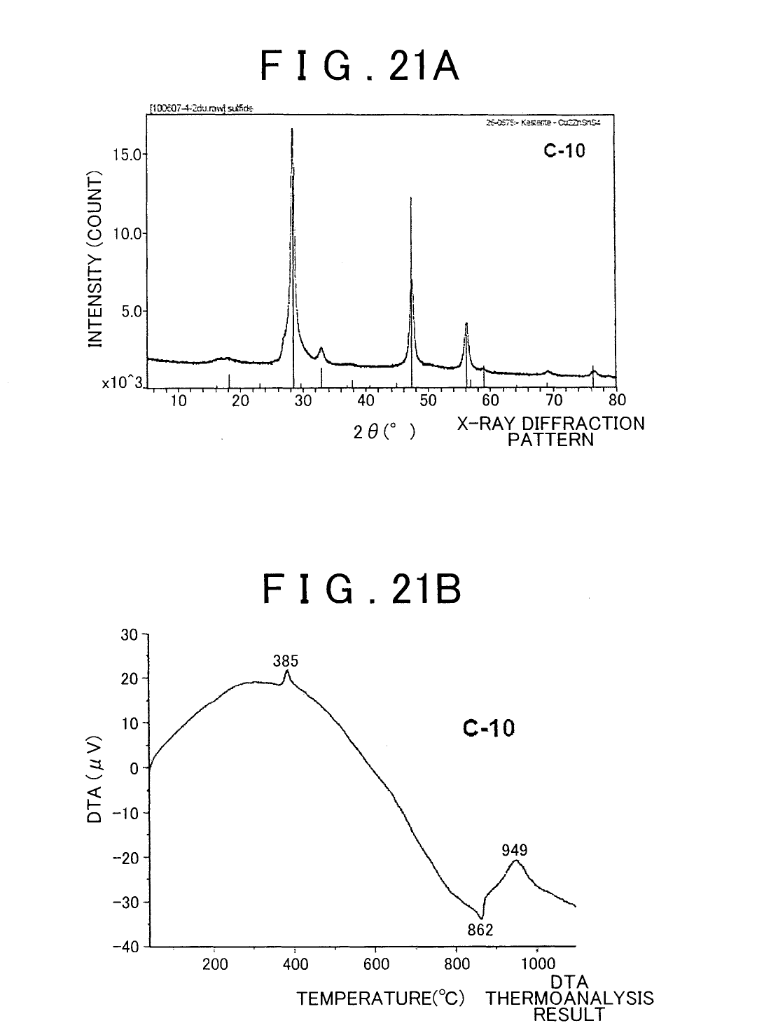

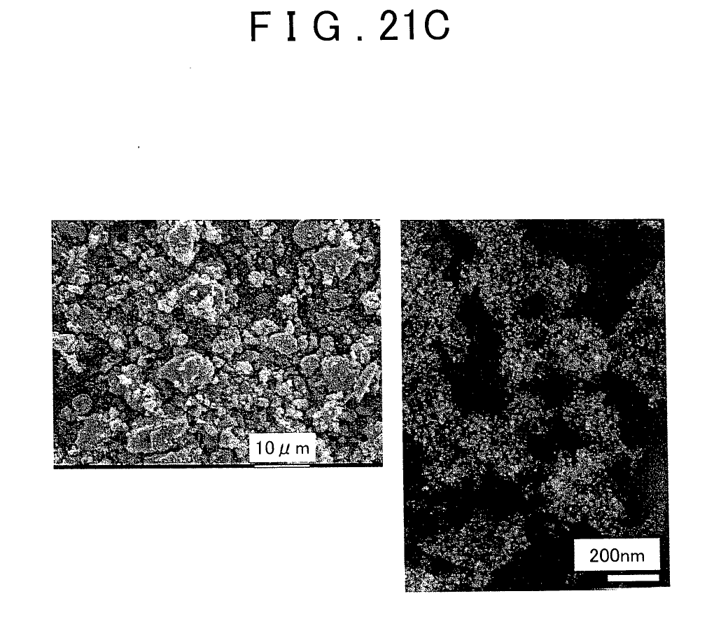

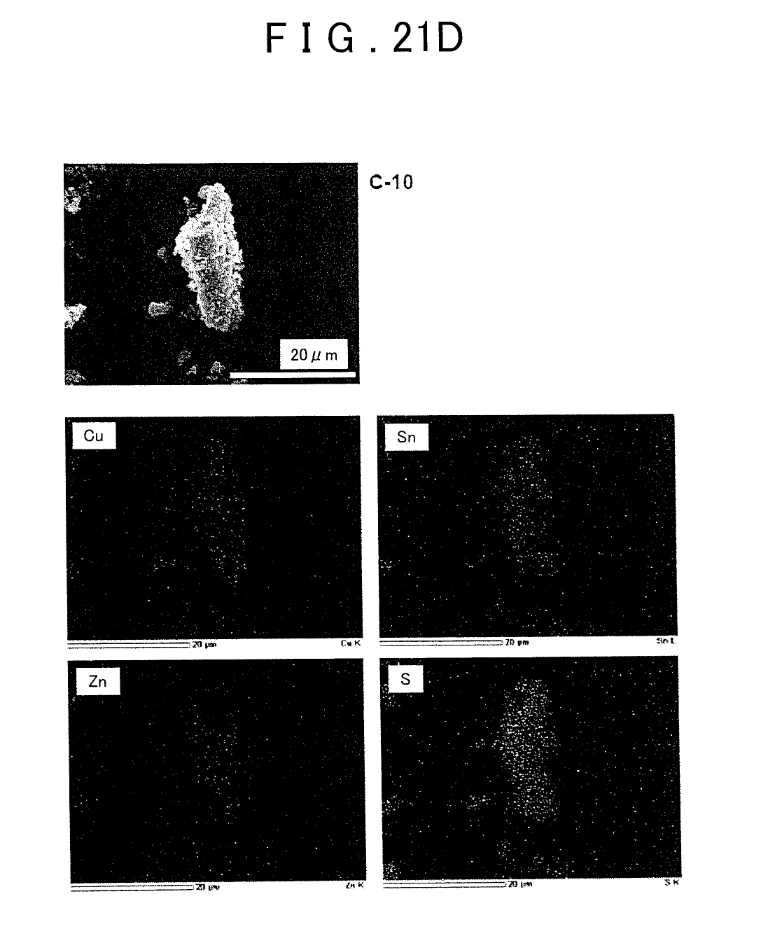

Obtained powders of Examples 1 to 21 were analyzed according to X-ray powder diffraction (XRD), differential thermal analysis (DTA), transmission electron microscope (TEM), energy dispersive fluorescent X-ray analysis (EDX) and scanning electron microscope (SEM). Results are shown in Table 1 and FIGS. 1A to 21D.

As shown in Table 1, elements compositions of the powders of Examples 1 to 21 were in the range of 21 to 33: 9 to 27: 7 to 15: 39 to 51, and an average value thereof was 28:14:13:45.

As shown in FIGS. 1A to 21A, diffraction peak patterns of XRD of Examples 1 to 21 were well coincided with a diffraction peak pattern of XRD derived from a crystal of Cu₂ZnSnS₄. Accordingly, Examples 1 to 21 were identified as the crystal of Cu₂ZnSnS₄. Each DTA of Examples 1 to 21 indicated an exothermic peak in the range of 200 to 500° C. (FIGS. 1B to 21B). When TEM images of Examples 1 to 21 were compared, all samples were found to form fine crystal particles (FIGS. 1C to 21C). Further, when element mapping images based on SEM images of Examples 1 to 21 were compared, in all crystals of samples, the respective elements were found distributed uniformly (FIGS. 1D to 21D).

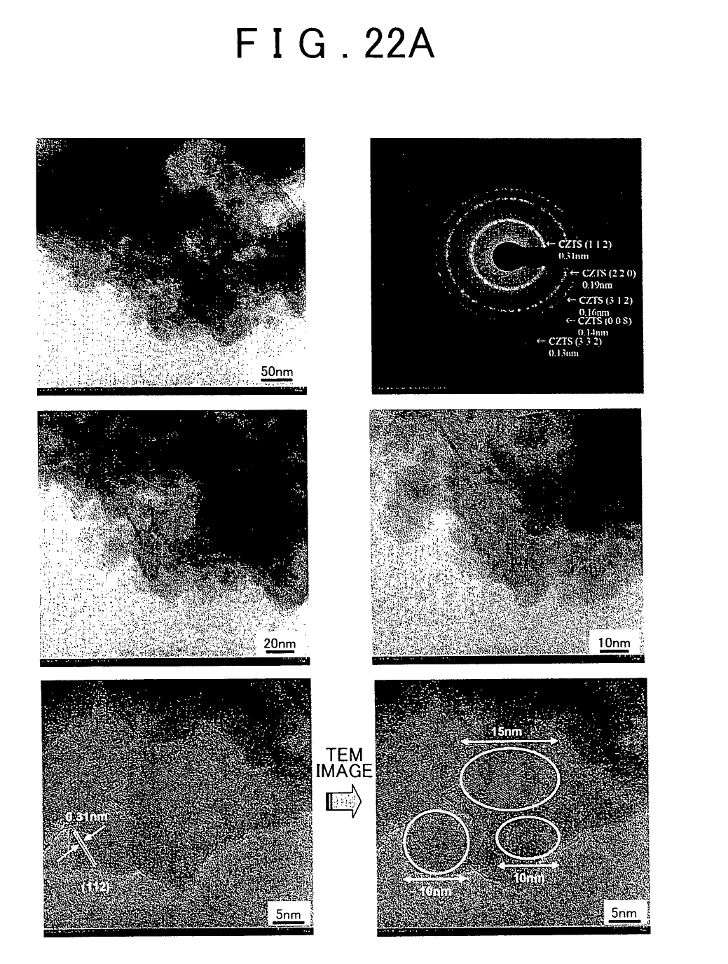

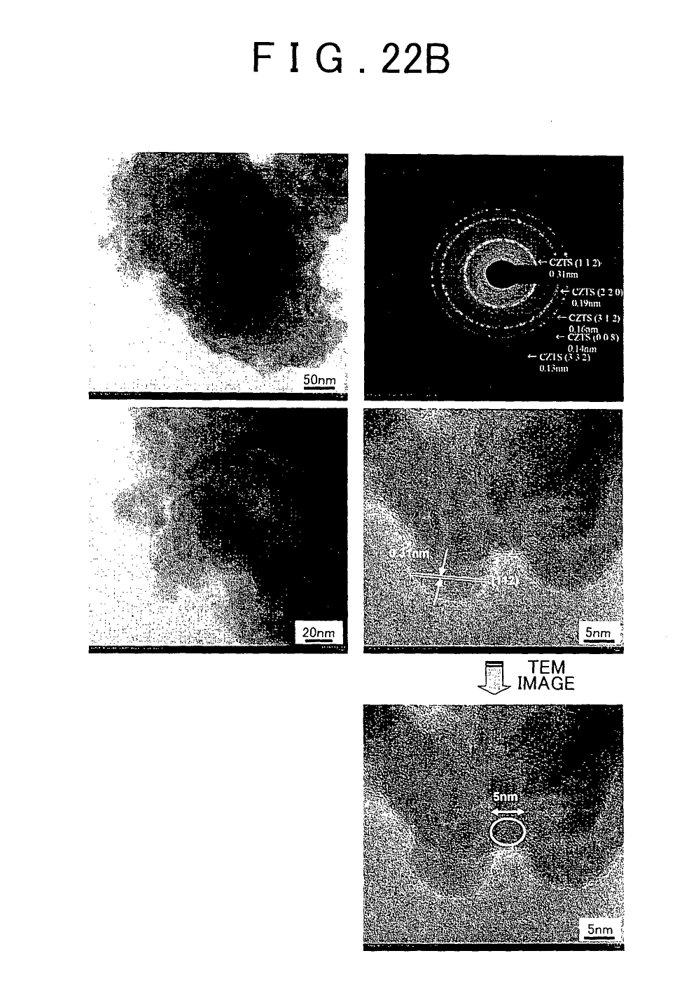

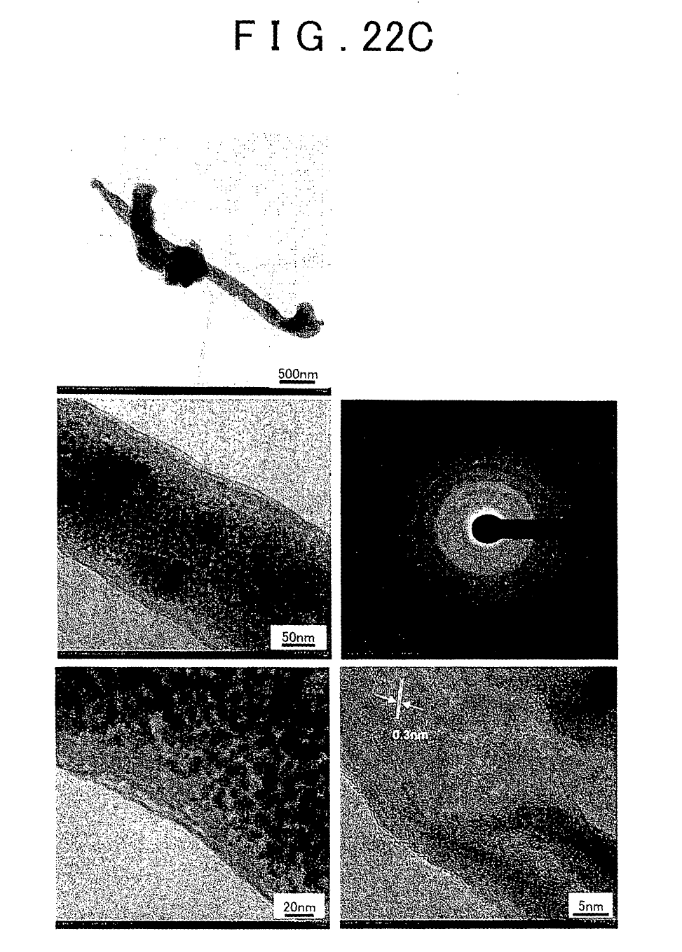

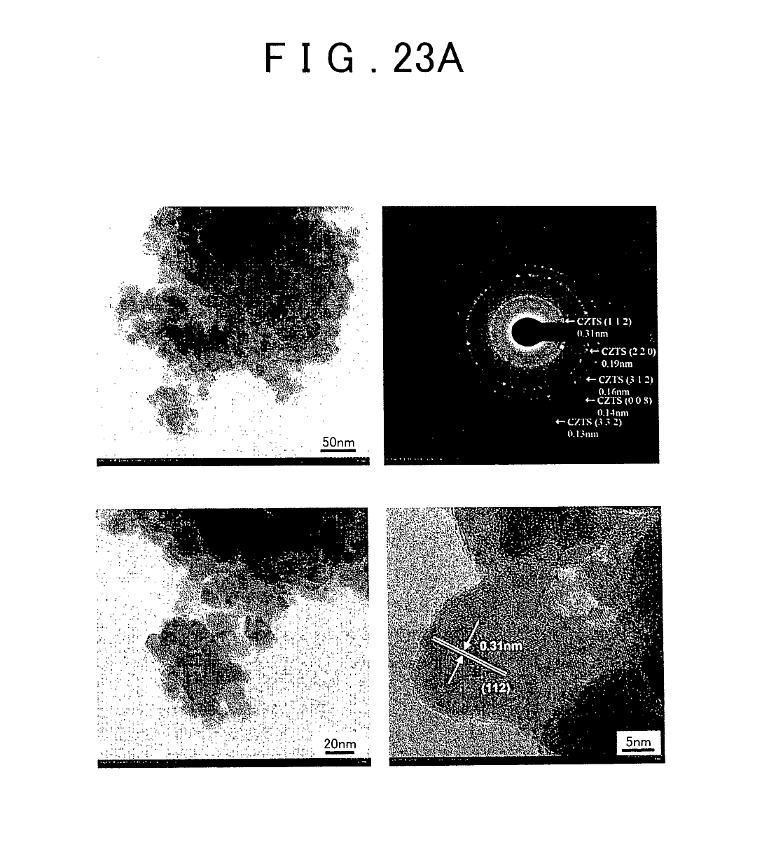

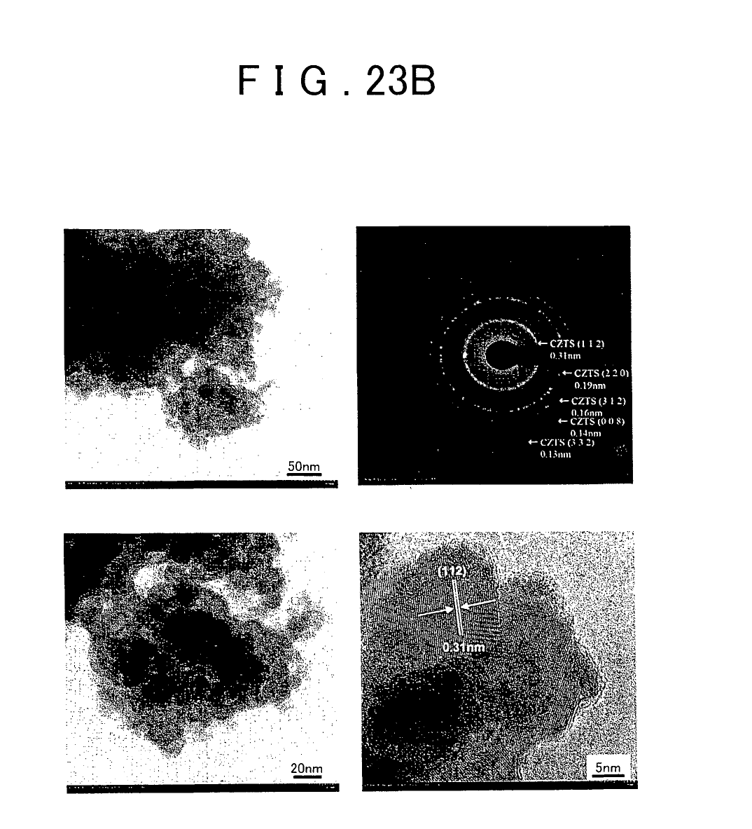

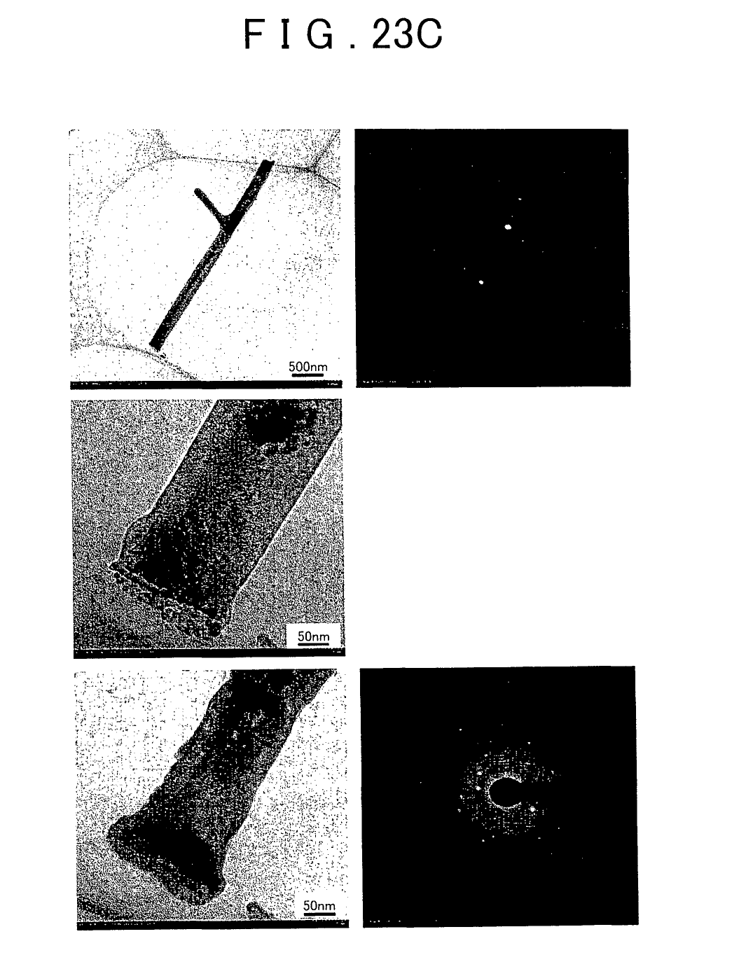

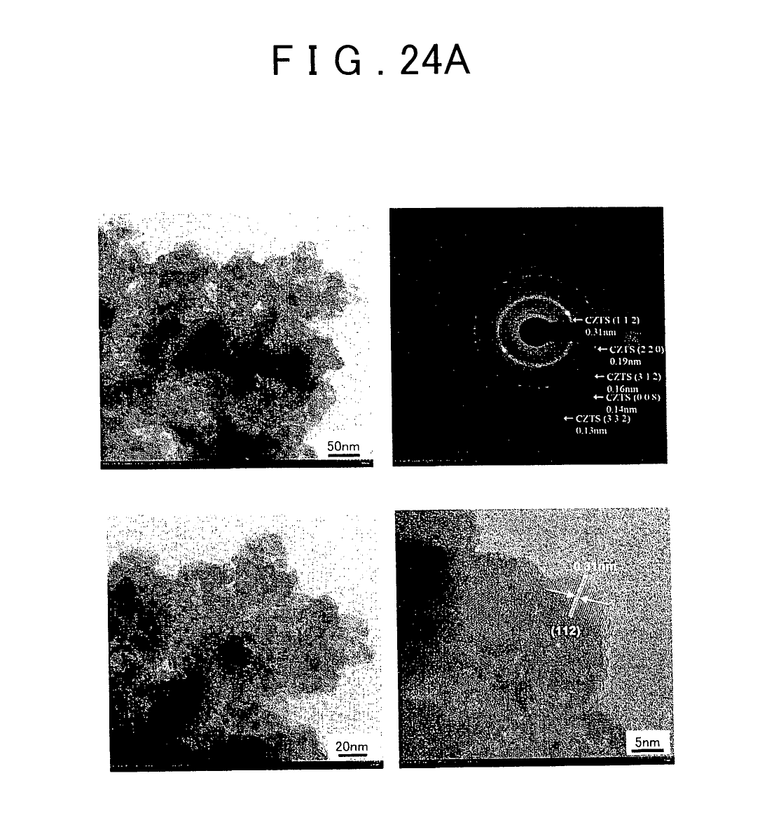

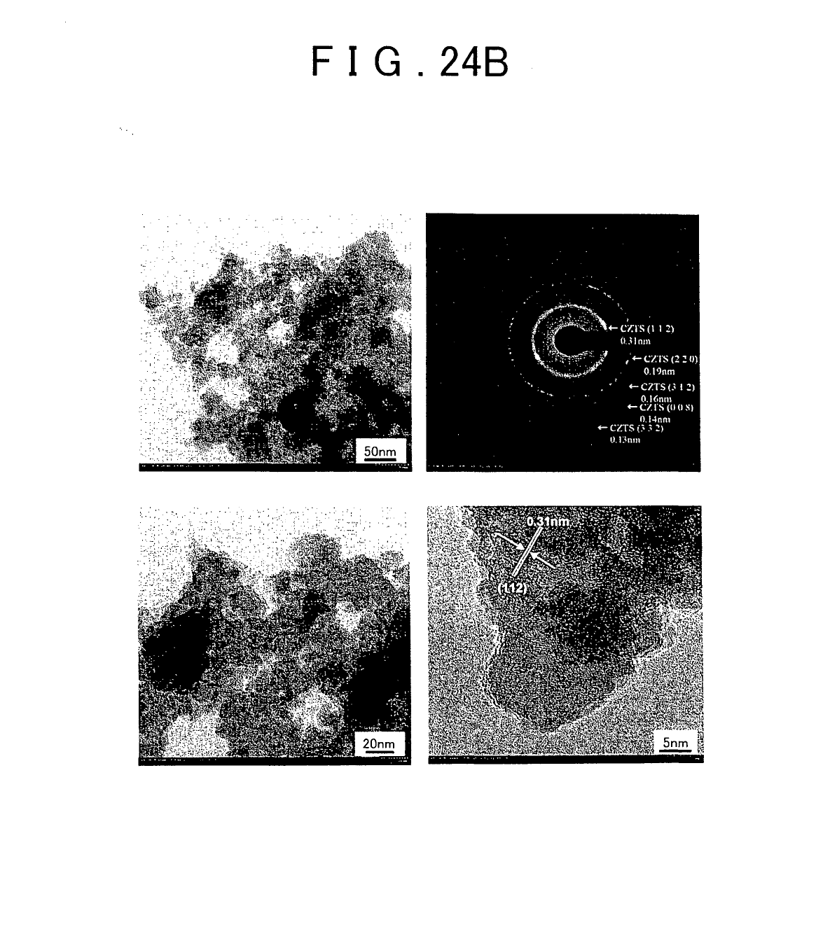

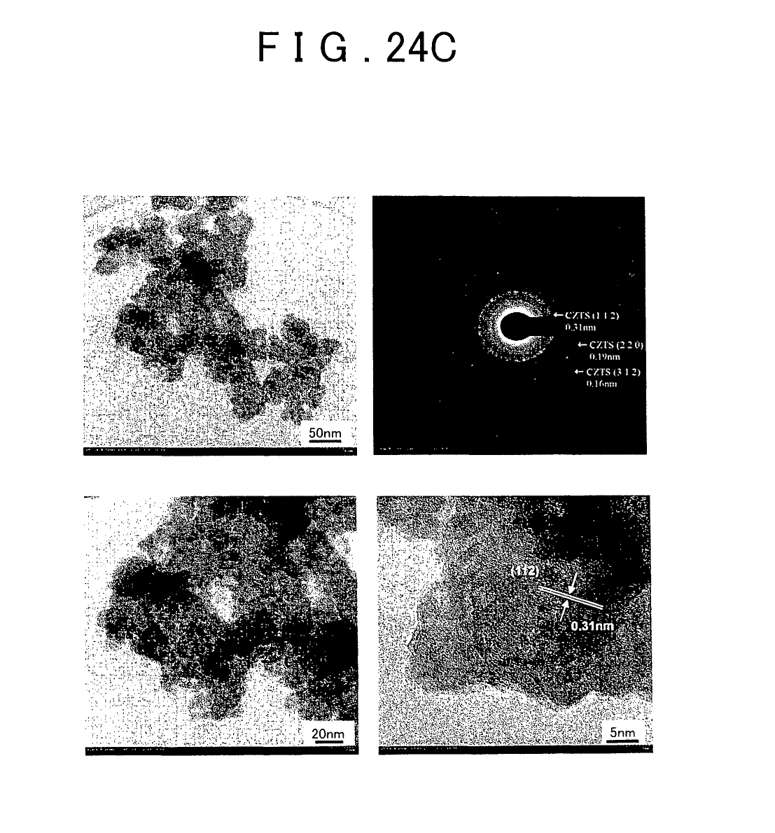

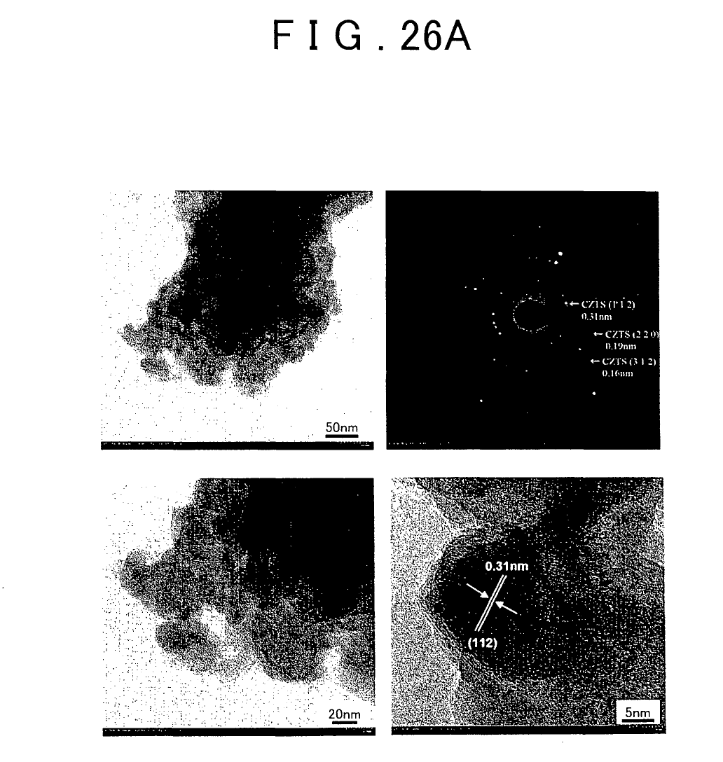

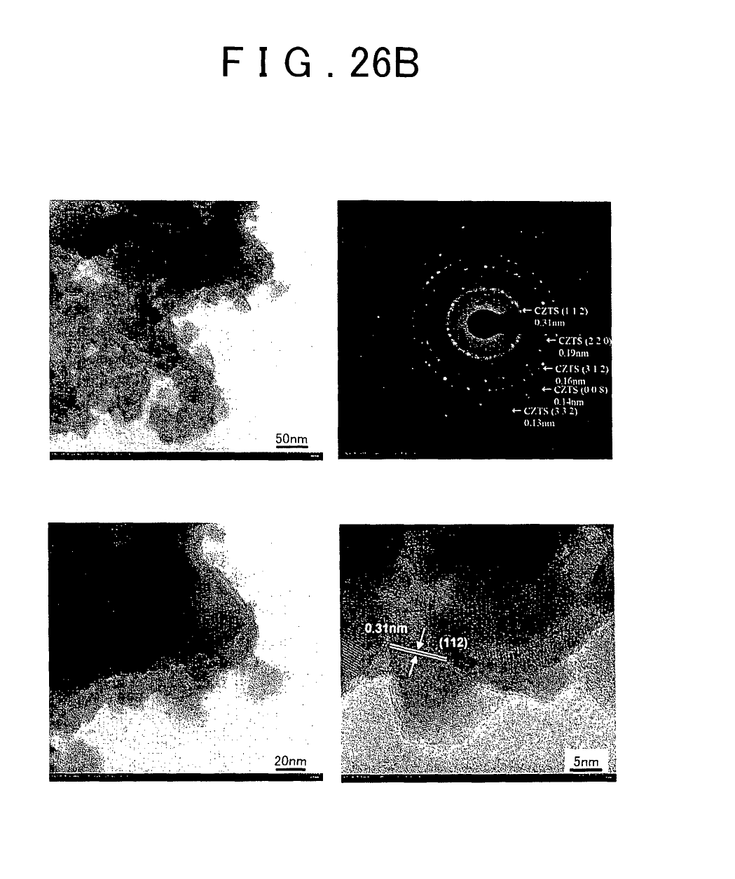

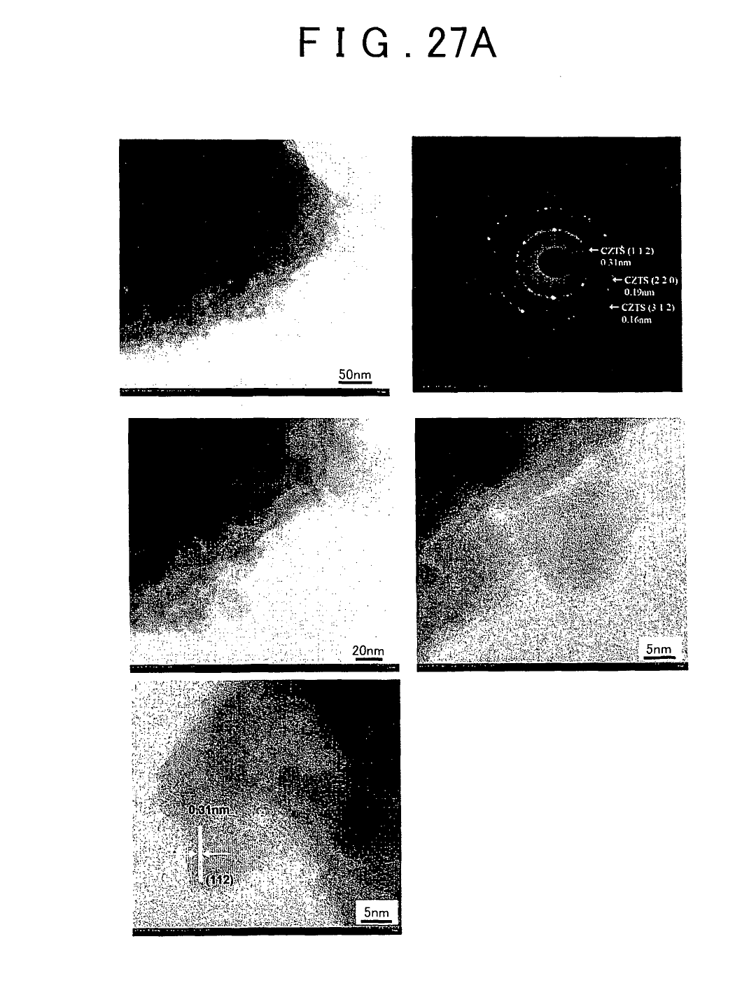

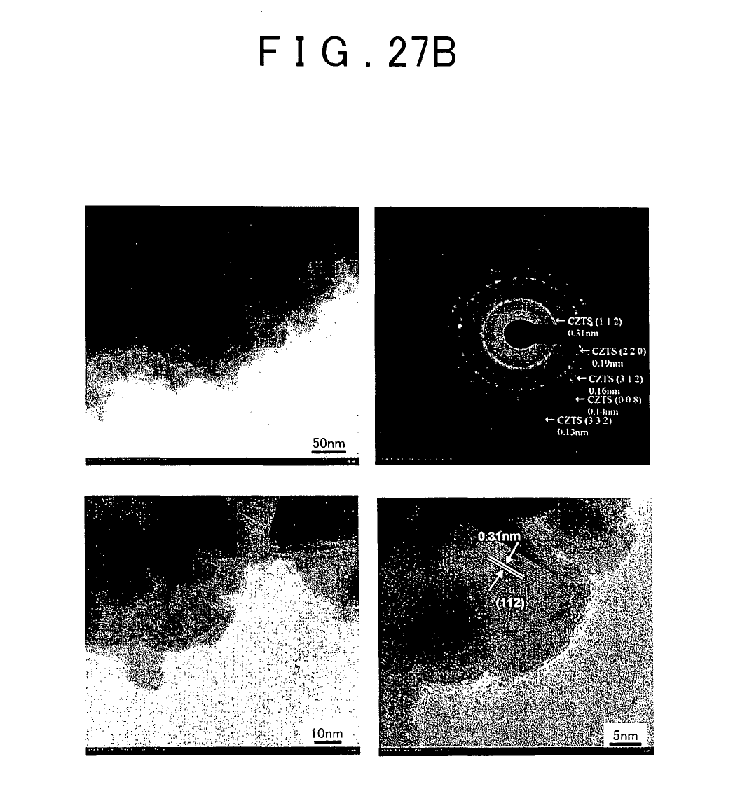

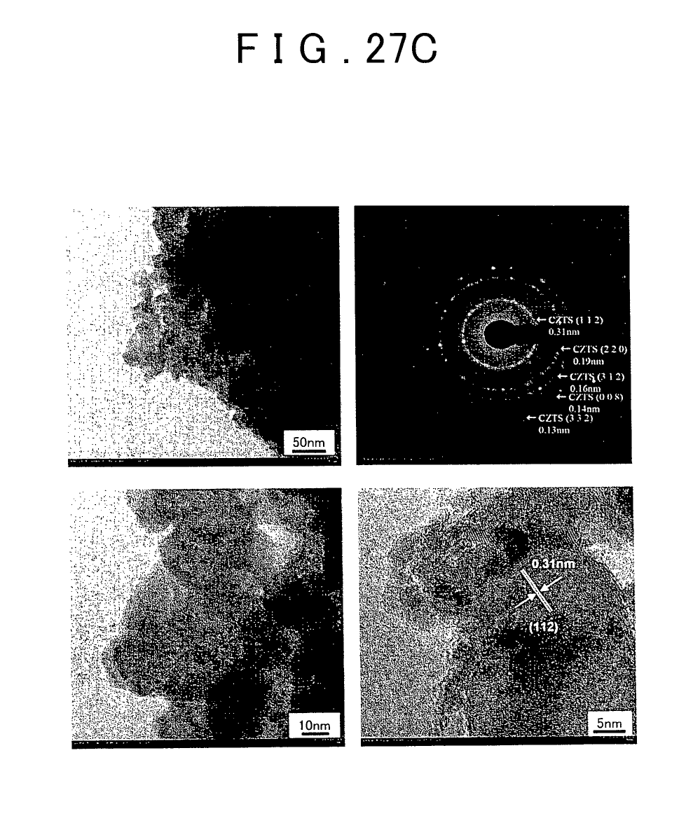

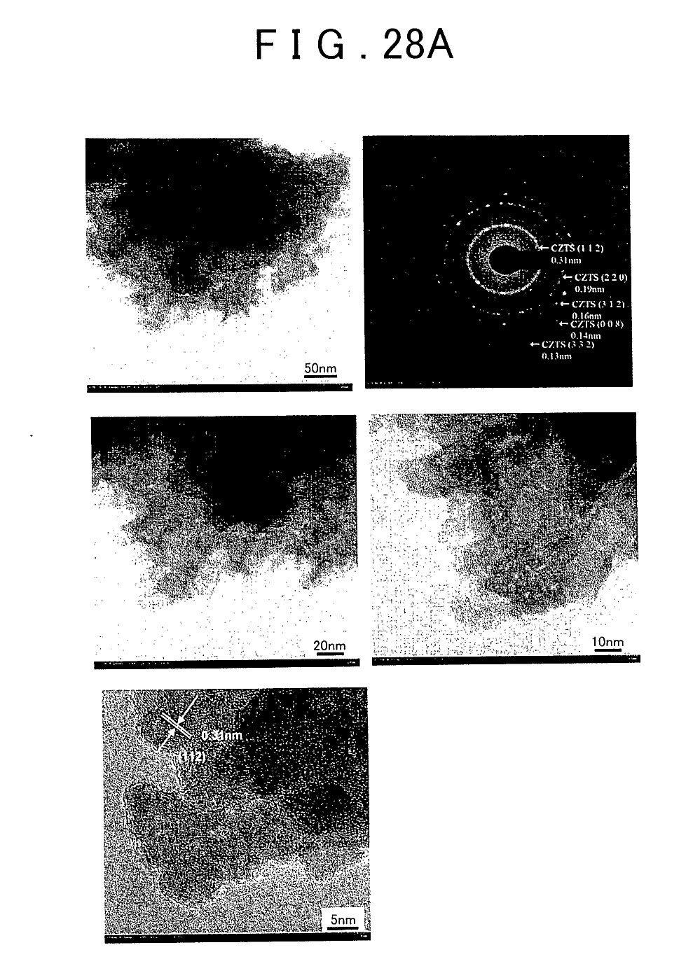

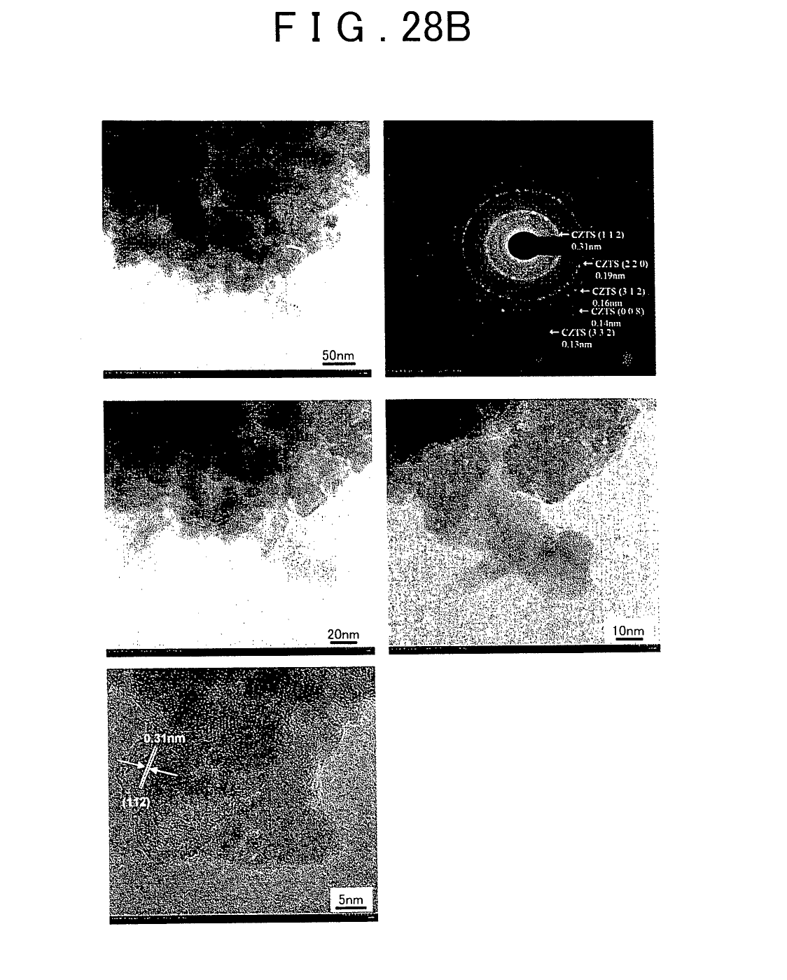

Powders obtained according to Examples 11 to 21 except Examples 12, 15, 17 and 18 were analyzed by use of TEM and high resolution TEM. Results are shown in FIGS. 22A to 28B.

As shown in FIGS. 22A to 28B, in electron diffraction images of powders of examples 11, 13, 14, 16, 19 and 20, diffraction fringes indicating the presence of lattice planes of (112), (220), (312), (008) and (332) were found. A lattice spacing of (112) was 0.31 nm, a lattice spacing of (220) was 0.19 nm, a lattice spacing of (312) was 0.16 nm, a lattice spacing of (008) was 0.14 nm, and a lattice spacing of (332) was 0.13 nm.

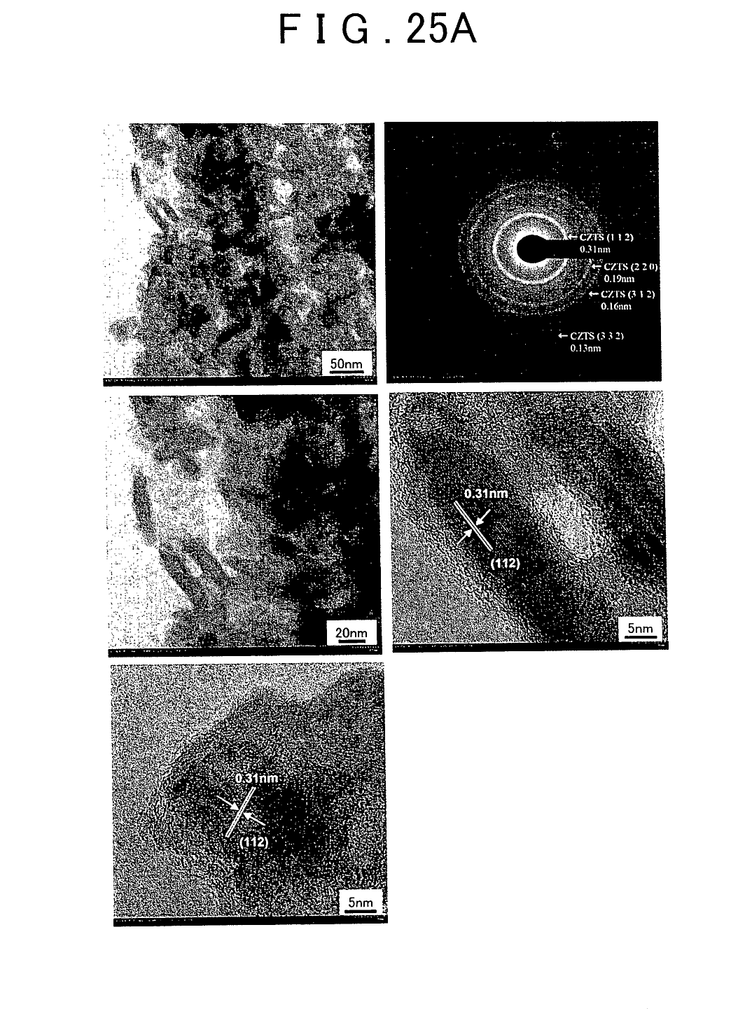

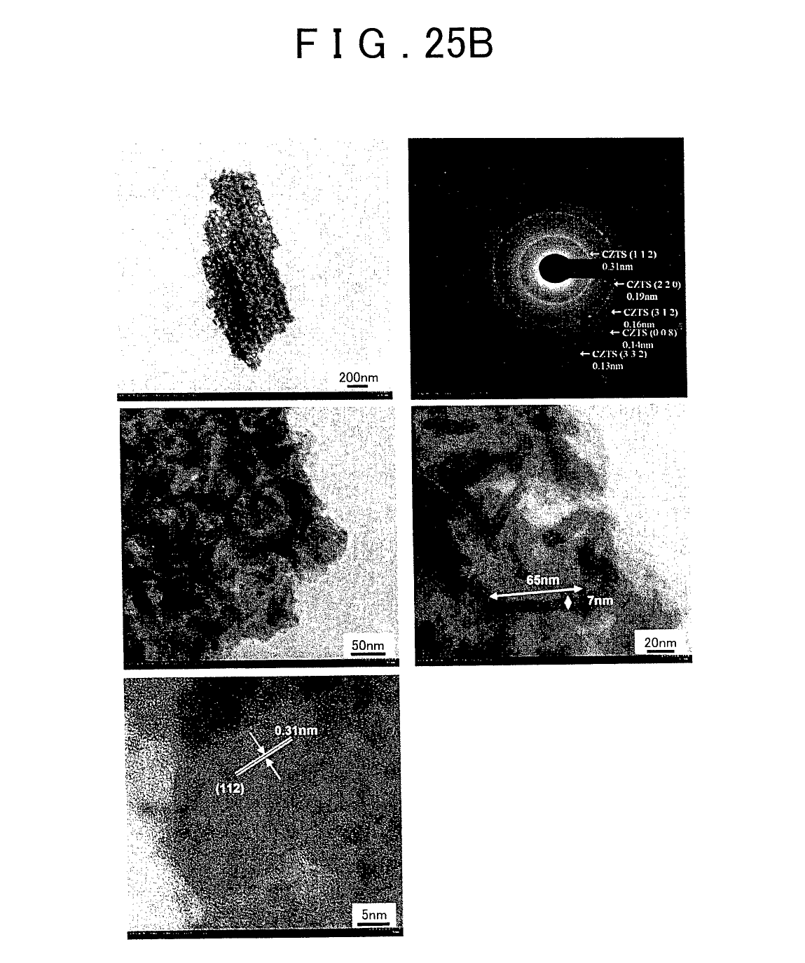

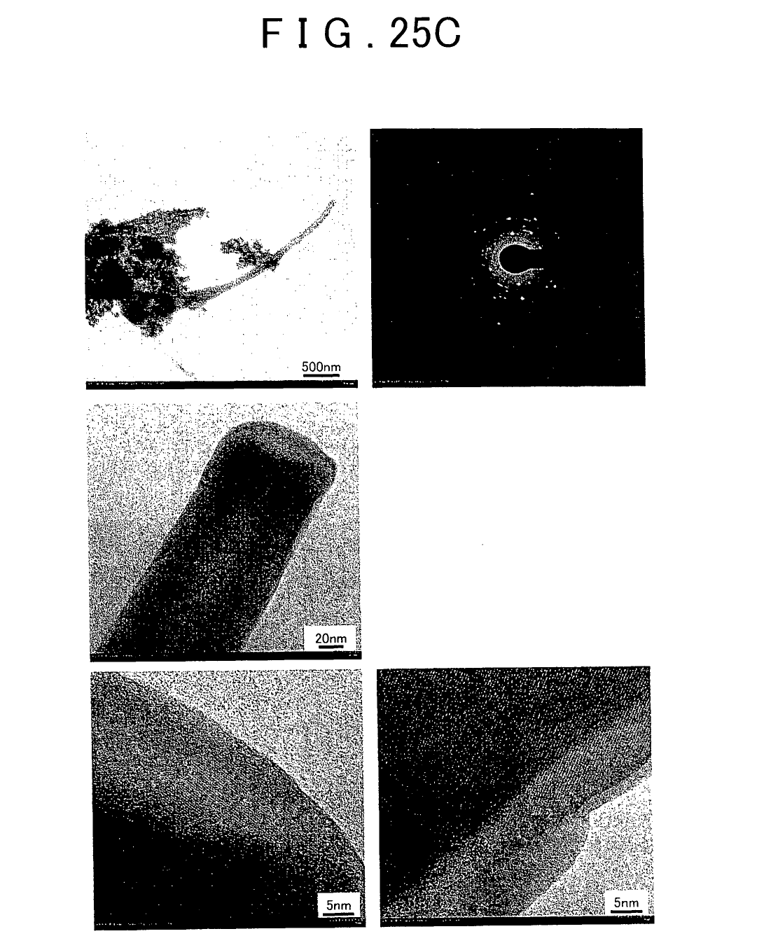

As shown in FIGS. 25A to 25C, the crystal of Example 16 was found to be a rod-like crystal. In the rod-like crystal of Example 16, a length in a major axis direction was about 30 to 70 nm and a length in a minor axis direction was about 5 to 10 nm.

Then, 2 mmol of Cu source, 1 mmol of Zn source, 1 mmol of Sn source and 5 mmol of S source were filled in an autoclave of HASTELLOY™ and 30 ml of the organic solvent was added so that a filling rate becomes 50%. In the cases of Examples 33 and 35, polyvinylpyrrolidone as an additive was further added. The autoclave was, after hermetically sealing, heated at 240° C. for 24 hours to conduct the solvothermal reaction (solvothermal step). The resulted product was naturally cooled. Thereafter, the product was separated by centrifugation, and precipitate was washed with pure water and ethanol. The product after washing was dried under condition of 70° C. for 30 min to 10 hours (drying step). Thereby, a CZTS was obtained. The preparation condition of the respective Examples was shown in Table 2.

TABLE 2

| Example | | | | | Organic | |
|---|---|---|---|---|---|---|
| No. | Cu source | Zn source | Sn source | S source | solvent | Additive |
| 31 | CuCl₂•2H₂O | ZnCl₂ | SnCl₂ | (NH₂)₂CS | Ethylene | Nothing |
| 32 | CuCl₂ | ZnCl₂ | SnCl₄•5H₂O | (NH₂)₂CS | Ethylene glycol | Nothing |
| 33 | CuCl₂•2H₂O | ZnCl₂ | SnCl₄•5H₂O | (NH₂)₂CS | Ethylene glycol | Polyvinylpyrrolidone |
| 34 | CuCl₂•2H₂O | ZnCl₂ | SnCl₂ | S | Ethylene glycol | Nothing |
| 35 | CuCl₂•2H₂O | ZnCl₂ | SnCl₂ | (NH₂)₂CS | Oleylamine | Polyvinylpyrrolidone |

Each of resulted powders of Examples 31 to 35 was analyzed by scanning electron microscope (SEM), transmission electron microscope (TEM), energy dispersive fluorescent X-ray analysis provided to transmission electron microscope (TEM/EDX), X-ray powder diffraction (XRD), X-ray photoelectron spectrometry (XPS), Raman spectrometry, and thermogravimetric differential thermal analysis (TG-DTA).

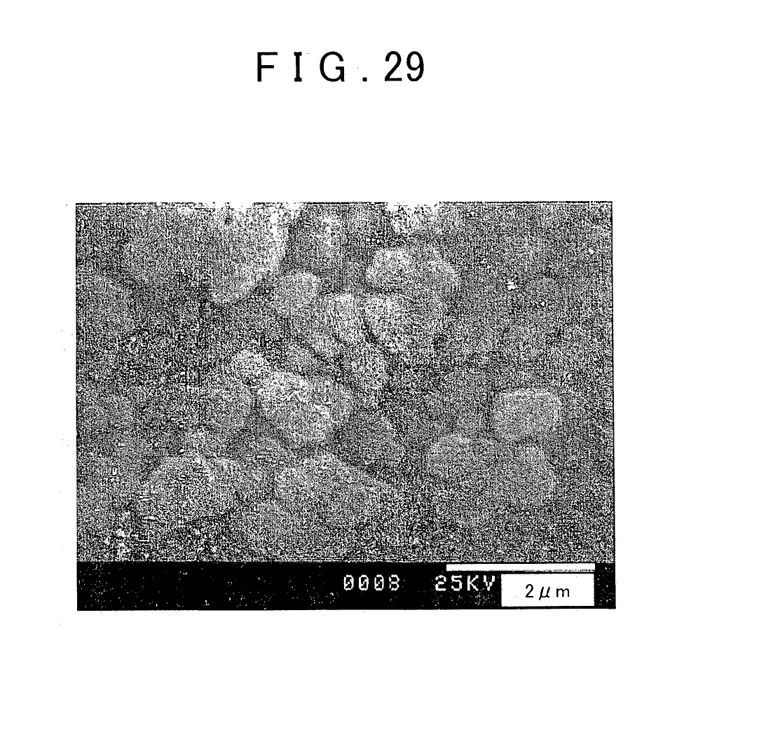

An SEM image of the powder of Example 31 is shown in FIG. 29. As illustrated in FIG. 29, it was found that the powder of Example 31 is spherical crystal having a diameter of several micrometers. Further, also the powders of Examples 32 to 35 had the same crystal shape as that of the powder of Example 31.

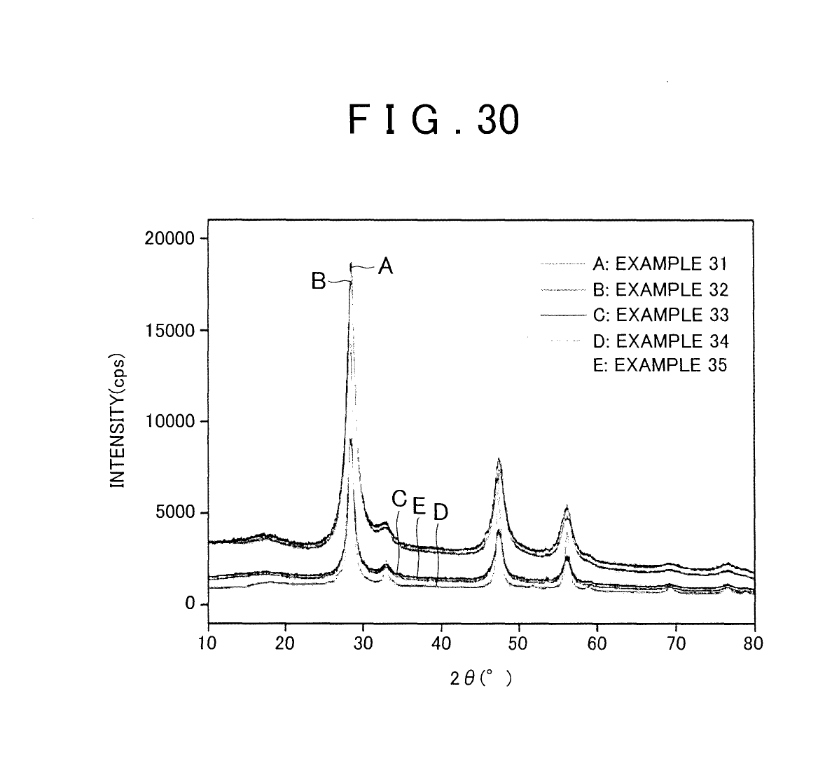

XRD spectra of powders of Examples 31 to 35 are shown in FIG. 30. As illustrated in FIG. 30, diffraction peak patterns of XRD of Examples 31 to 35 are well coincident with a diffraction peak pattern of XRD derived from a crystal of CZTS, and peaks of sulfides such as SnS, SnS₂ and Cu₂S were not observed. Main diffraction lines are observed at 2θ=28.5, 33.0, 47.4° and 56.3°, and these peaks correspond to diffractions from (112), (200), (220) and (312) plane of CZTS, respectively.

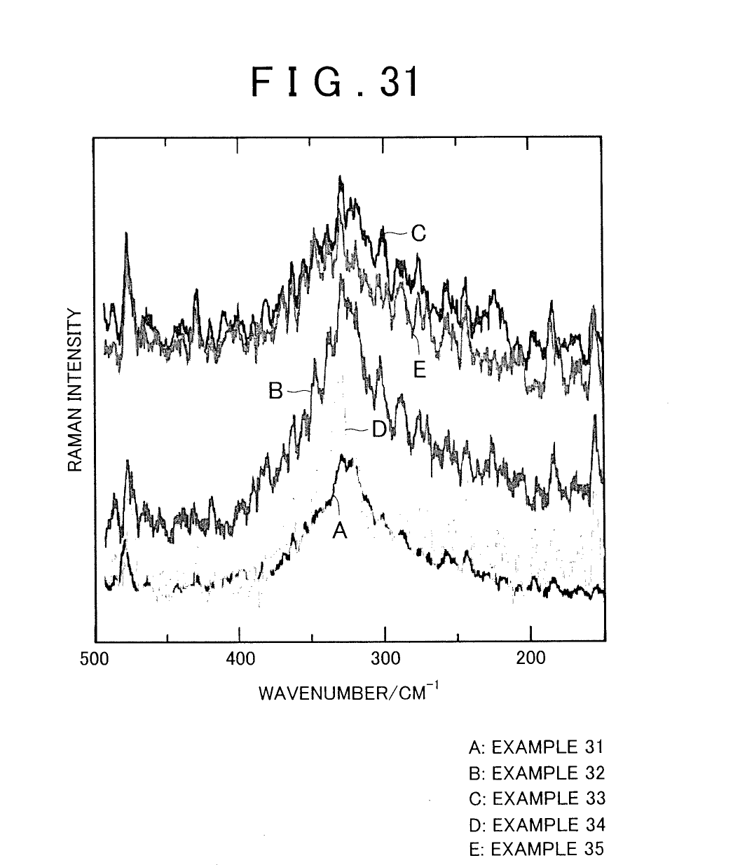

Then, whether the CZTS is present is confirmed by Raman spectrometry. Results are shown in FIG. 31. As illustrated in FIG. 31, in all cases of examples, a main peak was observed in a region of 338 cm⁻¹. Cu₂SnS₃ and other Cu—Sn—S compounds do not have a peak in the wave number region. Accordingly, it was demonstrated that in powders of Examples 31 to 35, a CZTS kesterite structure is present. Further, it is obvious that β-ZnS having a main peak in the region of 355 cm⁻¹ is hardly present in powders of all examples. A small peak at 475 cm⁻¹ shows existence of Cu₂-xS as a secondary phase.

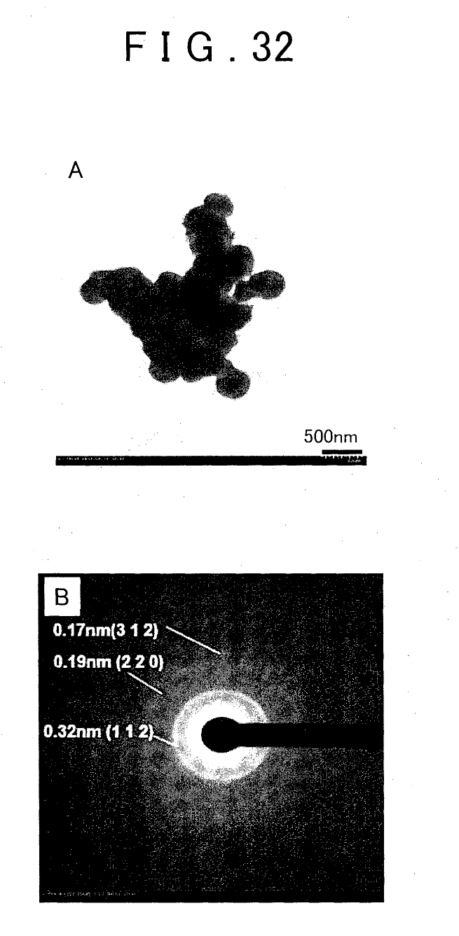

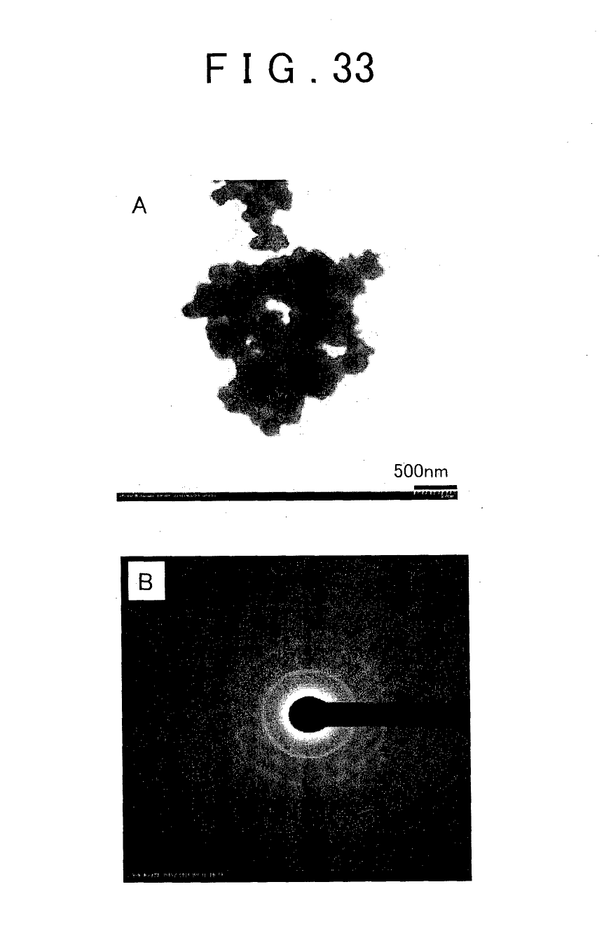

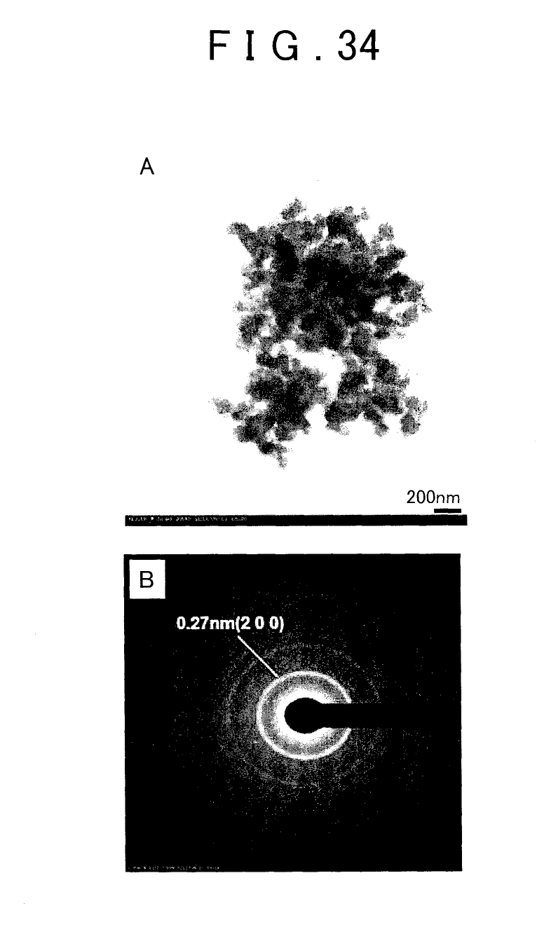

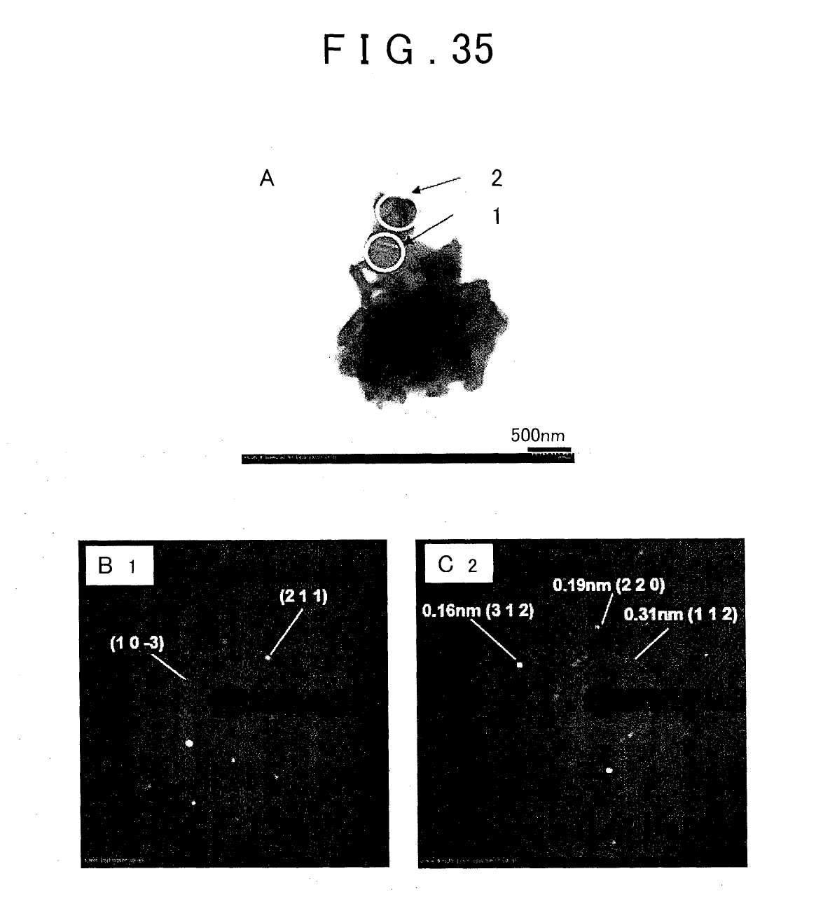

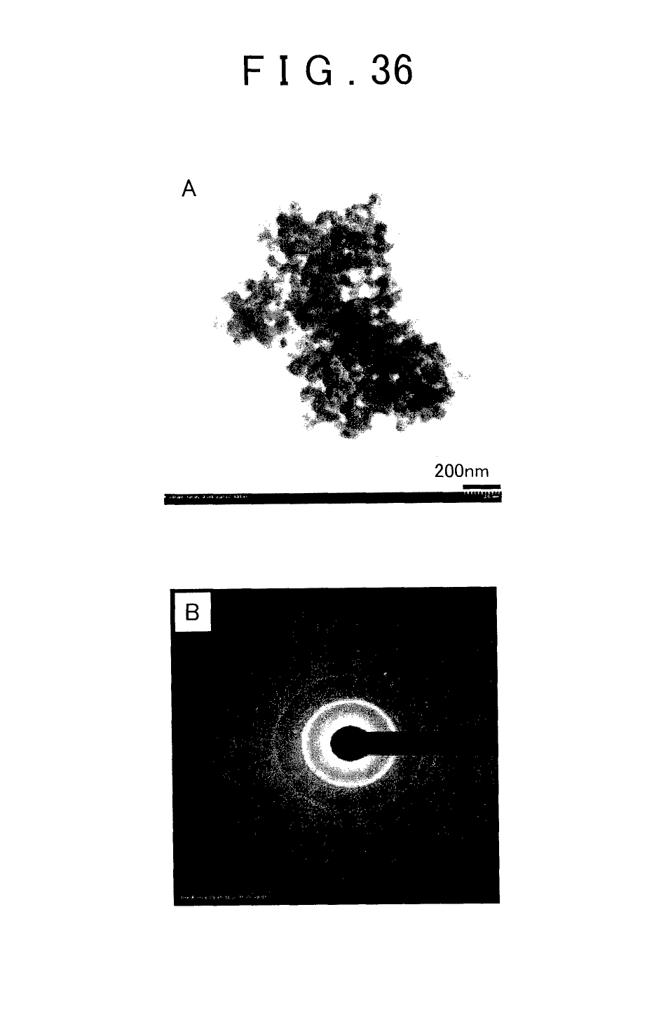

TEM images and electron diffraction images of powders of Examples 31 to 35 are shown in FIGS. 32 to 36, respectively. As illustrated in FIGS. 32A to 36A respectively, all of powders of Examples 31 to 35 were configured of very fine particles. Powders of Examples 31 to 33 and 35 were configured of particles having a particle size of 10 nm. In powder of Example 34, relatively large particles having a particle size of several hundreds nanometers were observed. In powders of Examples 31 to 35, these primary particles flocculated to form spherical crystal particles (secondary particles) having a particle size of about 1 (FIG. 29). Further, as illustrated in FIGS. 32B to 36B, respectively, also in electron diffractions of powders of Examples 31 to 35, diffractions at 0.17 nm (or 0.16 nm), 0.19 nm, 0.27 nm, and 0.32 nm (or 0.32 nm) corresponding to diffractions of (312), (220), (200) and (112) planes were observed. From these results, it was confirmed that a CZTS kesterite structure is present in powders of Examples 31 to 35.

Composition analysis of powders of Examples 31 to 35 was conducted by EDX. As the result thereof, it was demonstrated that powders of Examples 31 to 35 contain elements Cu, Zn, Sn and S corresponding to CZTS; that is, almost stoichiometric CZTS is generated. However, a composition ratio of four elements was observed to be different depending on measurement sites.

In order to differentiate the CZTS contained in powders of Examples 31 to 35 from Cu₂SnS₃ and β-ZnS, TG-DTA measurement was conducted. It is reported that Cu₂SnS₃ has a transition temperature at 775° C. from triclinic to cubic and melts at 850° C. CZTS is reported to melt at 991° C. Further, ZnS is reported to cause transition at 1020° C. from cubic to wurtzite and to melt at 1650° C. However, it is considered that in nanosize crystals, these temperatures become lower. For example, it is reported that CZTS nanocrystal and Cu₂SnS₃ nanocrystal, respectively have a phase transition temperature at 830° C. and 747° C.

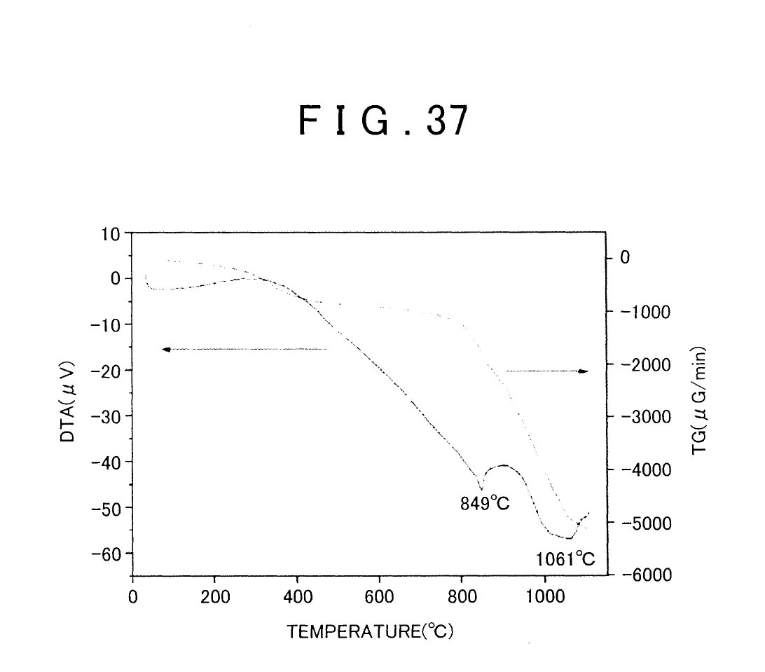

TG-DTA measurements of powders of Examples 31 to 35 were all similar. Accordingly, the TG-DTA measurement of powder of Example 34 is shown in FIG. 37. As illustrated in FIG. 37, two peaks at 849° C. and 1061° C. were observed in DTA curve. Since there is no change at 849° C. or less, it is considered that Cu₂SnS₃ does not exist. The likelihood that β-ZnS is contained together with CZTS in the powder of Example 34 is considered. However, since a large weight loss was observed from 849° C. in the TG curve, it is indicated that β-ZnS is not contained.

As shown above, in Examples 31 to 35, irrespective of use of raw materials having different valence, same products were obtained. Then, valence and composition of synthesized CZTSs were investigated by XPS. XPS spectra of four elements (Culp, Zn2p3, Sn3d5 and S2p) are shown in FIGS. 37 to 41.

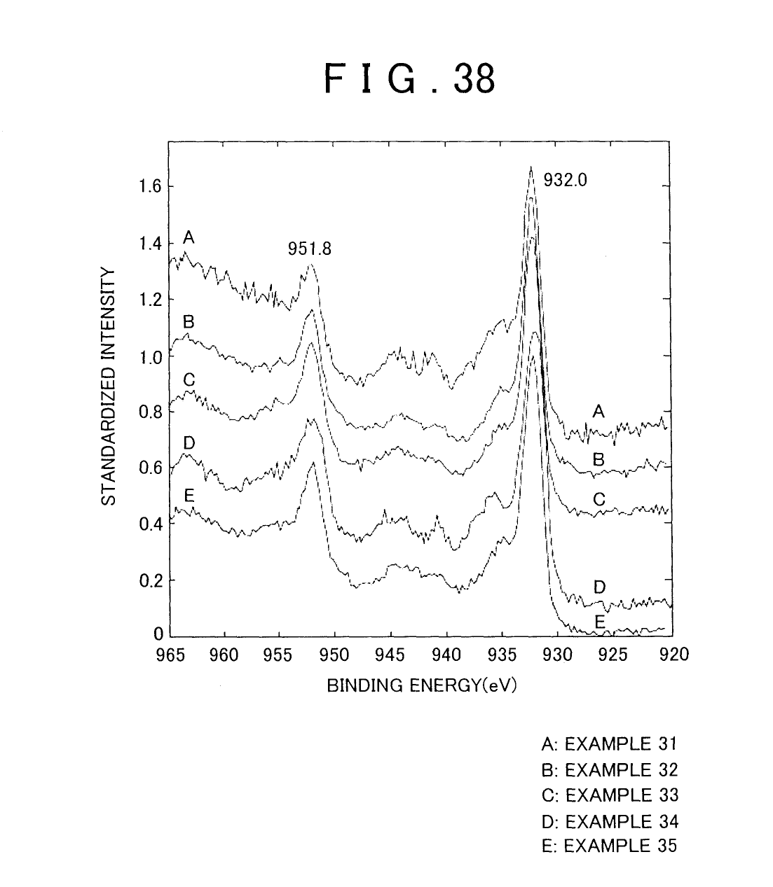

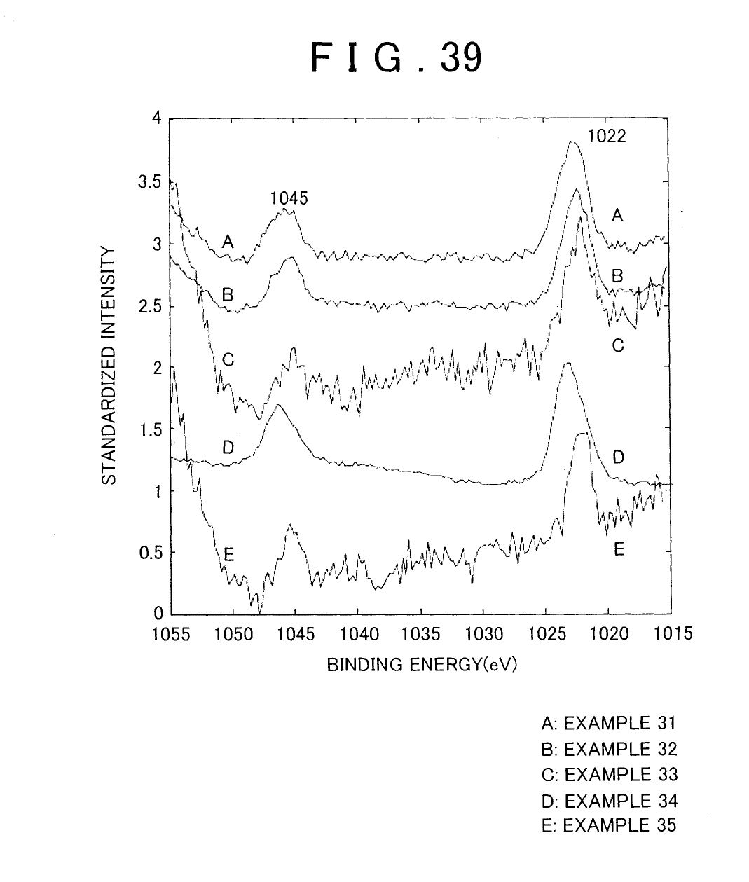

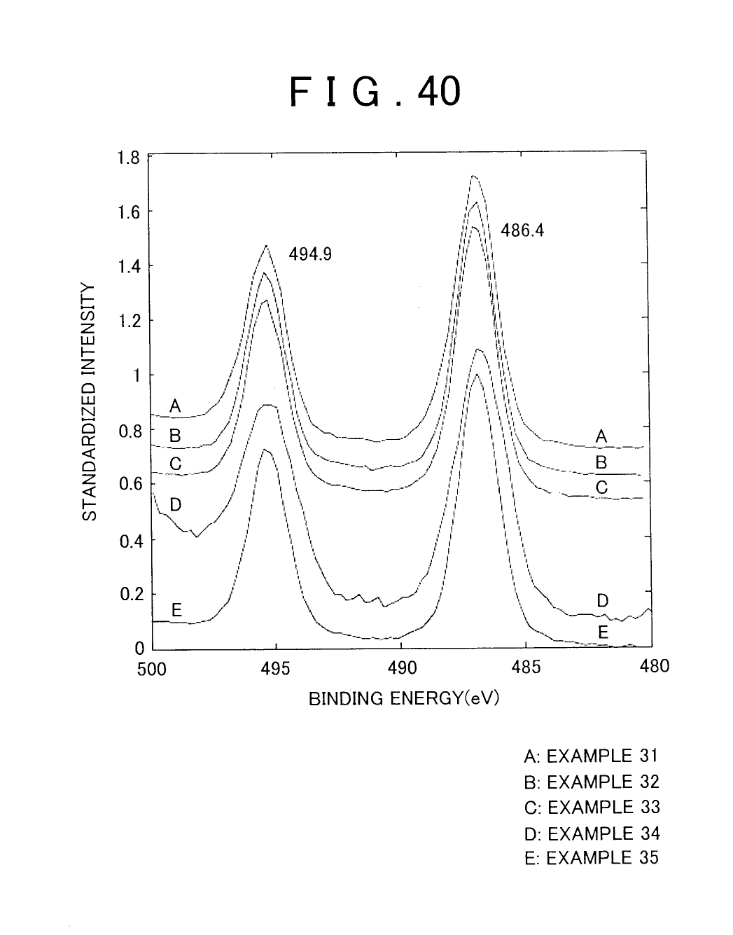

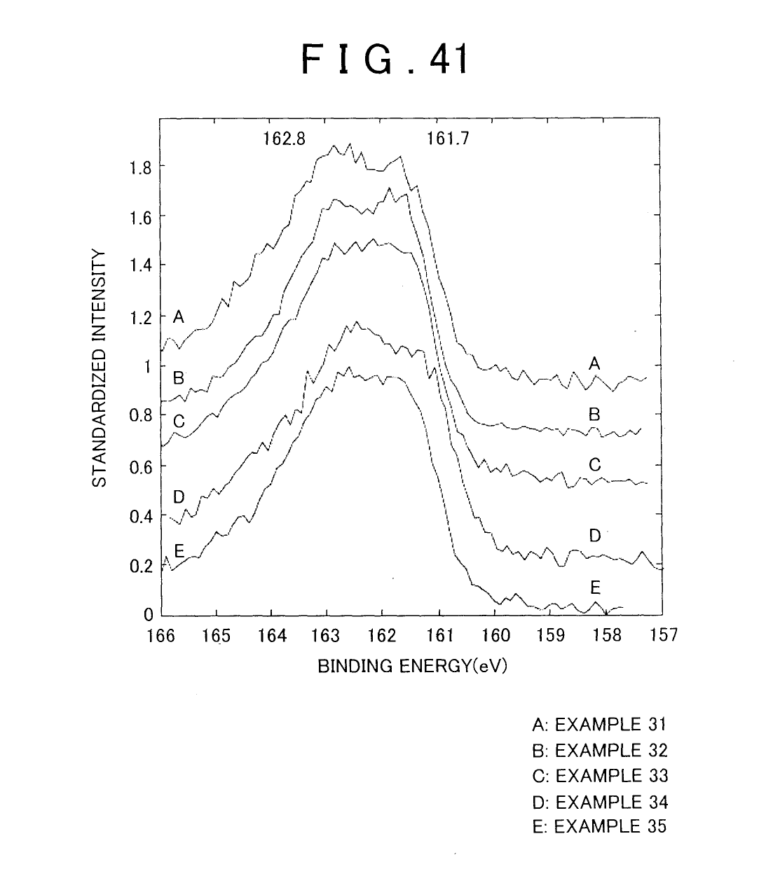

In XPS spectrum of copper (Cu), there are two peaks at 932.0 and 951.8 eV, and from the peak difference of 19.8 eV, it is indicated that Cu(I) exists (FIG. 38). In XPS spectrum of zinc (Zn), there are two peaks at 1022 and 1045 eV, and from the peak difference of 23 eV, it is indicated that Zn(II) exists (FIG. 39). In XPS spectrum of till (Sn), there are two peaks at 486.4 and 494.9 eV, and from the peak difference of 8.5 eV, it is indicated that Sn(IV) exists (FIG. 40). In XPS spectrum of sulfur (S), two broad peaks were observed at 161.7 and 162.8 eV (FIG. 41). These peaks were in the range of 160 to 164 eV that shows S in sulfide. From results mentioned above, it is considered that the valence of metal ions in raw materials does not largely affect on synthesis of CZTS, and, during reaction, Cu(II) and Sn(II) changed to Cu(I) and Sn(IV), respectively.

From analysis results of XPS, elemental composition of CZTS nanoparticles of Examples 31 to 35 were calculated. Results are shown in Table 3. Values in the table were calculated on the basis of Cu.

TABLE 3

| Example No. | Cu | Zn | Sn | S |
|---|---|---|---|---|
| 31 | 2.0 | 1.3 | 5.9 | 3.5 |
| 32 | 2.0 | 0.7 | 4.3 | 3.6 |
| 33 | 2.0 | 0.2 | 4.5 | 3.8 |
| 34 | 2.0 | 3.4 | 2.4 | 3.8 |
| 35 | 2.0 | 0.1 | 4.5 | 3.5 |

Since the results of Table 3 were calculated from results of XPS analysis, the results are based on elemental compositions of local regions on surfaces of samples. In this connection, in order to improve accuracy of quantitative analysis values, the respective elements of the CZTS nanoparticles of Examples 31 to 35 were quantitatively analyzed by use of ICP (high frequency plasma emission spectrometer).

About 20 mg of each of powders of Examples 31 to 35 was measured. To the powder, 3 ml of aqua regalis was added, further the mixture was subjected to white smoking by adding 3 ml of sulfuric acid (400° C., for 10 min). The processed mixture was cooled, 2 ml of hydrochloric acid was added, further a slight amount of pure water was added, and the resulted mixture was heated at 200° C. for 10 min. Thereafter, a reaction mixture was prepared to a constant volume of 100 ml for a sample for quantitative analysis. By use of ICP (trade name: ICP-8100, manufactured by Shimadzu Corporation), Cu (measurement wavelength: 327.396 nm), Zn (measurement wavelength: 213.856 nm) and Sn (measurement wavelength: 189.989 nm) contained in the sample for quantitative analysis were quantitatively analyzed. Further, by use of catalyst sulfur analyzer (trade name: EMIA-920V, manufactured by Horiba Limited), S contained in the sample for quantitative analysis was quantitatively: analyzed (measurement condition: integrated time 80 sec, current value 350 mA, 50 sec, combustion improver Sn: 0.3 g, W 1.5 g).

From analysis results by ICP and sulfur analyzer, elemental compositions of the CZTS nanoparticles of Examples 31 to 35 were calculated. Results thereof are shown in Table 4. Values in the table are values calculated based on Cu.

TABLE 4

| Example No. | Cu | Zn | Sn | S |
|---|---|---|---|---|
| 31 | 2.0 | 0.6 | 0.9 | 3.6 |
| 32 | 2.0 | 0.6 | 1.0 | 3.3 |
| 33 | 2.0 | 0.1 | 0.9 | 2.7 |
| 34 | 2.0 | 1.1 | 1.0 | 3.4 |
| 35 | 2.0 | 0.1 | 0.9 | 2.9 |

From analysis results described above, it was clarified that according to a solvothermal reaction, spherical CZTS powder having an almost uniform particle size of several hundreds nanometers can be produced. A particle size of primary particles of CZTS is about 10 nm and the primary particles flocculate to form secondary particle. Valence of each of metal elements configuring the CZTS was not affected by valence of the starting raw material.

According to the method of the present invention, CZTS nano-particles having a fine particle size can be produced at a low cost.

1-14. (canceled)

15. A method of producing a sulfide compound semiconductor containing Cu, Zn, Sn and S, the method comprising:
a solvothermal step of conducting a solvothermal reaction of Cu, Zn, Sn and S in an organic solvent, the solvothermal reaction in the solvothermal step being conducted at a temperature more than 250° C. and 450° C. or lower using an apparatus that uses a nickel alloy.

16. The method according to claim 15, wherein, in the solvothermal step, S is solvothermally reacted in the form of sulfur powder or thiourea.

17. The method according to claim 16, wherein, in the solvothermal step, at least one of Cu, Zn and Sn is solvothermally reacted in the form of metal.

18. The method according to claim 16, wherein, in the solvothermal step, Cu, Zn and Sn are solvothermally reacted in the form of salt.

19. The method according to claim 15, wherein, in the solvothermal step, the solvothermal reaction is conducted for 1 to 24 hours.

20. The method according to claim 19, wherein, in the solvothermal step, the solvothermal reaction is conducted for 8 to 12 hours.

21. The method according to claim 15, wherein the S is in the form of sulfur powder.

22. The method according to claim 15, wherein a concentration of the Cu is in the range of 0.1 to 1.0 mol/L.

23. The method according to claim 15, wherein a concentration of the Zn is in the range of 0.05 to 0.5 mol/L.

24. The method according to claim 15, wherein a concentration of the Sn is in the range of 0.05 to 0.5 mol/L.

25. The method according to 15, wherein a concentration of the S is in the range of 0.2 to 4.0 mol/L.

26. The method according to claim 15, wherein a mole ratio of the Cu, Zn, Sn and S is, as a composition ratio of S to Cu, Zn and Sn, in the range of 2:1:1:4 to 2:1:1:12.

27. The method according to claim 26, wherein a mole ratio of the Cu, Zn, Sn and S is, as a composition ratio of S to Cu, Zn and Sn, in the range of 2:1:1:6 to 2:1:1:8.

28. A rod-like crystal of sulfide compound semiconductor, comprising:
Cu, Zn, Sn and S.
